(19) United States
(12) Patent Application Publication
(10) Pub. No.: US 2026/0222526 A1
(43) Pub. Date: Jul. 30, 2026

(54) DISPLAY SYSTEM

(71) Applicant: Semiconductor Energy Laboratory Co., Ltd., Atsugi-shi, Kanagawa-ken (JP)

(72) Inventors: Yosuke TSUKAMOTO, Atsugi (JP); Yusuke KUWAHARA, Atsugi (JP); Shigeru ONOYA, Isehara (JP); Junya MARUYAMA, Ebina (JP); Hisao IKEDA, Zama (JP); Ryo HATSUMI, Hadano (JP)

(21) Appl. No.: 19/149,279

(22) PCT Filed: Feb. 13, 2024
(86) PCT No.: PCT/IB2024/051302

§ 371 Date: Jul. 18, 2025

(30) Foreign Application Priority Data
Feb. 20, 2023 (JP) 2023-024456

(51) Int. Cl. H04N 13/117; G02B 27/00; G02B 27/01; H04N 13/344; H04N 13/376; H04N 13/378; H04N 13/38; H04N 13/383; H10D 86/40; H10D 86/60

(52) U.S. Cl. CPC H04N 13/117; G02B 27/0172; H04N 13/344; H04N 13/376; H04N 13/378; H04N 13/38; H04N 13/383; H10D 86/451; H10D 86/60; G02B 27/0093; G02B 2027/0138; G02B 2027/0178

(57) ABSTRACT

A display system with low power consumption is provided. A display system in which the amount of data transmission can be reduced is provided. A display module of the display system includes a circuit portion and a display portion divided into a plurality of blocks. A gaze detection portion captures an image of a user's eye and its vicinity, and a coordinate detection portion generates coordinate information of a gaze point. An attitude detection portion detects an orientation of a user's head. An image generation portion generates first image data on the basis of attitude information, and generates definition information for each of the blocks on the basis of the coordinate information. A data generation portion generates second image data obtained by performing thinning processing on some of the blocks of the first image data on the basis of the definition information, and transmits the second image data to the display module. The circuit portion generates third data obtained by interpolation processing for interpolating missing data of the block, subjected to the thinning processing, of the second data, and the display portion displays an image on the basis of the third data.

### TECHNICAL FIELD

One embodiment of the present invention relates to a display apparatus. One embodiment of the present invention relates to a system including a display apparatus. One embodiment of the present invention relates to an electronic device including a display apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, electronic devices including display apparatuses have been widely used. In particular, the electronic devices, for example, HMDs (Head Mounted Displays) suitable for XR (Extended Reality or Cross Reality) applications such as virtual reality (VR) or augmented reality (AR), have been attracting attention. HMDs are capable of displaying a video showing 360-degree view of the user's surroundings in accordance with the motion of the user's head or the user's gaze or operation; thus, the user can have a high sense of immersion and a high realistic sensation.

An HMD has a structure in which an optical member or the like magnifies an image displayed on a display apparatus, so that the user sees the magnified image. In this case, there is a possibility that the size of a housing increases because of the presence of the optical member or that the user sees pixels easily and senses graininess strongly; hence, the display apparatus is required to have high resolution and a smaller size. For example, an HMD that includes minute pixels using transistors capable of high-speed driving is disclosed (see Patent Document 1).

### REFERENCE

### Patent Document

[Patent Document 1] Japanese Published Patent Application No. 2000-2856

### SUMMARY OF THE INVENTION

### Problems to be Solved by the Invention

With higher resolution and higher definition of a display apparatus, an increase in power consumption, an increase in the data amount, an increase in the amount of arithmetic operation, and the like might arise.

An object of one embodiment of the present invention is to provide a semiconductor device, a display apparatus, an electronic device, or a display system that has low power consumption. An object of one embodiment of the present invention is to provide a semiconductor device, a display apparatus, an electronic device, or a display system that can have a reduced amount of data transmission. An object of one embodiment of the present invention is to provide a semiconductor device, a display apparatus, an electronic device, or a display system with excellent drawing processing capacity.

An object of one embodiment of the present invention is to provide a novel semiconductor device, a novel display apparatus, a novel electronic device, or a novel display system. An object of one embodiment of the present invention is to at least alleviate at least one of problems of the conventional technique.

Note that the description of these objects does not preclude the existence of other objects. One embodiment of the present invention does not necessarily achieve all these objects. Other objects can be derived from the description of the specification, the drawings, the claims, and the like.

### Means for Solving the Problems

One embodiment of the present invention is a display system including a display module, a gaze detection portion, an attitude detection portion, a coordinate detection portion, an image generation portion, and a data generation portion. The display module includes a circuit portion and a display portion divided into a plurality of blocks. The gaze detection portion has a function of capturing an image of a user's eye and its vicinity and outputting image information to the coordinate detection portion. The coordinate detection portion has a function of generating coordinate information of a gaze point from the image information and outputting the coordinate information to the image generation portion. The attitude detection portion has a function of detecting the orientation of a user's head and outputting the orientation to the image generation portion as attitude information. The image generation portion has a function of generating first image data on the basis of the attitude information, a function of generating definition information for each of the blocks on the basis of the coordinate information, and a function of outputting the first image data and the definition information to the data generation portion. The data generation portion has a function of generating second image data obtained by performing thinning processing on some of the blocks of the first image data on the basis of the definition information and outputting the second image data to the display module. The circuit portion has a function of generating third image data obtained by interpolation processing for interpolating missing data of the block, subjected to the thinning processing, of the second image data and outputting the third image data to the display portion. The display portion has a function of displaying an image on the basis of the third image data.

In the above, an optical system positioned between the display module and the user is preferably included. In that case, the optical system preferably includes a pancake lens.

In the above, the optical system preferably includes one or more lenses and two or more reflective plates.

In the above, the gaze detection portion preferably includes a light source emitting infrared light and a camera having sensitivity to the infrared light. In that case, the camera is preferably provided at a position allowing image capturing of the user's eye from obliquely below.

In the above, preferably, the display portion includes a pixel circuit, and the pixel circuit includes a transistor including an oxide semiconductor in a semiconductor layer where a channel is formed.

In the above, preferably, the display module further includes a plurality of driver circuits, and the driver circuits each include a gate driver circuit and a source driver circuit. Furthermore, preferably, the display portion and the driver circuits are provided over the same substrate and overlap with each other.

In the above, the source driver circuit preferably includes a transistor including silicon in a semiconductor layer where a channel is formed.

### Effect of the Invention

According to one embodiment of the present invention, a semiconductor device, a display apparatus, an electronic device, or a display system having low power consumption can be provided. Alternatively, a semiconductor device, a display apparatus, an electronic device, or a display system that can have a reduced amount of data transmission can be provided. Alternatively, a semiconductor device, a display apparatus, an electronic device, or a display system with excellent drawing processing capacity can be provided.

According to one embodiment of the present invention, a novel semiconductor device, a novel display apparatus, a novel electronic device, or a novel display system can be provided. According to one embodiment of the present invention, at least one of problems of the conventional technique can be at least alleviated.

Note that the description of these effects does not preclude the existence of other effects. Note that one embodiment of the present invention does not need to have all of these effects. Note that effects other than these can be derived from the description of the specification, the drawings, the claims, and the like.

### BRIEF DESCRIPTION OF THE DRAWINGS

FIG. 1A and FIG. 1B are diagrams showing structure examples of a display system.

FIG. 2A to FIG. 2C are diagrams showing structure examples of a display system.

FIG. 3 is a diagram showing an operation method example of a display system.

FIG. 4A and FIG. 4B are diagrams showing structure examples of a display apparatus.

FIG. 5 is a diagram showing a structure example of a display apparatus.

FIG. 6A and FIG. 6B are diagrams showing structure examples of a display apparatus.

FIG. 7A to FIG. 7D are diagrams showing structure examples of a display apparatus.

FIG. 8A to FIG. 8C are diagrams showing structure examples of a display apparatus.

FIG. 9A to FIG. 9C are diagrams showing structure examples of a display apparatus.

FIG. 10A and FIG. 10B are diagrams showing operation examples of a display apparatus.

FIG. 11A to FIG. 11C are perspective views of a display module.

FIG. 12A and FIG. 12B are diagrams showing structure examples of a display apparatus.

FIG. 13A to FIG. 13D are diagrams showing structure examples of a pixel circuit.

FIG. 14A to FIG. 14D are diagrams showing structure examples of a pixel circuit.

FIG. 15 is a timing chart showing a driving method of a display apparatus.

FIG. 16A and FIG. 16B are diagrams showing structure examples of an electronic device.

FIG. 17A and FIG. 17B are diagrams showing structure examples of an electronic device.

FIG. 18 is a diagram showing an operation example of an electronic device.

FIG. 19A and FIG. 19B are schematic views showing structure examples of an electronic device.

FIG. 20A and FIG. 20B are schematic views showing structure examples of an electronic device.

FIG. 21A and FIG. 21B are schematic views showing structure examples of an electronic device.

FIG. 22A is a diagram showing a sub-display portion. FIG. 22B1 to FIG. 22B7 are diagrams showing structure examples of a pixel.

FIG. 23A to FIG. 23D are diagrams showing structure examples of a light-emitting element.

FIG. 24A to FIG. 24D are diagrams showing structure examples of a light-emitting element.

FIG. 25A to FIG. 25D are diagrams showing structure examples of a light-emitting element.

FIG. 26A and FIG. 26B are diagrams showing structure examples of a light-emitting element.

FIG. 27 is a diagram showing a structure example of a display apparatus.

FIG. 28 is a diagram showing a structure example of a display apparatus.

FIG. 29A to FIG. 29C are diagrams showing structure examples of a semiconductor device.

FIG. 30A to FIG. 30D are diagrams showing structure examples of a semiconductor device.

FIG. 31A is a schematic view of an electronic device according to Example, and FIG. 31B is a photograph of the electronic device.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Thus, the size, the layer thickness, or the region is not limited to the shown scale.

Note that in this specification and the like, ordinal numbers such as “first” and “second” are used in order to avoid confusion among components and do not limit the number.

### Embodiment 1

In this embodiment, a display system of one embodiment of the present invention will be described.

The display system of one embodiment of the present invention can be used for a wearable display apparatus that can be worn on a user's head. The display system has a function of detecting where in an image a user is gazing, displaying a high-definition image at the gaze point and in its vicinity, and displaying a low-definition image in a region away from the gaze point. This can reduce the amount of image data, whereby power consumption for data transmission can be reduced.

A display portion that displays an image is preferably divided into a plurality of blocks so that the definition and frame frequency can be set for each block. In that case, the number of blocks is smaller than the number of pixels included in the display portion. With such a structure, the number of pieces of data for setting the definition and the frame frequency is only the number of blocks, and thus the definition and the frame frequency can be efficiently varied at high speed.

More specific structure examples are described below with reference to drawings.

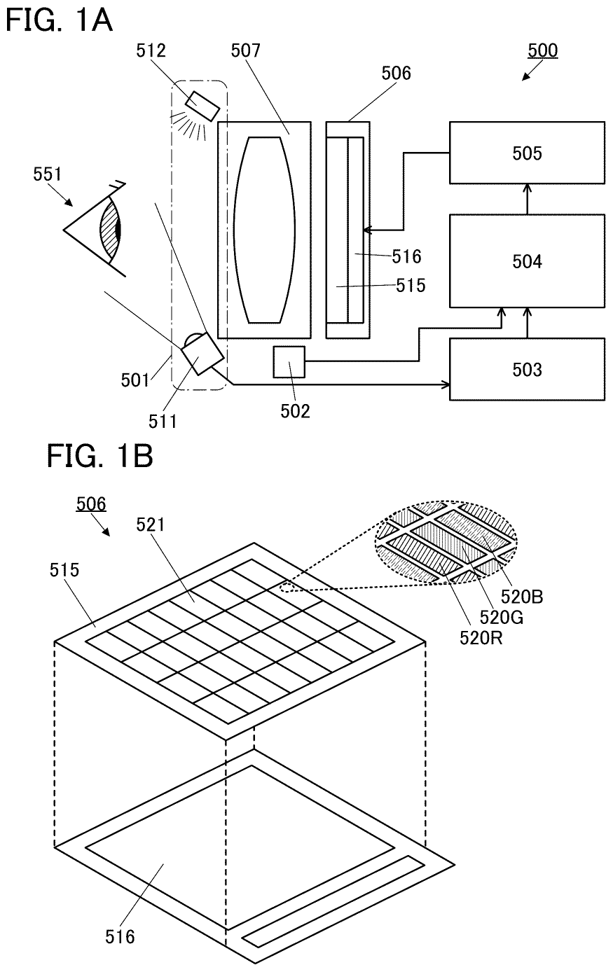

FIG. 1A shows a schematic view of a display system 500 of one embodiment of the present invention. The display system 500 includes a gaze detection portion 501, an attitude detection portion 502, a coordinate detection portion 503, an image generation portion 504, a data generation portion 505, a display module 506, and an optical system 507.

Although not shown here, at least the gaze detection portion 501, the attitude detection portion 502, the display module 506, and the optical system 507 are preferably stored in a housing including a wearing tool that can be fixed to the user's head. The coordinate detection portion 503, the image generation portion 504, and the data generation portion may each be stored in the housing or provided separately from the housing.

The display module 506 includes a display portion 515 and a circuit portion 516.

FIG. 1B shows a schematic view of the display module 506. The display portion 515 includes a plurality of pixels arranged in a matrix. In FIG. 1B, an enlarged view of the display portion 515 is shown. In the display portion 515, pixels 520R that emit red light, pixels 520G that emit green light, and pixels 520B that emit blue light are periodically arranged.

The display portion 515 is divided into a plurality of blocks 521. The blocks (also referred to as sections) are each independently provided with a driver circuit (e.g., a source driver circuit and a gate driver circuit) and can be individually driven. Specifically, the frame frequency can differ between the blocks. Accordingly, realistic sensation can be improved by increasing the frame frequency of the blocks 521 that are close to the user's gaze point, and power consumption of the driver can be reduced by decreasing the frame frequency of the blocks 521 that are far from the gaze point. This can achieve a display system having low power consumption and offering a high realistic sensation.

The display definition can be set for each block. For example, an image can be displayed such that the display definition of the blocks 521 close to the gaze point is equal to the pixel definition and the display definition of the blocks 521 far from the gaze point is lower than the pixel definition. This can reduce the amount of image data transmission, whereby power consumption for data transmission can be reduced.

Here, in this specification and the like, the pixel definition refers to the total number of pixels included in the display portion, and the display definition refers to the definition of an image (image data) displayed on the display portion. The display portion cannot display an image with a display definition higher than the pixel definition. Meanwhile, the display portion can display an image with a display definition lower than the pixel definition. Note that each of the pixel definition and the display definition is simply referred to as definition in some cases.

The gaze detection portion 501 has a function of capturing an image of a user's eye 551 and its vicinity and outputting captured data to the coordinate detection portion 503 as image information. The gaze detection portion 501 includes an image capturing portion 511 and a light source 512. A light-emitting element that emits infrared light is preferably used as the light source 512, in which case image capturing can be performed without being perceived by a user. Moreover, a camera having sensitivity to infrared light can be used for the image capturing portion 511.

Here, as shown in FIG. 1A, the image capturing portion 511 is preferably placed at a position allowing image capturing of the user's eye 551 from obliquely below. For example, in the case where an image of the user's eye 551 is captured from above, part of the eye 551 is covered with an eyebrow, an eyelash, an upper eyelid, a hair, or the like depending on the user, and thus a clear image of a pupil cannot be captured in some cases. However, the frequency of occurrence of such a problem can be reduced by capturing an image from obliquely below. Note that the position of the image capturing portion 511 is not limited thereto, and can be changed as appropriate in accordance with the specifications of the housing or the like.

The attitude detection portion 502 has a function of detecting an orientation of the user's head and outputting the orientation to the image generation portion 504 as attitude information. As the attitude detection portion 502, a motion sensor using an acceleration sensor is preferably used, for example, in which case the size can be easily reduced.

The coordinate detection portion 503 has a function of estimating the user's gaze on the basis of the image information input from the gaze detection portion 501, calculating coordinates of the gaze point on the display portion of the display module 506 from the direction of the gaze, and outputting the coordinates to the image generation portion 504 as coordinate information.

The image generation portion 504 has a function of generating first image data corresponding to a movement of the user's head on the basis of the attitude information input from the attitude detection portion 502 and outputting the first image data to the data generation portion 505. For example, the first image data can be generated using image data captured by an omnidirectional camera or the like or image data generated by computer graphics. Here, the first image data is an image with a definition corresponding to the pixel definition of the display portion 515.

The image generation portion 504 also has a function of generating definition information including information on the display definition of each block 521 of the display portion 515 on the basis of the coordinate information input from the coordinate detection portion 503 and outputting the definition information to the data generation portion 505.

For example, the display definition of the blocks 521 including the gaze point and the display definition of the blocks 521 therearound can be equal to the pixel definition, and the display definition of the blocks 521 positioned outside them can be 1/n (n is an integer greater than or equal to 2) of the pixel definition. It is preferable that the user be capable of setting the degree of reduction in display definition, the range of blocks with reduced display definition, or the like. For example, depending on the user's settings, all the display definitions can be equal to the pixel definition regardless of the gaze point.

The data generation portion 505 generates second image data obtained by performing thinning processing (also referred to as downconversion), on the basis of the definition information, on some of the blocks of the first image data input from the image generation portion 504 and outputs the second image data to the circuit portion 516 of the display module 506. For example, even when the thinning processing is performed on only one of the blocks of the second image data, the second image data has a smaller amount of information (data amount) than the first image data. Thus, the amount of data transmission from the data generation portion 505 to the display module 506 can be reduced, leading to a reduction in power consumption.

Here, one or more of the coordinate detection portion 503, the image generation portion 504, and the data generation portion 505 may be composed of a computer and a program that can be executed by the computer. In other words, one or more of them may be implemented by an arithmetic device such as a general-purpose CPU and a program executed by the arithmetic device. Alternatively, they may be implemented with an SoC (System on Chip) typified by a specially designed application processor. Further alternatively, they may be implemented in a way that customization is possible by an FPGA.

The second image data can be transmitted from the data generation portion 505 to the display module 506 with or without a wire.

The circuit portion 516 has a function of generating third image data obtained by performing interpolation processing (also referred to as upconversion) for interpolating missing data of the block 521, which is subjected to the thinning processing, of the second image data input from the data generation portion 505 and outputting the third image data to the display portion 515.

The display portion 515 has a function of displaying an image on the basis of the third image data input from the circuit portion 516. Accordingly, the display portion 515 can display an image with a higher definition closer to the gaze point and with a lower definition far from the gaze point.

The optical system 507 is positioned between the user's eye 551 and the display portion 515 and has a function of magnifying an image displayed on the display portion 515, magnifying the field of view (FOV), and adjusting the focus, for example. The optical system 507 can include a reflective plate, a light guide plate, a polarizing plate, a diffusing plate, or at least one lens.

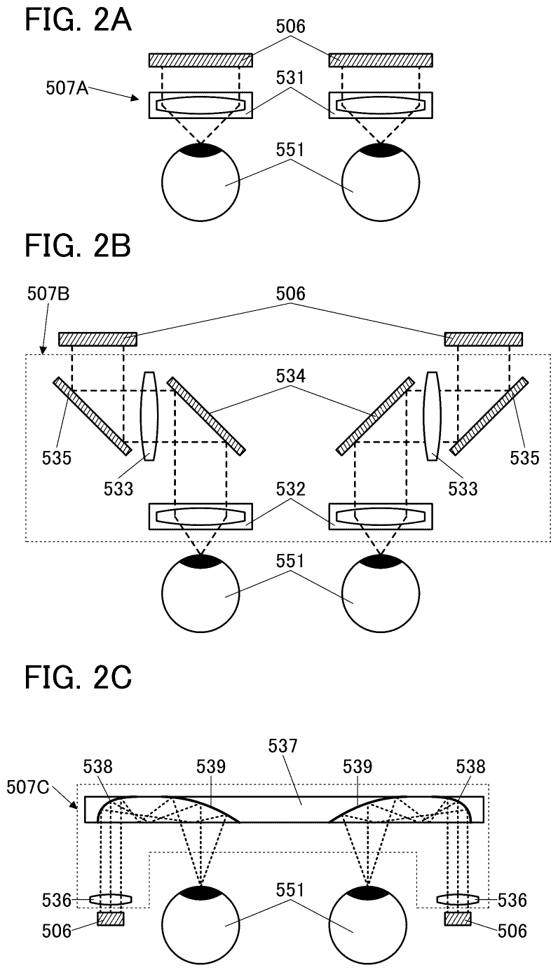

FIG. 2A to FIG. 2C each show a more specific structure example of the optical system 507.

An optical system 507A shown in FIG. 2A includes a pair of lens groups 531. The lens groups 531 are positioned between the display modules 506 and the user's eyes 551. The lens groups 531 can each have a structure where a convex lens, a concave lens, a Fresnel lens, and the like are combined. In particular, a catadioptric system (also referred to as a pancake lens) using a reflective polarizing plate or the like is preferably used for each of the lens groups 531, in which case the lens groups 531 can be reduced in thickness and weight.

An optical system 507B shown in FIG. 2B includes a pair of lens groups 532, a pair of lenses 533, a pair of reflective plates 534, and a pair of reflective plates 535. Light of images displayed on the display portions of the display modules 506 is reflected by the reflective plates 535, transmitted through the lenses 533, reflected by the reflective plates 534, transmitted through the lens groups 532, and delivered to the eyes 551. When reflection by the two reflective plates (the reflective plates 534 and the reflective plates 535) is used, the display modules 506 do not need to be placed on extension lines of optical axes of the lens groups 532, which increases the degree of freedom in design. Moreover, when the lenses 533 functioning as relay lenses are placed between the two reflective plates (the reflective plates 534 and the reflective plates 535), the degree of freedom in design can be further increased.

Although the display modules 506 are placed in front of the eyes 551 here, the display modules can be placed in various positions by changing the direction of the reflective plates and the number of reflective plates.

An optical system 507C shown in FIG. 2C includes a light guide plate 537, a pair of lenses 536, a pair of reflective plates 538, and a pair of reflective plates 539. Note that although one light guide plate 537 is provided here, the light guide plate 537 may be divided for each eye.

Light emitted from the display modules 506 is transmitted through the lenses 536, reflected by the reflective plates 538, guided inside the light guide plate 537, reflected by the reflective plates 539, and delivered to the eyes 551. With such a structure, lenses do not need to be provided in front of the eyes 551; thus, a thin and lightweight device can be obtained.

In the case where a half mirror is used as each of the reflective plates 539, the user can see an image where a real image transmitted through each of the reflective plates 539 and an image reflected by each of the reflective plates 539 can be superimposed on each other to be seen.

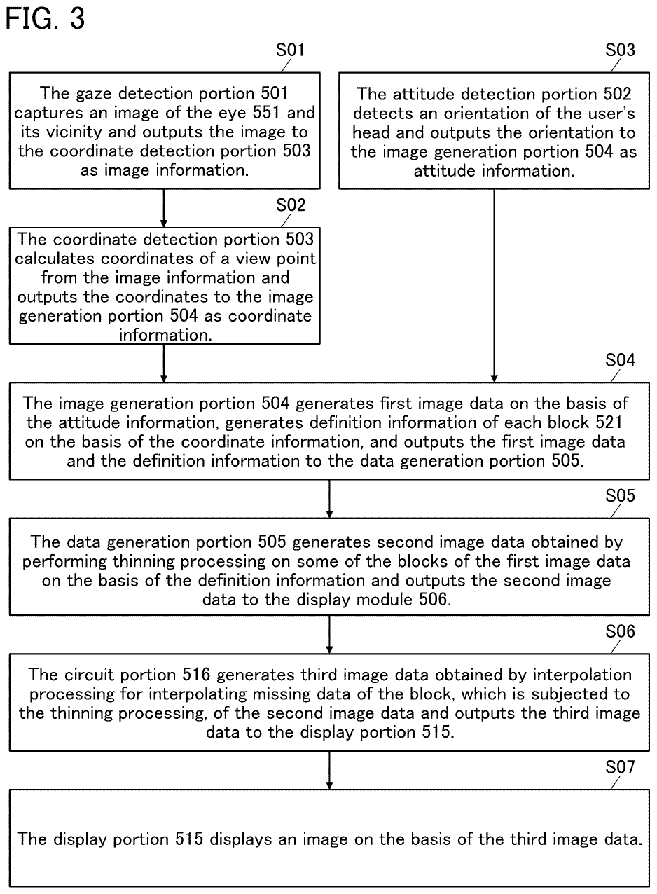

Next, an operation method example of the display system 500 will be described with reference to FIG. 3. Here, procedures for an operation in one frame period is described. In practice, the procedures described below is repeated in a period during which an image is displayed, whereby a moving image can be displayed.

In Step S01, the gaze detection portion 501 captures an image of the user's eye 551 and its vicinity and outputs the image to the coordinate detection portion 503 as image information.

Next, in Step S02, the coordinate detection portion 503 calculates coordinates of a view point from the image information and outputs the coordinates to the image generation portion 504 as coordinate information.

In parallel with Step S01 and Step S02, the attitude detection portion 502 detects an orientation of the user's head and outputs the orientation to the image generation portion 504 as attitude information in Step S03.

Next, in Step S04, the image generation portion 504 generates the first image data on the basis of the attitude information. In addition, definition information of each block 521 is generated on the basis of the coordinate information. Then, the first image data and the definition information are output to the data generation portion 505.

Subsequently, in Step S05, the data generation portion 505 generates the second image data obtained by performing thinning processing on some of the blocks of the first data on the basis of the definition information and outputs the second image data to the display module 506. Here, the definition information may also be output to the display module 506 in addition to the second image data. In that case, when the definition information is transmitted in a blanking interval between the frames, delay in data transmission can be prevented.

Next, in Step S06, the circuit portion 516 generates the third image data obtained by interpolation processing for interpolating missing data of the block, which is subjected to the thinning processing, of the second image data and outputs the third image data to the display portion 515. At this time, the interpolation processing may be performed on the basis of the definition information input from the data generation portion 505.

Subsequently, in Step S07, the display portion 515 displays an image on the basis of the third image data.

The above is the operation method example of the display system in one frame period. By repeating the above steps, the amount of data transmission can be reduced, and a high-quality moving image can be displayed with low power consumption. Furthermore, the reduced amount of data transmission can increase the frame frequency, and thus a smooth moving image can be displayed.

At least part of this embodiment can be implemented in combination with the other embodiments described in this specification as appropriate.

### Embodiment 2

In this embodiment, a display apparatus that can be used for the display system of one embodiment of the present invention will be described. The display apparatus described below as an example can be used for the display module described in Embodiment 1, for example.

### <Display Apparatus 10A>

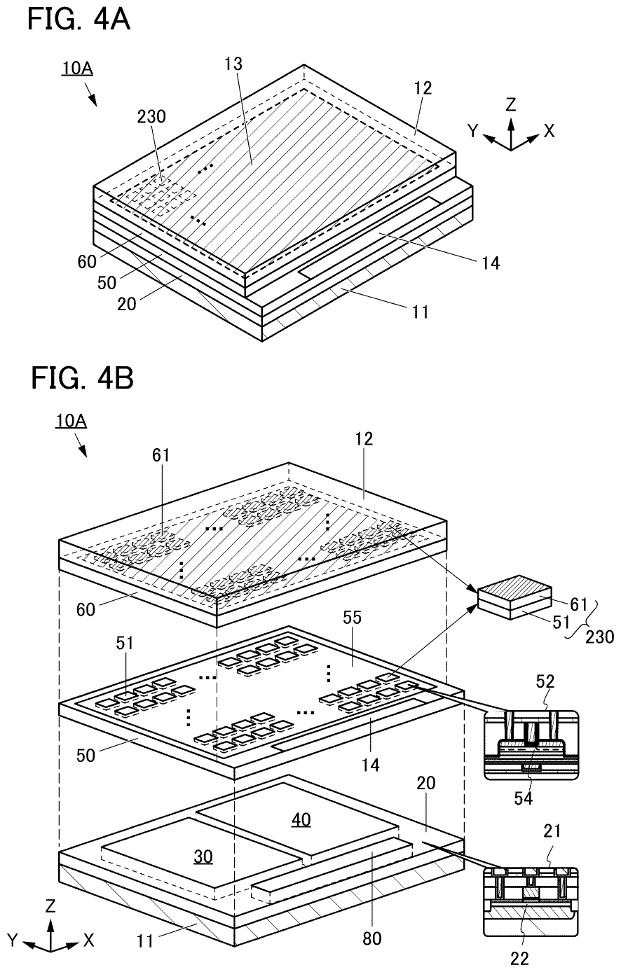

FIG. 4A is a perspective view of a display apparatus 10A of one embodiment of the present invention. The display apparatus 10A includes a substrate 11 and a substrate 12. The display apparatus 10A includes a display portion 13 between the substrate 11 and the substrate 12. The display portion 13 includes a plurality of pixels 230. The pixels 230 each include a pixel circuit 51 and a light-emitting element 61. The display portion 13 is a region where an image is displayed in the display apparatus 10A.

By using the pixels 230 arranged in a matrix of 1920×1080 pixels, the display portion 13 can achieve display with a definition of a so-called full hi-vision (also referred to as “2K definition”, “2K1K”, “2K”, or the like). For example, by using the pixels 230 arranged in a matrix of 3840×2160 pixels, the display portion 13 can achieve display with a definition of a so-called ultra hi-vision (also referred to as “4K definition”, “4K2K”, “4K”, or the like). For example, by using the pixels 230 arranged in a matrix of 7680×4320 pixels, the display portion 13 can achieve display with a definition of a so-called super hi-vision (also referred to as “8K definition”, “8K4K”, “8K”, or the like). By increasing the number of pixels 230, the display portion 13 that can perform display with 16K or 32K definition can also be obtained.

Furthermore, the pixel density (resolution) of the display portion 13 is preferably higher than or equal to 1000 ppi and lower than or equal to 10000 ppi. For example, the pixel density may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 13. For example, the display portion 13 is compatible with a variety of screen ratios such as 1:1 (square), 4:3, 16:9, and 16:10.

In this specification and the like, the term “element” can be replaced with the term “device” in some cases. For example, a display element, a light-emitting element, and a liquid crystal element can be rephrased as a display device, a light-emitting device, and a liquid crystal device, respectively, for example.

Various kinds of signals and power supply potentials are input to the display apparatus 10A from the outside via a terminal portion 14, so that image display can be performed using a display element provided in the display portion 13. Any of a variety of elements can be used as the display element. Typically, a light-emitting element having a function of emitting light, such as an organic EL element or an LED element, a liquid crystal element, a MEMS (Micro Electro Mechanical Systems) element, or the like can be used.

A plurality of layers are provided between the substrate 11 and the substrate 12, and each of the layers is provided with a transistor for a circuit operation, or a display element which emits light. A pixel circuit having a function of controlling an operation of the display element, a driver circuit having a function of controlling the pixel circuit, a functional circuit having a function of controlling the driver circuit, and the like are provided in the plurality of layers.

The functional circuit corresponds to the circuit portion described as an example in Embodiment 1.

FIG. 4B is a perspective view schematically showing structures of layers provided between the substrate 11 and the substrate 12 in the display apparatus 10A.

A layer 20 is provided over the substrate 11. The layer 20 includes a driver circuit 30, a functional circuit 40, and an input/output circuit 80. The layer 20 includes a transistor 21 including silicon in a channel formation region 22 (such a transistor is also referred to as a “Si transistor” or “SiFET”). The substrate 11 is, for example, a silicon substrate. A silicon substrate is preferable because it has higher thermal conductivity than a glass substrate. By providing the driver circuit 30, the functional circuit 40, and the input/output circuit 80 in the same layer, wirings electrically connecting the driver circuit 30, the functional circuit 40, and the input/output circuit 80 can be short. As a result, charge and discharge time of a control signal used when the functional circuit 40 controls the driver circuit 30 becomes short, leading to a reduction in power consumption. In addition, charge and discharge time during which a signal is supplied from the input/output circuit 80 to the functional circuit 40 and the driver circuit 30 becomes short, leading to a reduction in power consumption.

The transistor 21 can be a transistor including single crystal silicon in its channel formation region (also referred to as a “c-Si transistor”), for example. In particular, the use of a transistor including single crystal silicon in a channel formation region as the transistor provided in the layer 20 can increase the on-state current of the transistor. This enables high-speed driving of circuits included in the layer 20 and is thus preferable. The Si transistor can be formed by microfabrication to have a channel length greater than or equal to 3 nm and less than or equal to 10 nm, for example; thus, a CPU, an accelerator such as a GPU, an application processor, or the like can be integral with the display portion in the display apparatus 10A.

A transistor including polycrystalline silicon in its channel formation region (also referred to as a “Poly-Si transistor”) may be provided in the layer 20. As the polycrystalline silicon, low-temperature polysilicon (LTPS) may be used. Note that a transistor including LTPS in its channel formation region is also referred to as an “LTPS transistor”. An OS transistor may be provided in the layer 20 as necessary.

Any of a variety of circuits such as a shift register, a level shifter, an inverter, a latch, an analog switch, and a logic circuit can be used as the driver circuit 30. The driver circuit 30 includes a gate driver circuit (also referred to as a “scan line driver circuit”), a source driver circuit (also referred to as a “video signal line driver circuit”), or the like, for example. In addition, an arithmetic circuit, a memory circuit, a power supply circuit, and the like may be included. Since the gate driver circuit, the source driver circuit, and other circuits can be placed to overlap with the display portion 13, the width of a non-display region (also referred to as a bezel) provided along the outer periphery of the display portion 13 of the display apparatus 10A can be extremely narrow compared with the case where these circuits and the display portion 13 are arranged side by side, whereby the display apparatus 10A can be reduced in size.

The functional circuit 40 has a function of an application processor for controlling the circuits in the display apparatus 10A and generating signals used for controlling the circuits, for example. The functional circuit 40 may include a circuit used for correcting image data, like a CPU or an accelerator such as a GPU. The functional circuit 40 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the display apparatus 10A. The functional circuit 40 may include a circuit for compressing and decompressing image data and a power supply circuit, for example. Note that the functional circuit 40 is not necessarily provided in the display apparatus 10A, and an external arithmetic device or the like may be used instead of the functional circuit 40. Part of the functions of the functional circuit 40 may be provided in a layer 50.

The layer 50 is provided over the layer 20. The layer 50 includes a pixel circuit group 55 including a plurality of pixel circuits 51. An OS transistor may be provided in the layer 50. Each of the pixel circuits 51 may include an OS transistor. Note that the layer 50 can be stacked over the layer 20.

A Si transistor may be provided in the layer 50. For example, the pixel circuits 51 may each include a transistor including single crystal silicon or polycrystalline silicon in its channel formation region. As the polycrystalline silicon, LTPS may be used. For example, the layer 50 can be formed over another substrate and bonded to the layer 20. Alternatively, the layer 50 may be formed over another substrate, and only the layer 50 may be transferred from the substrate onto the layer 20. Alternatively, the layer 50 may be formed over another substrate, the layer 50 may be separated from the substrate, and the layer 50 may be provided over a flexible substrate.

As another example, the pixel circuits 51 may each include a plurality of kinds of transistors using different semiconductor materials. In the case where the pixel circuits 51 each include a plurality of kinds of transistors using different semiconductor materials, different kinds of transistors may be provided in different layers. For example, in the case where the pixel circuits 51 each include a Si transistor and an OS transistor, the Si transistor and the OS transistor may be provided to overlap with each other. Providing the transistors to overlap with each other reduces the area occupied by the pixel circuits 51. Thus, the resolution of the display apparatus 10A can be improved. Note that a structure in which an LTPS transistor and an OS transistor are combined is referred to as LTPO in some cases.

It is preferable to use, as a transistor 52 that is an OS transistor, a transistor including an oxide including at least one of indium and zinc in a channel formation region 54. Such an OS transistor has a characteristic of an extremely low off-state current. Thus, it is particularly preferable to use the OS transistor as a transistor provided in the pixel circuit, in which case analog data written to the pixel circuit can be retained for a long period.

When the functional circuit 40 is used as a CPU and an OS transistor is used in the CPU, a normally-off CPU (also referred to as “NoffCPU” (registered trademark)) can be obtained. In the NoffCPU, power supply to a circuit that does not need to operate can be stopped so that the circuit can be set in a standby state. The circuit set in the standby state because of the stop of power supply does not consume power. Thus, the power usage of the NoffCPU can be minimized.

A layer 60 is provided over the layer 50. Over the layer 60, the substrate 12 is provided. The substrate 12 is preferably a light-transmitting substrate or a layer formed of a light-transmitting material. The layer 60 includes a plurality of light-emitting elements 61. Note that the layer 60 can be stacked over the layer 50. As the light-emitting element 61, an organic electroluminescent element (also referred to as an organic EL element) or the like can be used, for example. However, the light-emitting element 61 is not limited thereto, and an inorganic EL element formed of an inorganic material may be used, for example. Note that an “organic EL element” and an “inorganic EL element” are collectively referred to as “EL element” in some cases. The light-emitting element 61 may include an inorganic compound such as quantum dots. For example, when used for the light-emitting layer, the quantum dots can function as a light-emitting material.

As shown in FIG. 4B, the display apparatus 10A of one embodiment of the present invention can have a structure in which the light-emitting elements 61, the pixel circuits 51, and the driver circuit 30, and the functional circuit 40 are stacked; thus, the pixel aperture ratio (effective display area ratio) can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 51 can be arranged extremely densely, and thus the resolution of the pixels can be extremely high. For example, the pixels 230 can be arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi in the display portion 13 of the display apparatus 10A.

The display apparatus 10A described above has an extremely high resolution and is thus suitable for a VR device or an AR device such as a head-mounted display or a glasses-type device. For example, even in the case of a structure in which the display portion of the display apparatus 10A is seen through an optical member such as a lens, pixels of the extremely-high-resolution display portion included in the display apparatus 10A are not seen when the display portion is magnified by the lens, so that display providing a high sense of immersion can be performed.

Note that in the case where the display apparatus 10A is used as a display apparatus of a wearable electronic device such as a head-mounted display or a glasses-type device, the display portion 13 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 13 may have a diagonal size of 1.5 inches or approximately 1.5 inches. When the display portion 13 has a diagonal size less than or equal to 2.0 inches, the number of times of light exposure treatment using a light exposure apparatus (typically, a scanner apparatus) can be one; thus, the productivity of the display apparatus improves.

The display apparatus 10A of one embodiment of the present invention can be used for an electronic device other than a wearable electronic device. In that case, the display portion 13 can have a diagonal size greater than 2.0 inches. The structure of transistors used in the pixel circuits 51 may be selected as appropriate depending on the diagonal size of the display portion 13. In the case where single crystal Si transistors are used in the pixel circuits 51, for example, the diagonal size of the display portion 13 is preferably greater than or equal to 0.1 inches and less than or equal to 3 inches. In the case where LTPS transistors are used in the pixel circuits 51, the diagonal size of the display portion 13 is preferably greater than or equal to 0.1 inches and less than or equal to 30 inches, further preferably greater than or equal to 1 inch and less than or equal to 30 inches. In the case where LTPO is used in the pixel circuits 51, the diagonal size of the display portion 13 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 13 is preferably greater than or equal to 0.1 inches and less than or equal to 200 inches, further preferably greater than or equal to 50 inches and less than or equal to 100 inches.

A size increase of a display apparatus using single crystal Si transistors is extremely difficult because a size increase of a single crystal Si substrate is difficult. Furthermore, in the case where LTPS transistors are used in a display apparatus, it is difficult to respond to a size increase (typically to a screen diagonal size greater than 30 inches) because a laser crystallization apparatus is used in the manufacturing process. By contrast, OS transistors can be applied to a display apparatus with a relatively large area (typically, a diagonal size greater than or equal to 50 inches and less than or equal to 100 inches) because the manufacturing process does not necessarily require a laser crystallization apparatus or the like or can be performed at a relatively low process temperature (typically, lower than or equal to 450° C.). In addition, LTPO can be applied to a diagonal size of a display portion between the case of using LTPS transistors and the case of using OS transistors (typically, greater than or equal to 1 inch and less than or equal to 50 inches).

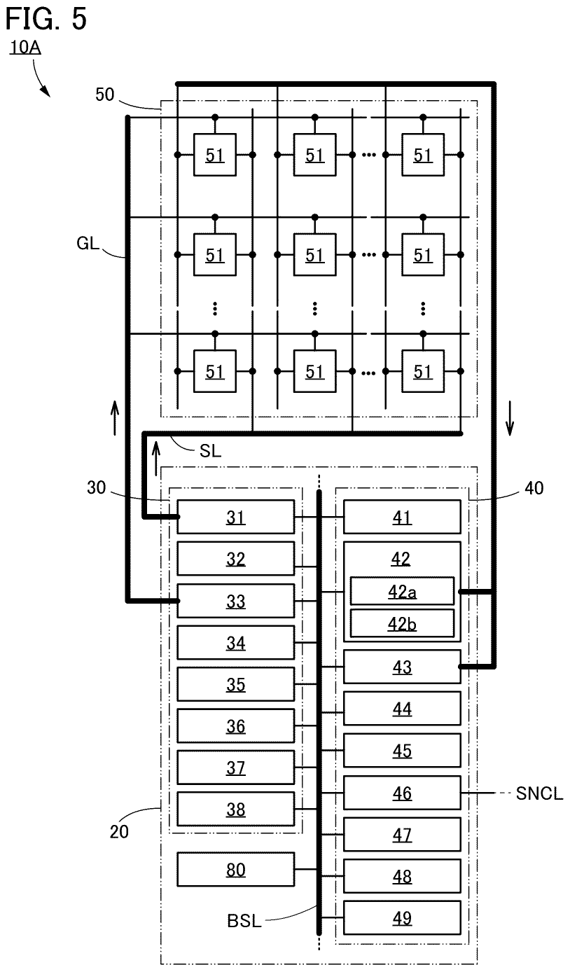

A specific structure example of the driver circuit 30 and the functional circuit 40 will be described with reference to FIG. 5. FIG. 5 is a block diagram showing a plurality of wirings connecting the pixel circuits 51, the driver circuit 30, and the functional circuit 40 in the display apparatus 10A, a bus wiring in the display apparatus 10A, and the like.

In the display apparatus 10A shown in FIG. 5, the plurality of pixel circuits 51 are arranged in a matrix in the layer 50.

Furthermore, the driver circuit 30, the functional circuit 40, and the input/output circuit 80 are arranged in the layer 20 in the display apparatus 10A shown in FIG. 5. The driver circuit 30 includes, for example, a source driver circuit 31, a digital-analog converter (DAC) circuit 32, a gate driver circuit 33, a level shifter 34, an amplifier circuit 35, an inspection circuit 36, a video generation circuit 37, and a video distribution circuit 38. The functional circuit 40 includes, for example, a memory circuit (also referred to as a “memory device”) 41, a GPU (also referred to as an “AI accelerator”) 42, an EL correction circuit 43, a timing generation circuit 44, a CPU 45, a sensor controller 46, a power supply circuit 47, a temperature sensor 48, and a luminance correction circuit 49. The functional circuit 40 has a function of an application processor.

The input/output circuit 80 is compatible with a transmission method such as LVDS (Low Voltage Differential Signaling), and the input/output circuit 80 has a function of dividing control signals, image data, and the like input via the terminal portion 14 between the driver circuit 30 and the functional circuit 40. Furthermore, the input/output circuit 80 has a function of outputting information of the display apparatus 10A to the outside via the terminal portion 14.

FIG. 5 shows an example of a structure in which the circuits included in the driver circuit 30, the circuits included in the functional circuit 40, and the input/output circuit 80 are each electrically connected to a bus wiring BSL.

The source driver circuit 31 has a function of transmitting image data to the pixel circuits 51 included in the pixels 230, for example. Thus, the source driver circuit 31 is electrically connected to the pixel circuits 51 through a wiring SL (also referred to as a “video signal line”). Note that a plurality of source driver circuits 31 may be provided.

The digital-analog converter circuit 32 has a function of converting, into analog data, image data that has been digitally processed by a GPU, a correction circuit, or the like described later, for example. The image data converted into analog data is amplified by the amplifier circuit 35 such as an operational amplifier and is transmitted to the pixel circuits 51 via the source driver circuit 31. Note that the image data may be transmitted to the source driver circuit 31, the digital-analog converter circuit 32, and the pixel circuits 51 in this order. The digital-analog converter circuit 32 and the amplifier circuit 35 may be included in the source driver circuit 31.

The gate driver circuit 33 has a function of selecting the pixel circuit to which image data is to be transmitted among the pixel circuits 51, for example. Thus, the gate driver circuit 33 is electrically connected to the pixel circuits 51 through a wiring GL (also referred to as a “scan line”). Note that a plurality of gate driver circuits 33 may be provided such that the number of the gate driver circuits 33 corresponds to the number of the source driver circuits 31.

The level shifter 34 has a function of converting signals to be input to the source driver circuit 31, the digital-analog converter circuit 32, the gate driver circuit 33, and the like into appropriate levels, for example.

The memory circuit 41 has a function of storing image data to be displayed by the pixel circuits 51, for example. Note that the memory circuit 41 can be configured to store the image data as digital data or analog data.

In the case where the memory circuit 41 stores image data, the memory circuit 41 is preferably a nonvolatile memory. In that case, a NAND memory or the like can be used as the memory circuit 41, for example.

In the case where the memory circuit 41 stores temporary data generated in the GPU 42, the EL correction circuit 43, the CPU 45, or the like, the memory circuit 41 is preferably a volatile memory. In that case, an SRAM, a DRAM, or the like can be used as the memory circuit 41, for example.

The GPU 42 has a function of performing processing for outputting, to the pixel circuits 51, image data read from the memory circuit 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 10A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with the properties of the light-emitting device may be provided in the functional circuit 40. The functional circuit 40 includes, for example, the EL correction circuit 43.

The above-described image correction may be performed using artificial intelligence. For example, a current flowing in a pixel circuit (or a voltage applied to the pixel circuit) may be monitored and obtained, a displayed image may be obtained with an image sensor or the like, the current (or voltage) and the image may be used as input data in an arithmetic operation of artificial intelligence (e.g., an artificial neural network), and the output result may be used to judge whether the image should be corrected.

Such an arithmetic operation of artificial intelligence can be applied to not only image correction but also upconversion processing for increasing the definition of image data. As an example, FIG. 5 shows the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, an SRCNN (Super-Resolution Convolutional Neural Network) method, and the like.

The algorithm used for the upconversion processing may be different between specific regions of the display portion 13. For example, a user's gaze point on the display portion 13 is detected, upconversion processing for a region including the gaze point and the vicinity of the gaze point is performed using an algorithm with a low processing speed but high accuracy, and upconversion processing for a region other than the above region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the definition of image data may be performed. In the case where the definition of image data is higher than the definition of the display portion 13, part of the image data is not displayed on the display portion 13, in some cases. In that case, downconversion processing enables the entire image data to be displayed on the display portion 13.

The timing generation circuit 44 has a function of controlling driving frequency (sometimes also referred to as “frame frequency”, “frame rate”, “refresh rate”, or the like) for displaying an image, for example. In the case where a still image is displayed on the display apparatus 10A, for example, the driving frequency is lowered by the timing generation circuit 44, so that power consumption of the display apparatus 10A can be reduced. The driving with a lowered driving frequency for reducing power consumption of a display apparatus may be referred to as idling stop (IDS) driving.

The CPU 45 has a function of performing general-purpose processing such as execution of an operating system, control of data, and execution of various kinds of arithmetic operations and programs, for example. The CPU 45 has a role in, for example, giving an instruction for an operation for writing or reading image data to/from the memory circuit 41, an operation for correcting image data, an operation for a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 5 shows a wiring SNCL as a wiring for electrical connection to the sensor.

The sensor can be, for example, a touch sensor that can be provided in the display portion 13. Alternatively, the sensor can be an illuminance sensor, for example.

The power supply circuit 47 has a function of generating voltages to be supplied to the pixel circuits 51, the driver circuit 30, and the functional circuit 40, for example. Note that the power supply circuit 47 may have a function of selecting a circuit to which a voltage is to be supplied. The power supply circuit 47 can stop supply of a voltage to the CPU 45, the GPU 42, or the like during a period in which a still image is displayed, so that the power consumption of the whole display apparatus 10A is reduced, for example.

As described above, the display apparatus of one embodiment of the present invention can have a structure in which display elements, pixel circuits, and a driver circuit and the functional circuit 40 are stacked. The driver circuit and the functional circuit, which are peripheral circuits, can be provided so as to overlap with the pixel circuits and thus the width of the bezel can be made extremely small, so that a reduction in size of the display apparatus can be achieved. A structure of the display apparatus of one embodiment of the present invention in which circuits are stacked enables its wirings connecting the circuits to be shortened, resulting in a reduction in weight of the display apparatus. The display apparatus of one embodiment of the present invention can include a display portion with an increased resolution of pixels; thus, the display apparatus can have high display quality.

### <Display Apparatus 10B>

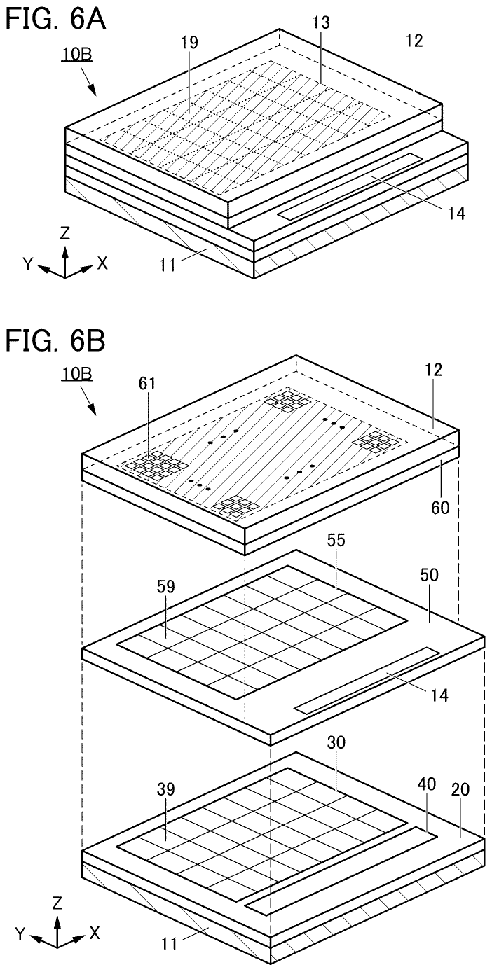

FIG. 6A and FIG. 6B show perspective views of a display apparatus 10B, which is a modification example of the display apparatus 10A. FIG. 6B is a perspective view for explaining structures of layers included in the display apparatus 10B. Description is made mainly on portions different from those of the display apparatus 10A to reduce repeated description.

In the display apparatus 10B, the driver circuit 30 and the pixel circuit group 55 including the plurality of pixel circuits 51 (not shown in FIG. 6A and FIG. 6B) overlap with each other. In the display apparatus 10B, the pixel circuit group 55 is divided into a plurality of sections 59 and the driver circuit 30 is divided into a plurality of sections 39. The plurality of sections 39 each include the source driver circuit 31 and the gate driver circuit 33 (not shown in FIG. 6A and FIG. 6B).

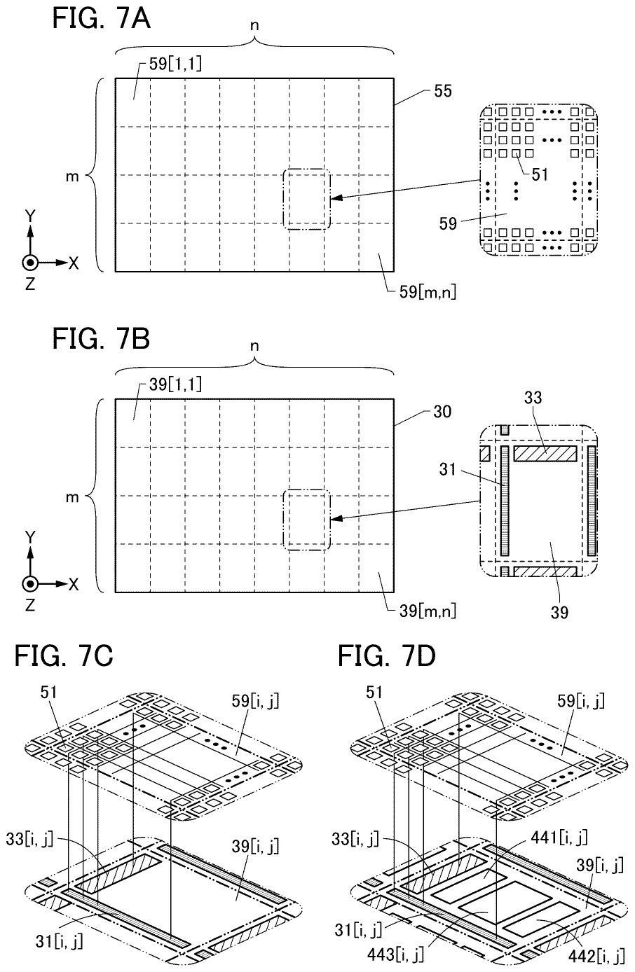

FIG. 7A shows a structure example of the pixel circuit group 55 included in the display apparatus 10B. FIG. 7B shows a structure example of the driver circuit 30 included in the display apparatus 10B. The sections 59 and the sections 39 are each arranged in a matrix of m rows and n columns (m and n are each an integer greater than or equal to 2). In this specification and the like, the section 59 in the first row and the first column is denoted as a section 59[1,1], and the section 59 in the m-th row and the n-th column is denoted as a section 59[m,n]. Similarly, the section 39 in the first row and the first column is denoted as a section 39[1,1], and the section 39 in the m-th row and the n-th column is denoted as a section 39[m,n]. Similarly, a sub-display portion 19 in the first row and the first column is sometimes denoted as a sub-display portion 19[1,1]. The sub-display portion 19[1,1] includes the section 59[1,1] and the section 39[1,1]. FIG. 7A and FIG. 7B show a case where m is 4 and n is 8. That is, the pixel circuit group 55 and the driver circuit 30 are each divided into 32 sections. Thus, the display portion 13 is divided into 32 portions.

The plurality of sections 59 each include the plurality of pixel circuits 51, a plurality of wirings SL, and a plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 7C). For example, a section 59[i,j](i is an integer greater than or equal to 1 and less than or equal to m, and j is an integer greater than or equal to 1 and less than or equal to n) and a section 39[i,j] are provided to overlap with each other. A source driver circuit 31[i,j] included in the section 39[i,j] is electrically connected to the wiring SL included in the section 59[i,j]. A gate driver circuit 33[i,j] included in the section 39[i,j] is electrically connected to the wiring GL included in the section 59[i,j]. The source driver circuit 31[i,j] and the gate driver circuit 33[i,j] have a function of controlling the plurality of pixel circuits 51 included in the section 59[i,j].

When the section 59[i,j] and the section 39[i,j] are provided to overlap with each other, a connection distance (wiring length) between the pixel circuit 51 included in the section 59[i,j] and each of the source driver circuit 31 and the gate driver circuit 33 included in the section 39[i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

A timing generation circuit (a timing generation circuit 441), an input/output circuit (an input/output circuit 442), and a memory circuit (a memory circuit 443) may be provided in each of the sections 39 (see FIG. 7D). For the input/output circuit 442, an I²C (Inter-Integrated Circuit) interface can be used, for example.

Note that the timing generation circuit 441, the input/output circuit 442, and the memory circuit 443 are collectively referred to as a “local controller” in some cases. Note that the local controller may include a circuit other than the timing generation circuit 441, the input/output circuit 442, and the memory circuit 443. The local controller does not necessarily include one or more of the timing generation circuit 441, the input/output circuit 442, and the memory circuit 443.

The timing generation circuit 441 included in the section 39[i,j] is denoted as a timing generation circuit 441[i,j] in FIG. 7C and FIG. 7D. Furthermore, the input/output circuit 442 included in the section 39[i,j] is denoted as an input/output circuit 442[i,j]. Furthermore, the memory circuit 443 included in the section 39[i,j] is denoted as a memory circuit 443[i,j].

The functional circuit 40 supplies setting signals for the scan direction and driving frequency of the gate driver circuit 33[i,j] and operation parameters, such as the number of pixels for which image data reduced by thinning out for decreasing definition (the number of pixels where image data rewriting is not performed at the time of image data rewriting), to the input/output circuit 442[i,j], for example. The timing generation circuit 441[i,j] has a function of determining the driving frequency of the section 39[i,j] in accordance with the operation parameters. That is, the timing generation circuit 441[i,j] has a function of determining the driving frequency of the sub-display portion 19 in the i-th row and the j-th column in accordance with the operation parameters. The operations of the source driver circuit 31[i,j] and the gate driver circuit 33[i,j] are controlled by the timing generation circuit 441[i,j].

The memory circuit 443[i,j] has a function of storing operation parameters, such as definition and driving frequency, supplied to the section 39[i,j]. The memory circuit 443[i,j] has a function of storing image data on an image to be displayed in the sub-display portion 19[1,1]. That is, the memory circuit 443[i,j] functions as a frame memory.

A flash memory, an MRAM, a PRAM, an ReRAM, an FeRAM, a DRAM, an SRAM, or the like may be used as the memory circuit 443. Alternatively, a DOSRAM (registered trademark), a NOSRAM (registered trademark), or the like may be used as the memory circuit 443. When the memory circuit 443 functioning as a frame memory is provided in each sub-display portion 19 (and each section 39), even when transmission of the image data to the sub-display portion 19 is stopped in the case of displaying a still image, display of the still image can be continued using the image data stored in the memory circuit 443.

When the memory circuit 443 is provided in each sub-display portion 19, image data rewriting can be performed in each sub-display portion 19. For example, in the case where part of image data is changed, only image data in the sub-display portion 19 corresponding to a region with the change is rewritten. That is, since image data for the entire display portion 13 does not need to be transmitted, the transmission quantity of the image data can be reduced. Accordingly, power saving during data transmission can be achieved.

In the case where the sub-display portion 19 includes a light-receiving element, the input/output circuit 442 has a function of outputting information obtained by photoelectric conversion by the light-receiving element to the functional circuit 40. Note that the functional circuit 40 is not necessarily provided in the display apparatus 10B, and an external device that can function as the functional circuit 40 may be connected to the display apparatus 10B. The input and output of a signal between the external device and the display apparatus 10B can be performed through the terminal portion 14.

A circuit other than the timing generation circuit 441, the input/output circuit 442, and the memory circuit 443 may be provided in each of the sections 39.

The display apparatus 10B has a structure in which the source driver circuit 31 and the gate driver circuit 33 are provided in each of the sections 39. Thus, the display portion 13 can be divided into the sections 59 corresponding to the sections 39, and image data rewriting can be performed in each section. For example, in the display portion 13, image data rewriting can be performed only in a section with a change in image and image data can be retained in a section with no change, so that power consumption can be reduced.

In this specification and the like, one of the portions of the display portion 13 that are divided so as to correspond to the sections 59 is sometimes referred to as the sub-display portion 19. Since one section 59 is controlled by one section 39, the sub-display portion 19 can be regarded as a portion of the display portion 13 that is divided so as to correspond to the section 39. The display portion 13 is constituted by a plurality of sub-display portions 19. Thus, the display portion 13 can also be regarded as including the plurality of sub-display portions 19. In the display apparatus 10B described with reference to FIG. 6A, FIG. 6B, and FIG. 7A to FIG. 7C, the display portion 13 is divided into 32 sub-display portions 19 in four rows and eight columns. Note that the number of the sub-display portions 19 included in the display portion 13 is not limited to that.

Like the display portion 13, the sub-display portion 19 also includes a plurality of pixels 230. The sub-display portion 19 is controlled in each section 59, and one of the sections 59 is controlled by the corresponding one of the sections 39. That is, image display operation in one sub-display portion 19 is performed by a plurality of light-emitting elements 61, one section 59, and one section 39 in an integrated manner. Thus, unless otherwise specified, the “sub-display portion 19” in this specification and the like may include a plurality of light-emitting elements 61, one section 59, and one section 39.

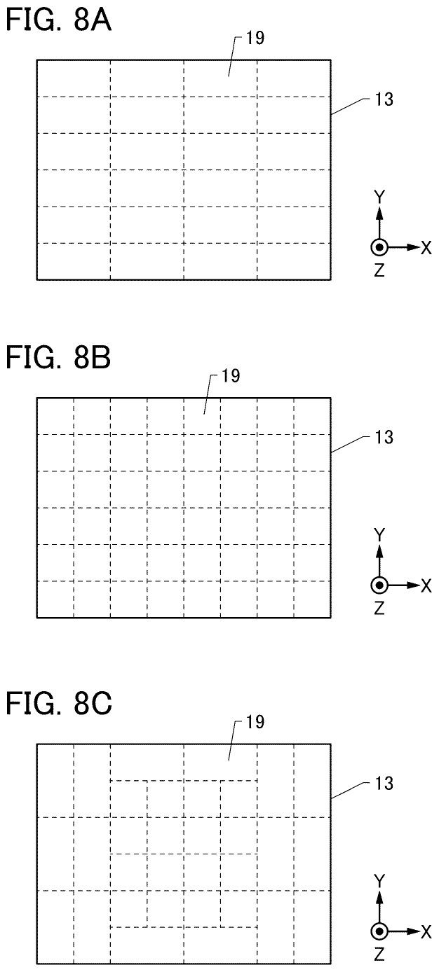

Although one sub-display portion 19 is shown as a vertically long rectangle when the display portion 13 is seen in the Z direction in FIG. 6A, the planar shape of the sub-display portion 19 is not limited to that. The planar shape of one sub-display portion 19 may differ depending on the shape and the number of divisions of the display portion 13. For example, as shown in FIG. 8A, the planar shape of the sub-display portion 19 may be a horizontally long rectangle. As shown in FIG. 8B, the planar shape of the sub-display portion 19 may be a square. As shown in FIG. 8C, the display portion 13 may have a structure in which vertically long sub-display portions 19, horizontally long sub-display portions 19, and square sub-display portions 19 are combined.

In the display apparatus 10B, driving frequency at the time of displaying an image can be set freely for each of the sub-display portions 19 by the timing generation circuit 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 19 arranged in a matrix. In addition, the functional circuit 40 has a function of adjusting synchronization between the sub-display portions.

For example, power consumption can be reduced by detecting a user's gaze point on the display portion 13 and making the driving frequency differ among the sub-display portions 19 in accordance with movement of the gaze point (in accordance with motion of the user's gaze).

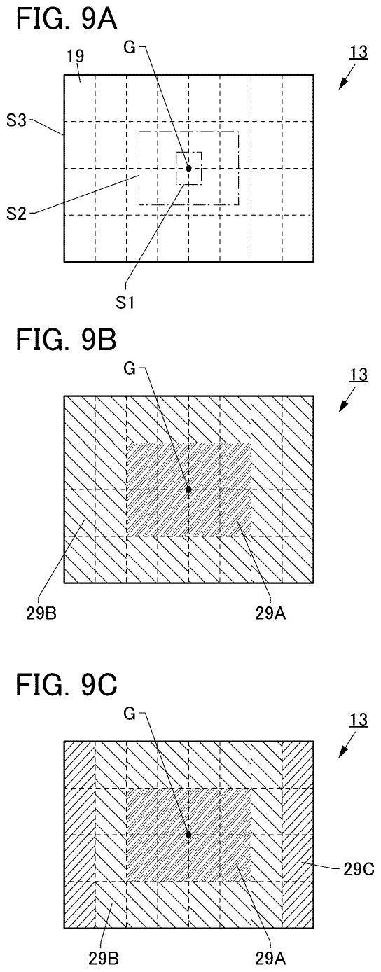

FIG. 9A shows the display portion 13 including the sub-display portions 19 in four rows and eight columns. FIG. 9A also shows a first region S1 to a third region S3 with a gaze point G on the display portion 13 as the center. The plurality of sub-display portions 19 are divided between a first section 29A overlapping with the first region S1 or the second region S2 and a second section 29B overlapping with the third region S3. In other words, the plurality of sections 39 are divided between the first section 29A and the second section 29B. The first section 29A includes a region overlapping with the gaze point G. Furthermore, the second section 29B includes the sub-display portions 19 positioned outside the first section 29A (see FIG. 9B).

Each of the above sections corresponds to the block described in Embodiment 1.

The operations of the driver circuits (the source driver circuit 31 and the gate driver circuit 33) included in each of the plurality of sections 39 are controlled by the functional circuit 40. For example, the second section 29B is a section overlapping with the third region S3 including later-described stable visual field, inducting visual field, and supplementary visual field, and is hard for the user to discriminate. Thus, the user perceives a small reduction in practical display quality (hereinafter also referred to as “practical display quality”) even when the number of times of image data rewriting per unit time (hereinafter also referred to as “image rewriting frequency”) at the time of displaying an image is smaller in the second section 29B than in the first section 29A. In other words, a reduction in practical display quality is small even when the driving frequency of the sub-display portions 19 included in the second section 29B (also referred to as a “second driving frequency”) is lower than the driving frequency of the sub-display portions 19 included in the first section 29A (also referred to as a “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be inhibited. According to one embodiment of the present invention, both display quality maintenance and a reduction in power consumption can be achieved.

The first driving frequency is higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency. Note that “fps” is sometimes used instead of “Hz” as the unit of the driving frequency (frame rate).

A section of the sub-display portions 19 overlapping with the third region S3 that is farther from the first section 29A may be set as a third section 29C (see FIG. 9C), and driving frequency of the sub-display portions 19 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering image rewriting frequency, power consumption can be further reduced. If necessary, image data rewriting may be stopped. By stopping image data rewriting, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as a transistor 52A.

In some cases, an image whose brightness, contrast, color tone, or the like is greatly different from that of the previous image is displayed as in the case where a video scene displayed on the display portion 13 is changed, for example. Such a case causes a mismatch of the timing at which an image is changed between the first section 29A and a section whose driving frequency is lower than that of the first section 29A. This may cause a great difference in the brightness, contrast, color tone, or the like between the sections, leading to the loss of the practical display quality. In such a case where a video scene is changed, image data rewriting is temporarily performed in the sections other than the first section 29A at a driving frequency which is the same as that of the first section 29A, and then the driving frequency of the sections other than the first section 29A is decreased.

Furthermore, in the case where the fluctuation amount of the gaze point G is judged to be exceeding a certain value, image data rewriting may be performed in the sections other than the first section 29A at a driving frequency which is the same as that of the first section 29A, and in the case where the fluctuation amount is judged to be less than or equal to the certain value, the driving frequency of the sections other than the first section 29A may be decreased. In the case where the fluctuation amount of the gaze point G is judged to be small, the driving frequency of the sections other than the first section 29A may be further decreased.

In the case where the display apparatus 10B does not include a frame memory, which retains image data, or includes one frame memory for the entire display portion 13, each of the second driving frequency and the third driving frequency needs to be an integral submultiple of the first driving frequency.

When the plurality of sub-display portions 19 are provided with respective frame memories, each of the second driving frequency and the third driving frequency can be set to a given value without limitation to an integral submultiple of the first driving frequency. When the second driving frequency and the third driving frequency are set to given values, the degree of freedom in setting the driving frequencies can be increased. As a result, a reduction in the practical display quality can be small.

Note that sections set for the display portion 13 are not limited to the three sections of the first section 29A, the second section 29B, and the third section 29C. Four or more sections may be set for the display portion 13. When a plurality of sections are set for the display portion 13 and the driving frequencies of the sections are gradually decreased, a reduction in the practical display quality can be smaller.

The above-described upconversion processing may be performed on an image to be displayed in the first section 29A. When an image obtained by the upconversion processing is displayed in the first section 29A, the display quality can be increased. The above-described upconversion processing may be performed on an image to be displayed in the sections other than the first section 29A. When an image obtained by the upconversion processing is displayed in the sections other than the first section 29A, a reduction in the practical display quality that occurs in the case where the driving frequency of the sections other than the first section 29A is decreased can be smaller.

Note that the upconversion processing of an image to be displayed in the first section 29A may be performed using an algorithm with high accuracy, and the upconversion processing of an image to be displayed in the sections other than the first section 29A may be performed using an algorithm with low accuracy. A reduction in the practical display quality that occurs in the case where the driving frequency of the sections other than the first section 29A is decreased can be smaller also in such a case.

In the case where the definition of image data is higher than the definition of the display portion 13, or in the case where high-speed rewriting and low power consumption have a priority, for example, downconversion processing may be performed on an image to be displayed in the sections other than the first section 29A in accordance with the purpose or the like. For example, high-speed rewriting and low power consumption can be achieved by rewriting an image to be displayed in the sections other than the first section 29A every several rows, every several columns, or every several pixels.

The definitions (amounts of information) of images displayed in the sections other than the first section 29A including the gaze point are lower (smaller) than that of an image to be displayed on the first section 29A, reducing the load during video signal generation (rendering). Such processing is also referred to as “foveated rendering”. When foveated rendering is combined with a reduction in driving frequency of the sections other than the first section 29A, power consumption can be further reduced while a reduction in display quality is inhibited.

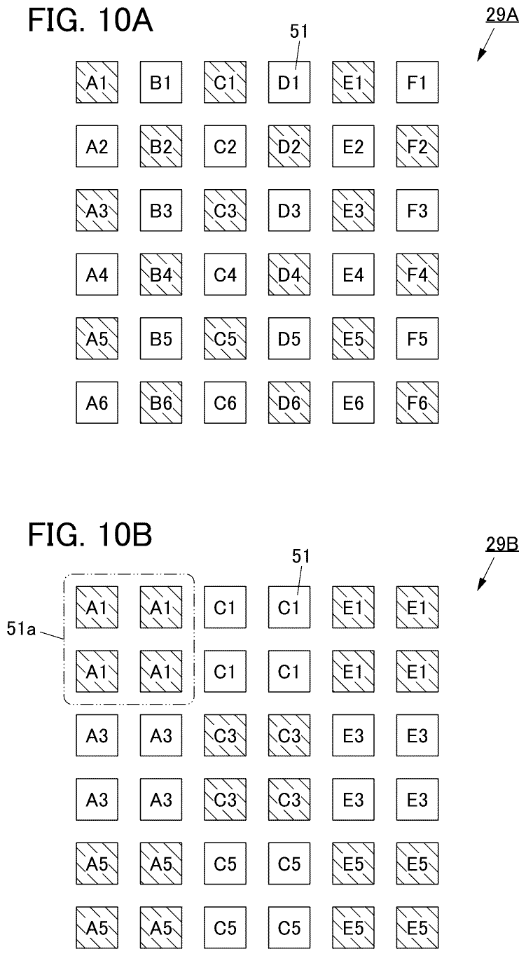

An example of foveated rendering will be described with reference to FIG. 10A and FIG. 10B. The case where an image is displayed with a normal definition in the first section 29A and the image is displayed with a half of the normal definition in the second section 29B will be described as an example.

The upconversion processing, the downconversion processing, the foveated rendering processing, and the like accompanying the display method described as an example here are equivalent to the interpolation processing for interpolating missing data, which is exemplified in Embodiment 1. In particular, such processing can be used as a method for recovering image data in which data is thinned out in each section (block).

FIG. 10A shows part of the plurality of pixel circuits 51 included in the first section 29A. FIG. 10A shows 36 pixel circuits 51 arranged in a matrix of six rows and six columns as an example. One piece of image data is written to one pixel circuit 51. Thirty six pieces of image data denoted as image data A1 to image data A6, image data B1 to image data B6, image data C1 to image data C6, image data D1 to image data D6, image data E1 to image data E6, and image data F1 to image data F6 are written to the 36 pixel circuits 51 shown in FIG. 10A.

FIG. 10B shows part of the plurality of pixel circuits 51 included in the second section 29B. In the second section 29B, four adjacent pixel circuits 51 are used as one pixel circuit. In FIG. 10B, the four pixel circuits 51 used as one pixel circuit are denoted as a pixel circuit 51a. The same image data is written to the four pixel circuits 51 included in the pixel circuit 51a.

For example, the image data A1 is written to the four pixel circuits 51 included in the pixel circuit 51a. In that case, the image data A2, the image data B1, and the image data B2 are not used; thus, the amount of information in image data transmitted to the sub-display portion 19 (the section 39) can be reduced.

Similarly, in the case where the image data C1 is written to the four pixel circuits 51 included in the pixel circuit 51a, the image data C2, the image data D1, and the image data D2 are not used. Thus, the amount of information in image data transmitted to the sub-display portion 19 (the section 39) can be reduced.

For example, in the case where the definition of the sub-display portion 19 included in the first section 29A is 480×720 pixels, the definition of the sub-display portion 19 included in the second section 29B can be regarded as 240×360 pixels. Thus, the amount of information in image data transmitted to the sub-display portion 19 (the section 39) included in the second section 29B is ¼ of that in the first section 29A.

When nine adjacent pixel circuits 51 are used as one pixel circuit, the definition can be regarded as 160×240 pixels. In that case, the amount of information in image data transmitted to the sub-display portion 19 (the section 39) included in the second section 29B is 1/9 of that in the first section 29A.

As described above, the amount of information in image data transmitted to the sub-display portion 19 can be reduced by a reduction in the apparent definition of the sub-display portion 19. The reduction in the amount of information in image data used for image display enables a reduction in the load on circuits included in the section 39, such as the input/output circuit 442, the memory circuit 443, and the driver circuits.

When image data rewriting performed in each of the sub-display portions 19 is performed concurrently in all of the sub-display portions 19, high-speed rewriting can be achieved. In other words, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of a line sequential driving. In the case where the display portion 13 is not divided into the plurality of sub-display portions 19 and the definition is 4000×2000 pixels, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select pixels in 2000 rows in approximately 8.3 msec, and the time for selecting pixels in one row, that is, the time for writing image data to each pixel is approximately 4.17 μsec. In other words, it becomes more difficult to ensure sufficient time for rewriting image data as the definition of the display portion increases or as the frame frequency increases.

The display portion 13 of the display apparatus 10B described as an example in this embodiment is divided into four parts in the row direction. Thus, the time for writing image data to each pixel in one sub-display portion 19 can be four times as long as that of the case where the display portion 13 is not divided. According to one embodiment of the present invention, the time for rewriting image data can be easily ensured even in the case where frame frequency is 240 Hz or 360 Hz; thus, a display apparatus with high display quality can be obtained.

Since the display portion 13 of the display apparatus 10B described as an example in this embodiment is divided into four parts in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 13 of the display apparatus 10B described as an example in this embodiment is divided into eight parts in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be inhibited and the time for rewriting image data can be easily ensured.

With the display apparatus 10B of one embodiment of the present invention, sufficient time for writing image data can be easily ensured, and thus high-speed rewriting of a display image can be achieved. Thus, a display apparatus with high display quality can be obtained. In particular, a display apparatus that excels in displaying a moving image can be obtained.

### Structure Example of Display Module

Next, a structure example of a display module including the display apparatus 10 (the display apparatus 10A or the display apparatus 10B) will be described.

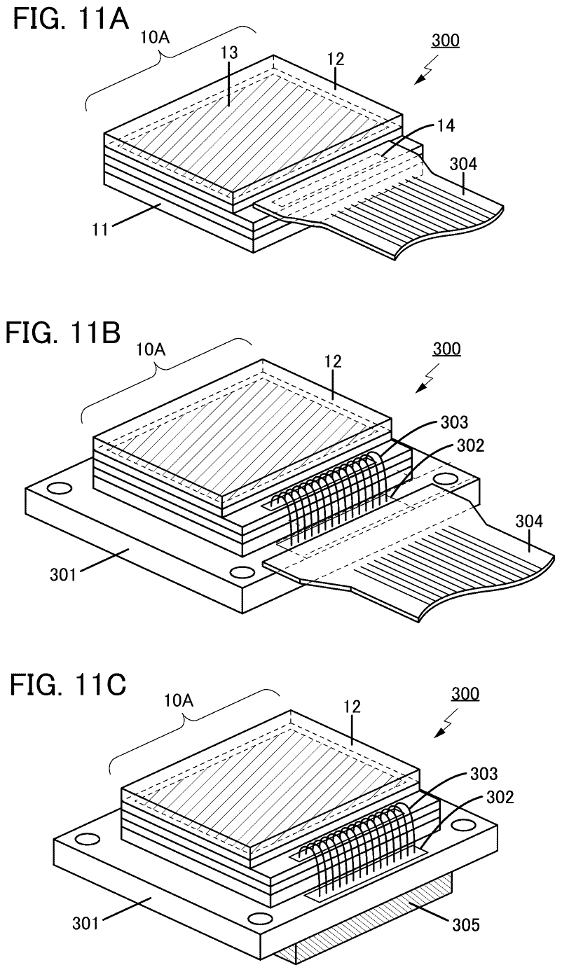

FIG. 11A to FIG. 11C are each a perspective view of a display module 300. The display module 300 has a structure in which an FPC 304 (Flexible printed circuit) is provided on the terminal portion 14 of the display apparatus 10A. The FPC 304 has a structure in which a film formed of an insulator is provided with a wiring. The FPC 304 is flexible. The FPC 304 functions as a wiring for supplying a video signal, a control signal, a power supply potential, and the like to the display apparatus 10A from the outside. An IC may be mounted on the FPC 304.

The display module 300 shown in FIG. 11B has a structure in which the display apparatus 10A is provided over a printed wiring board 301. The printed wiring board 301 has a structure in which wirings are provided inside a substrate formed of an insulator and/or on the surface of the substrate.

In the display module 300 shown in FIG. 11B, the terminal portion 14 of the display apparatus 10A is electrically connected to a terminal portion 302 of the printed wiring board 301 through a wire 303. The wire 303 can be formed in wire bonding. Ball bonding or wedge bonding can be used as the wire bonding.

After the wire 303 is formed, the wire 303 may be covered with a resin material or the like. Note that the display apparatus 10A and the printed wiring board 301 may be electrically connected to each other by a method other than the wire bonding. For example, the display apparatus 10A and the printed wiring board 301 may be electrically connected to each other using an anisotropic conductive adhesive or a bump.

In the display module 300 shown in FIG. 11B, the terminal portion 302 of the printed wiring board 301 is electrically connected to the FPC 304. In the case where the electrode pitch in the terminal portion 14 of the display apparatus 10A is different from the electrode pitch in the FPC 304, for example, the terminal portion 14 may be electrically connected to the FPC 304 via the printed wiring board 301. Specifically, the interval (pitch) between a plurality of electrodes in the terminal portion 14 can be converted into the interval between a plurality of electrodes in the terminal portion 302 using wirings formed on the printed wiring board 301. That is, even when the electrode pitch in the terminal portion 14 is different from the electrode pitch in the FPC 304, electrical connection between the electrodes can be achieved.

The printed wiring board 301 can be provided with a variety of elements such as a resistor element, a capacitor element, and a semiconductor element.

As in the display module 300 shown in FIG. 11C, the terminal portion 302 may be electrically connected to a connection portion 305 provided on the bottom surface (a surface where the display apparatus 10A is not provided) of the printed wiring board 301. With the use of a socket-type connection portion as the connection portion 305, for example, the display module 300 can be easily attached to and detached from another device.

### Structure Example of Pixel Circuit

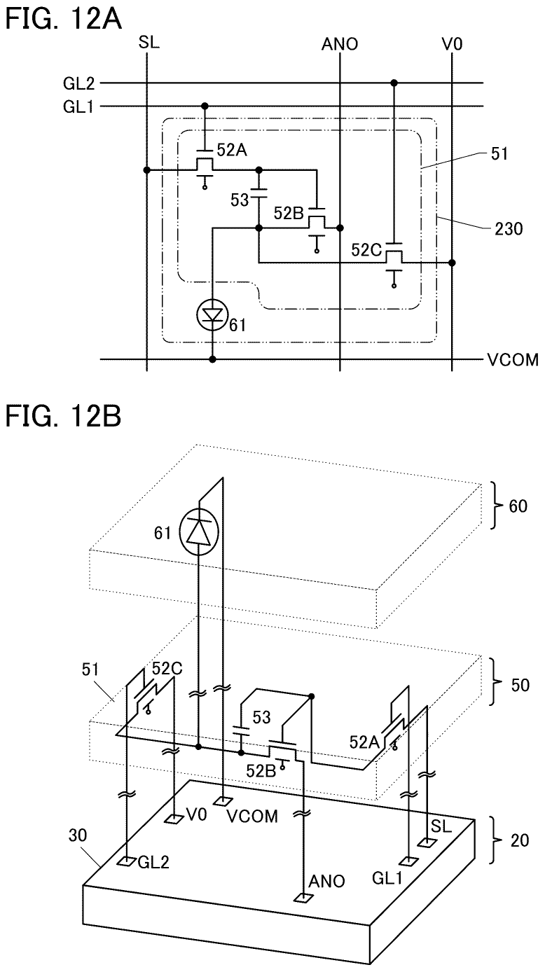

FIG. 12A and FIG. 12B show a structure example of the pixel circuit 51 and the light-emitting element 61 connected to the pixel circuit 51. FIG. 12A is a diagram showing connection of the elements, and FIG. 12B is a diagram schematically showing the vertical position relation of the layer 20 including the driver circuit, the layer 50 including a plurality of transistors of the pixel circuit, and the layer 60 including the light-emitting element.

The pixel circuit 51 shown as an example in FIG. 12A and FIG. 12B includes a transistor 52A, a transistor 52B, a transistor 52C, and a capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes the gate electrode electrically connected to the transistor 52A, a first electrode electrically connected to the light-emitting element 61, and a second electrode electrically connected to a wiring ANO. The wiring ANO is a wiring for supplying a potential for supplying a current to the light-emitting element 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to a wiring V0, a second terminal electrically connected to the light-emitting element 61, and the gate electrode having a function of controlling the conduction state or non-conduction state on the basis of the potential of a wiring GL2 which functions as a gate line. The wiring V0 is a wiring for supplying a reference potential and a wiring for outputting a current flowing through the pixel circuit 51 to the driver circuit 30 or the functional circuit 40.

The capacitor 53 includes a conductive film electrically connected to the gate electrode of the transistor 52B and a conductive film electrically connected to the second electrode of the transistor 52C.

The light-emitting element 61 includes a first electrode electrically connected to the first electrode of the transistor 52B and a second electrode electrically connected to a wiring VCOM. The wiring VCOM is a wiring for supplying a potential for supplying a current to the light-emitting element 61.

Accordingly, the intensity of light emitted from the light-emitting element 61 can be controlled in accordance with an image signal supplied to the gate electrode of the transistor 52B. Furthermore, variations in voltage between the gate and the source of the transistor 52B can be inhibited by the reference potential of the wiring V0 supplied through the transistor 52C.

A current value that can be used for setting pixel parameters can be output from the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting element described in one embodiment of the present invention refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

Note that in the structure shown as an example in FIG. 12B, the wirings electrically connecting the pixel circuit 51 and the driver circuit 30 can be shortened, so that wiring resistance of the wirings can be reduced. Thus, data can be written at high speed, which enables high-speed driving of the display apparatus 10A. Thus, even when the number of the pixel circuits 51 included in the display apparatus 10A is increased, a sufficiently long frame period can be ensured, and thus, the pixel density of the display apparatus 10A can be increased. In addition, the increased pixel density of the display apparatus 10A can increase the resolution of an image displayed by the display apparatus 10A. For example, the pixel density of the display apparatus 10A can be higher than or equal to 1000 ppi, higher than or equal to 5000 ppi, or higher than or equal to 7000 ppi. Thus, the display apparatus 10A can be, for example, a display apparatus for AR or VR and can be suitably used in an electronic device with a short distance between a display portion and the user, such as an HMD.

Although FIG. 12A and FIG. 12B show, as an example, the pixel circuit 51 including three transistors in total, one embodiment of the present invention is not limited thereto. Structure examples and a driving method example of a pixel circuit which can be used for the pixel circuit 51 will be described below.

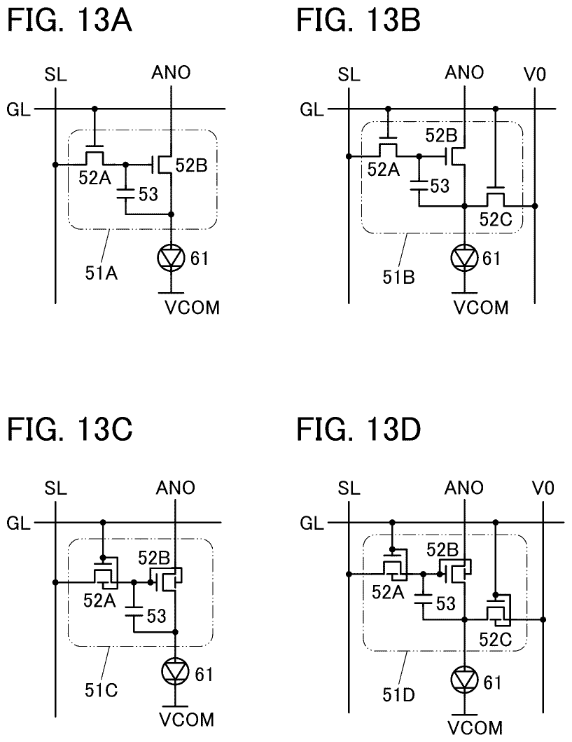

A pixel circuit 51A shown in FIG. 13A includes the transistor 52A, the transistor 52B, and the capacitor 53. FIG. 13A shows the light-emitting element 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 shown in FIG. 12A and the wiring GL1 and the wiring GL2 are replaced with the wiring GL.

The gate of the transistor 52A is electrically connected to the wiring GL, one of the source and the drain of the transistor 52A is electrically connected to the wiring SL, and the other of the source and the drain of the transistor 52A is electrically connected to the gate of the transistor 52B and one electrode of a capacitor C1. One of the source and the drain of the transistor 52B is electrically connected to the wiring ANO, and the other of the source and the drain of the transistor 52B is electrically connected to an anode of the light-emitting element 61. The other electrode of the capacitor C1 is electrically connected to the anode of the light-emitting element 61. A cathode of the light-emitting element 61 is electrically connected to the wiring VCOM.

A pixel circuit 51B shown in FIG. 13B has a structure in which a transistor 52C is added to the pixel circuit 51A. In addition, the wiring V0 is electrically connected to the pixel circuit 51B.

A pixel circuit 51C shown in FIG. 13C is an example of the case where a transistor in which a pair of gates are electrically connected to each other is used as each of the transistor 52A and the transistor 52B of the pixel circuit 51A. A pixel circuit 51D shown in FIG. 13D is an example of the case where such transistors are used in the pixel circuit 51B. Thus, a current that can flow through the transistors can be increased. Note that although a transistor in which a pair of gates are electrically connected to each other is used for each of the transistors here, one embodiment of the present invention is not limited thereto. A transistor that includes a pair of gates electrically connected to different wirings may be used. When, for example, a transistor in which one of the gates is electrically connected to the source is used, the reliability can be increased.

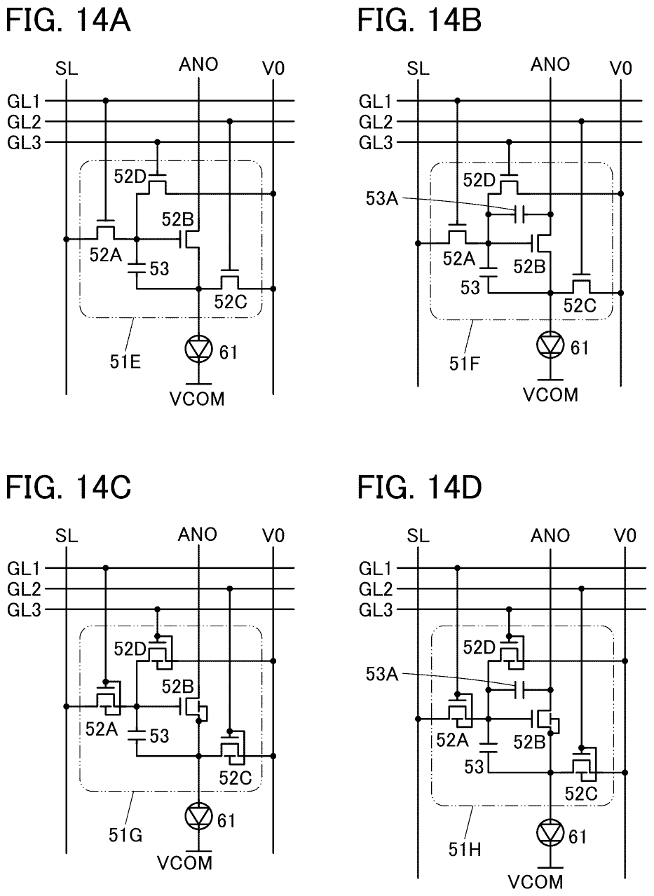

A pixel circuit 51E shown in FIG. 14A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and includes a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are brought into a conduction state at the same time, the source and the gate of the transistor 52B have the same potential, so that the transistor 52B can be brought into a non-conduction state. Thus, a current flowing to the light-emitting element 61 can be blocked forcibly. Such a pixel circuit is suitable for the case of using a display method in which a display period and a non-lighting period are alternately provided.

A pixel circuit 51F shown in FIG. 14B is an example of the case where a capacitor 53A is added to the pixel circuit 51E. The capacitor 53A functions as a storage capacitor.

A pixel circuit 51G shown in FIG. 14C and a pixel circuit 51H shown in FIG. 14D are respectively examples of the cases where transistors each including a pair of gates are used in the pixel circuit 51E and the pixel circuit 51F. A transistor in which a pair of gates are electrically connected to each other is used as each of the transistor 52A, the transistor 52C, and the transistor 52D, and a transistor in which one of gates is electrically connected to a source is used as the transistor 52B.

Next, an example of a method for driving a display apparatus in which the pixel circuit 51E is used will be described. Note that a similar driving method can be applied to display apparatuses in which the pixel circuits 51F, 51G, and 51H are used.

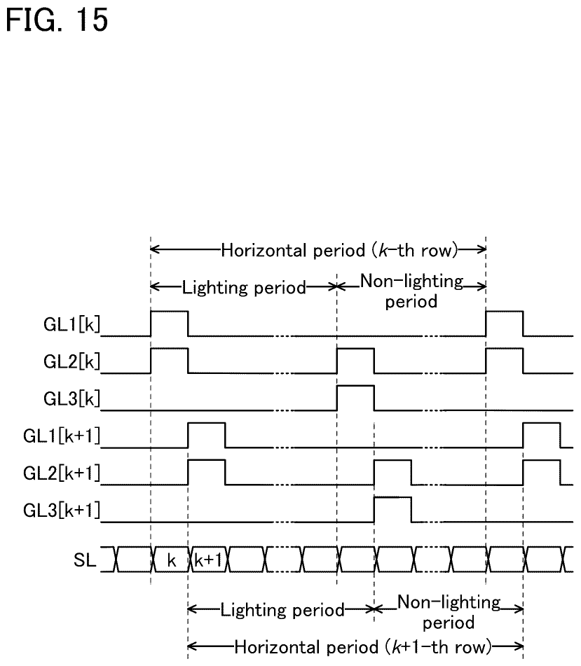

FIG. 15 shows a timing chart of a method for driving the display apparatus in which the pixel circuit 51E is used. Changes in the potentials of a wiring GL1[k], a wiring GL2[k], and a wiring GL3[k] that are gate lines of the k-th row and a wiring GL1[k+1], a wiring GL2[k+1], and a wiring GL3[k+1] that are gate lines of the k+1-th row are shown here. FIG. 15 also shows the timing of supplying a signal to the wiring SL functioning as a source line.

Here, an example of the driving method in which one horizontal period is divided into a lighting period and a non-lighting period is shown. A horizontal period of the k-th row is shifted from a horizontal period of the k+1-th row by a selection period of the gate line.

In the lighting period of the k-th row, first, the wiring GL1[k] and the wiring GL2[k] are supplied with a high-level potential and the wiring SL is supplied with a source signal. Thus, the transistor 52A and the transistor 52C are brought into a conduction state, so that a potential corresponding to the source signal is written from the wiring SL to the gate of the transistor 52B. After that, the wiring GL1[k] and the wiring GL2[k] are supplied with a low-level potential, so that the transistor 52A and the transistor 52C are brought into a non-conduction state and the gate potential of the transistor 52B is retained.

Subsequently, in a lighting period of the k+1-th row, data is written by an operation similar to that described above.

Next, the non-lighting period is described. In the non-lighting period of the k-th row, the wiring GL2[k] and the wiring GL3[k] are supplied with a high-level potential. Accordingly, the transistor 52C and the transistor 52D are brought into a conduction state, and the source and the gate of the transistor 52B are supplied with the same potential, so that almost no current flows through the transistor 52B. Thus, the light-emitting element 61 is turned off. All the subpixels that are positioned in the k-th row are turned off. The subpixels of the k-th row remain in the non-lighting state until the next lighting period.

Subsequently, in a non-lighting period of the k+1-th row, all the subpixels of the k+1-th row are in the non-lighting state in a manner similar to that described above.

Such a driving method described above, in which the pixels are not constantly on through one horizontal period and a non-lighting period is provided in one horizontal period, can be called duty driving. With duty driving, an afterimage phenomenon can be inhibited at the time of displaying moving images; thus, a display apparatus with high performance in displaying moving images can be obtained. Particularly in a VR device and the like, a reduction in an afterimage can reduce what is called VR sickness.

In the duty driving, the proportion of the lighting period in one horizontal period can be called a duty cycle. For example, a duty cycle of 50% means that the lighting period and the non-lighting period have the same length. Note that the duty cycle can be set freely and can be adjusted appropriately within a range higher than 0% and lower than or equal to 100%, for example.

At least part of the structure examples, the drawings corresponding thereto, and the like described in this embodiment can be combined with the other structure examples, the other drawings, and the like as appropriate.

### Embodiment 3

In this embodiment, examples of electronic devices in which the display apparatus of one embodiment of the present invention can be used will be described. The display apparatus of one embodiment of the present invention can be suitably used in a wearable electronic device for VR or AR applications, for example.

### Structure Example of Electronic Device

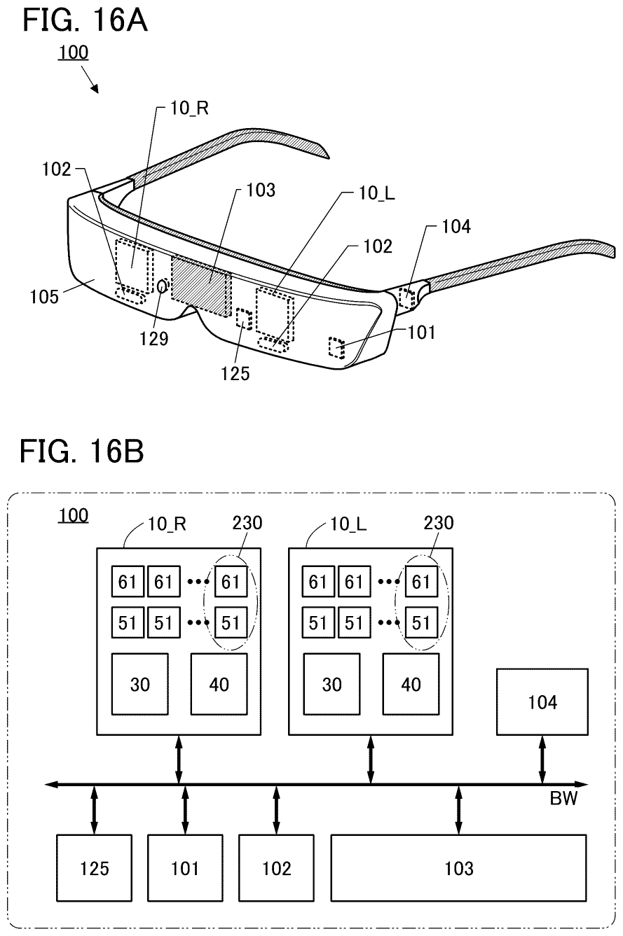

FIG. 16A shows a perspective view of a glasses-type (goggles-type) electronic device 100 as an example of a wearable electronic device. FIG. 16A shows the electronic device 100 that includes, in a housing 105, a pair of display apparatuses 10 (a display apparatus 10_L and a display apparatus 10_R), a motion detection portion 101, gaze detection portions 102, an arithmetic portion 103, and a communication portion 104. As the display apparatus 10 included in the electronic device 100, the display apparatus 10A or the display apparatus 10B described in the above embodiment can be used.

Here, the arithmetic portion 103 may have the functions of the image generation portion and the data generation portion exemplified in Embodiment 1. Either the gaze detection portion 102 or the arithmetic portion 103 may have the function of the coordinate detection portion exemplified in Embodiment 1.

FIG. 16B is a block diagram of the electronic device 100 in FIG. 16A. As in FIG. 16A, the electronic device 100 includes the display apparatus 10_L, the display apparatus 10_R, the motion detection portion 101, the gaze detection portions 102, the arithmetic portion 103, and the communication portion 104, and a variety of signals are transmitted and received between these components through a bus wiring BW. Each of the display apparatus 10_L and the display apparatus 10_R includes a plurality of pixels 230, a driver circuit 30, and a functional circuit 40. Note that the functional circuit 40 is not necessarily provided in one or both of the display apparatus 10_L and the display apparatus 10_R, and the arithmetic portion 103 may be used as the functional circuit 40. One pixel 230 includes one light-emitting element 61 and one pixel circuit 51. Thus, each of the display apparatus 10_L and the display apparatus 10_R includes a plurality of light-emitting elements 61 and a plurality of pixel circuits 51.

The motion detection portion 101 has a function of detecting the motion of the housing 105, i.e., the motion of the head of the user who wears the electronic device 100. The motion detection portion 101 can include a motion sensor using a MEMS technology, for example. As the motion sensor, a three-axis motion sensor, a six-axis motion sensor, or the like can be used. Information on the motion of the housing 105 detected by the motion detection portion 101 is referred to as “first information” or “motion information” in some cases in this specification and the like.

The gaze detection portion 102 has a function of obtaining information regarding the user's gaze. Specifically, the gaze detection portion 102 has a function of detecting the user's gaze. The user's gaze, for example, is obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like.

The arithmetic portion 103 has a function of calculating the user's gaze point by using a gaze detection result in the gaze detection portion 102. That is, an object the user is gazing in the image being displayed on the display apparatus 10_L and the display apparatus 10_R can be found. In addition, whether or not the user is gazing at a part other than the screen can be found. Note that information on the user's gaze obtained by the gaze detection portion 102 (the gaze detection result) is referred to as “second information” or “gaze information” in some cases in this specification and the like.

The arithmetic portion 103 has a function of performing drawing processing (arithmetic process of image data) in accordance with the motion of the housing 105. The arithmetic portion 103 performs the drawing processing in accordance with the motion of the housing 105 with the use of the first information and image data that is input from the outside through the communication portion 104. As the image data, for example, 360-degree omnidirectional image data can be used. The 360-degree omnidirectional image data may be image data captured by a celestial sphere camera (an omnidirectional camera or a 360° camera) or image data generated by computer graphics, for example. The arithmetic portion 103 has a function of converting the 360-degree omnidirectional image data on the basis of the first information into image data that can be displayed on the display apparatus 10_L and the display apparatus 10_R.

The arithmetic portion 103 has a function of determining the size and shape of a plurality of regions that are set for each of the display portions of the display apparatus 10_L and the display apparatus 10_R with use of the second information. Specifically, the arithmetic portion 103 calculates a gaze point on the display portion on the basis of the second information and sets a first region S1 to a third region S3 and the like on the display portion with use of the gaze point as a reference.

A microprocessor such as a central processing unit (CPU), a DSP (Digital Signal Processor), or a GPU (Graphics Processing Unit) can be used alone or in combination as the arithmetic portion 103. A structure may be employed in which such a microprocessor is obtained with a PLD (Programmable Logic Device) such as an FPGA (Field Programmable Gate Array) or an FPAA (Field Programmable Analog Array).

The arithmetic portion 103 interprets and executes instructions from various programs with the use of a processor to perform various kinds of data processing and program control. The programs that might be executed by the processor may be stored in a memory region included in the processor or a memory portion which is additionally provided. As the memory portion, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) and an SRAM (Static RAM); or the like may be used, for example.

The communication portion 104 has a function of communicating with an external device by wire or wirelessly to obtain a variety of data, including image data. The communication portion 104 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication device using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication portion 104 may include an external port such as a LAN (Local Area Network) connection terminal, a digital broadcast-receiving terminal, or an AC adaptor connection terminal.

Each of the display apparatus 10_L and the display apparatus 10_R includes the plurality of light-emitting elements 61, the plurality of pixel circuits 51, the driver circuit 30, and the functional circuit 40. The pixel circuit 51 has a function of controlling light emission of the light-emitting element 61. The driver circuit 30 has a function of controlling the pixel circuit 51. Note that the functional circuit 40 is not necessarily provided in one or both of the display apparatus 10_L and the display apparatus 10_R, and the arithmetic portion 103 may be used as the functional circuit 40.

Information on the plurality of regions in the display portion of the display apparatus determined by the arithmetic portion 103 can be used for driving such that the definition differs from region to region. The functional circuit 40 has a function of controlling the driver circuit 30 such that the display definition is high in a region close to a gaze point and controlling the driver circuit 30 such that the display definition is low in a region distant from the gaze point.

For example, when image data rewriting is performed for every other pixel or every other plurality of pixels, low display definition can be achieved. By reducing the number of pixels where image data are rewritten, power consumption of the display apparatus can be reduced. Pixels where rewriting is not performed may emit light but preferably do not emit light. By stopping light emission of the pixels where rewriting is not performed, power consumption of the display apparatus can be reduced.

As in one embodiment of the present invention, the arithmetic portion 103 may be provided in addition to the functional circuit 40. Providing the arithmetic portion 103 makes it possible for the arithmetic portion 103 to perform heavy-load arithmetic processing such as drawing processing in accordance with the motion of the housing 105 and determining a plurality of regions described later (the first region S1 to the third region S3) in accordance with a gaze point. Meanwhile, the functional circuit 40 performs the processing of controlling the driver circuit 30, so that reductions in circuit size and power consumption can be achieved. A wearable electronic device in particular is required to detect the motion of the user's head, gaze, or the like in a short period, and thus high speed arithmetic processing is required, leading to high power consumption for an arithmetic operation. By contrast, in one embodiment of the present invention, the function of outputting a control signal for the driver circuit 30 is separated from the arithmetic portion 103 and can be performed by the functional circuit 40. This prevents concentration of load on one arithmetic portion and can reduce the load on the arithmetic portion. Thus, low power consumption as a whole can be achieved.

The electronic device 100 may be provided with a sensor 125. The sensor 125 has a function of obtaining information on one or more of the senses of sight, hearing, touch, taste, and smell of the user. Specifically, the sensor 125 has a function of sensing or measuring one or more of the following information: force, displacement, position, speed, acceleration, angular velocity, rotational frequency, distance, light, magnetism, temperature, sound, time, electric field, current, voltage, electric power, radiation, humidity, gradient, oscillation, smell, and infrared rays. The electronic device 100 may be provided with one or more sensors 125.

With use of the sensor 125, ambient temperature, humidity, illuminance, odor, and the like may be measured. Furthermore, with use of the sensor 125, information for personal authentication using a fingerprint, a palm print, an iris, a retina, a shape of a blood vessel (including a shape of a vein and a shape of an artery), a face, or the like may be obtained, for example. Moreover, with use of the sensor 125, the number of blinks, eyelid behavior, pupil size, body temperature, pulse, oxygen saturation in blood, or the like of the user may be measured, so that the user's fatigue level, health condition, and the like can be detected. The electronic device 100 may sense the user's fatigue level, health condition, and the like and display an alert or the like on the display apparatus 10.

The operation of the electronic device 100 may be controlled by detecting the user's gaze and eyelid movement. Since the user does not need to touch and operate the electronic device 100, an input operation or the like can be achieved with holding nothing in both hands (in a state where both hands are free).

The electronic device 100 may be provided with an image capturing device 129 for capturing an image of the surroundings. An image of the surroundings may be captured by the image capturing device 129 and displayed on the display apparatus 10. Another information or the like superimposed on an image obtained with the image capturing device 129 may be displayed on the display apparatus 10.

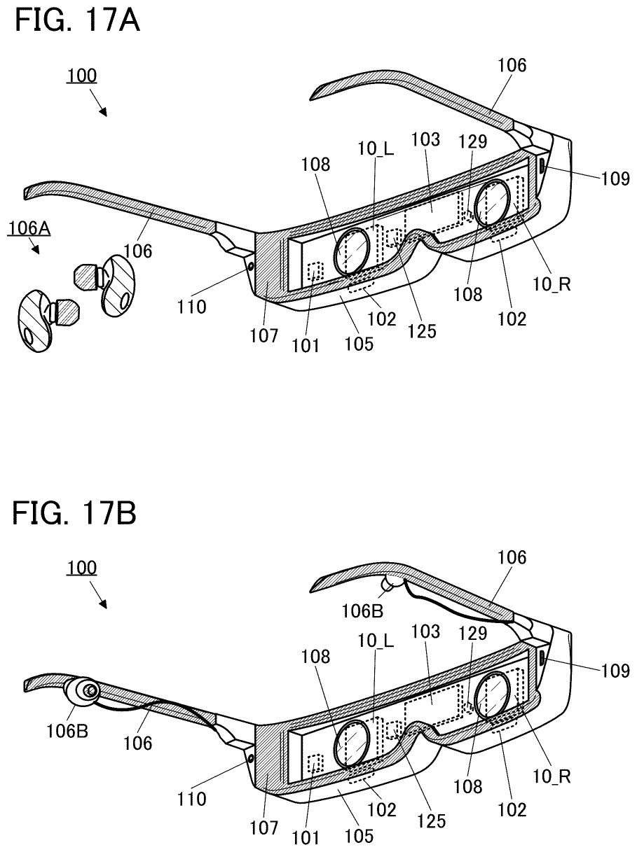

FIG. 17A is a perspective view showing the electronic device 100. In FIG. 17A, the housing 105 of the electronic device 100 includes, for example, a wearing portion 106, a cushion 107, a pair of lenses 108, and the like, in addition to the pair of the display apparatus 10_L and the display apparatus 10_R and the arithmetic portion 103. The pair of the display apparatus 10_L and the display apparatus 10_R are positioned inside the housing 105 so as to be seen through the lenses 108.

In addition, an input terminal 109 and an output terminal 110 are provided in the housing 105 shown in FIG. 17A. To the input terminal 109, a cable for supplying an image signal (image data) from a video output device or the like, power for charging a battery (not shown) provided in the housing 105, or the like can be connected. The output terminal 110 can function as, for example, an audio output terminal to which earphones, headphones, or the like can be connected.

In addition, the housing 105 preferably includes a mechanism by which the left and right positions of the lenses 108 and the display apparatus 10_L and the display apparatus 10_R can be adjusted to the optimal positions in accordance with the positions of the user's eyes. Moreover, the housing 105 preferably includes a mechanism for adjusting focus by changing the distance between the lenses 108 and the display apparatus 10_L and the display apparatus 10_R.

The cushion 107 is a portion to be in contact with the user's face (forehead, cheek, or the like). When the cushion 107 is in close contact with the user's face, external light incidence (light leakage) can be prevented, which increases the sense of immersion. A soft material is preferably used for the cushion 107 so that the cushion 107 is in close contact with the user's face when the user wears the electronic device 100. Using such a material is preferable because it provides a soft texture and the user does not feel cold when wearing the electronic device in a cold season, for example. The member to be in contact with the user's skin, such as the cushion 107 or the wearing portion 106, is preferably detachable, in which case cleaning or replacement can be easily performed.

The electronic device of one embodiment of the present invention may further include earphones 106A. The earphones 106A include a communication portion (not shown) and have a wireless communication function. The earphones 106A can output audio data with the wireless communication function. Note that the earphones 106A may include a vibration mechanism to function as bone-conduction earphones.

The earphones 106A can be connected to the wearing portion 106 directly or by wire like earphones 106B shown in FIG. 17B. The earphones 106B and the wearing portion 106 may each have a magnet. This is preferable because the earphones 106B can be fixed to the wearing portion 106 with magnetic force and thus can be easily housed.

### Example of Operation of Electronic Device

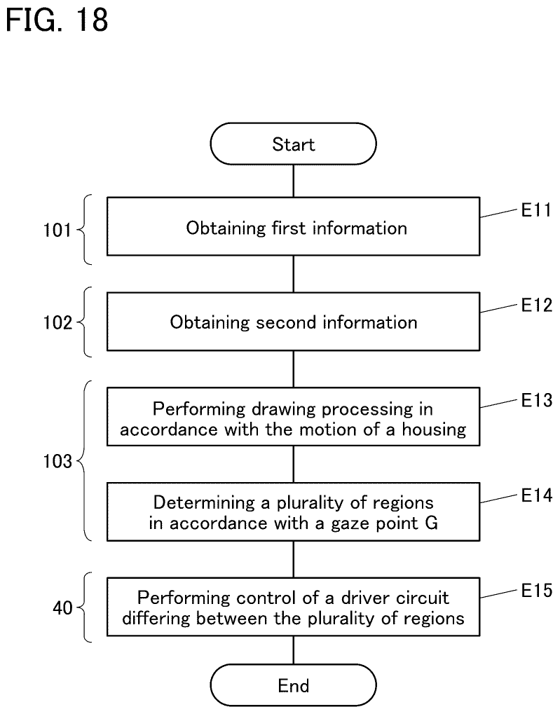

An example of operation of the electronic device 100 will be described with reference to a drawing. FIG. 18 is a flow chart showing the example of operation of the electronic device 100.

The motion detection portion 101 obtains the first information (the information on the motion of the housing 105) (Step E11).

The gaze detection portion 102 obtains the second information (the information on the user's gaze) (Step E12).

The arithmetic portion 103 performs drawing processing of 360-degree omnidirectional image data on the basis of the first information (Step E13).

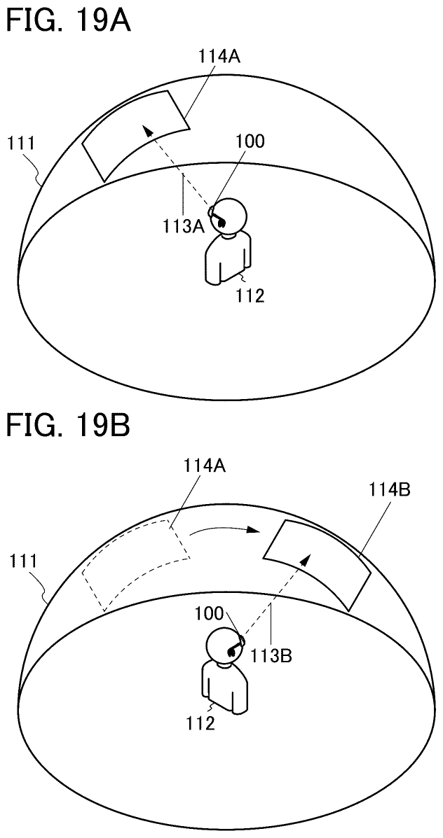

Step E13 is described by giving a specific example. A schematic view in FIG. 19A shows a user 112 positioned at the center of 360-degree omnidirectional image data 111. The user can see an image 114A that is displayed on the display apparatus 10 of the electronic device 100 and that is in a direction 113A.

A schematic view in FIG. 19B shows the state where the user 112 that has been in the state of the schematic view in FIG. 19A moves his/her head to see an image 114B that is in a direction 113B. The image 114A changes into the image 114B in accordance with the motion of the housing of the electronic device 100, so that the user 112 can perceive the space expressed by the 360-degree omnidirectional image data 111.

As shown in FIG. 19A and FIG. 19B, the housing of the electronic device 100 moves in accordance with the motion of the head of the user 112. When the image obtained from the 360-degree omnidirectional image data 111 is an image processed with higher drawing processing capacity in accordance with the motion of the electronic device 100, the user 112 can recognize a virtual space matching a real-world space.

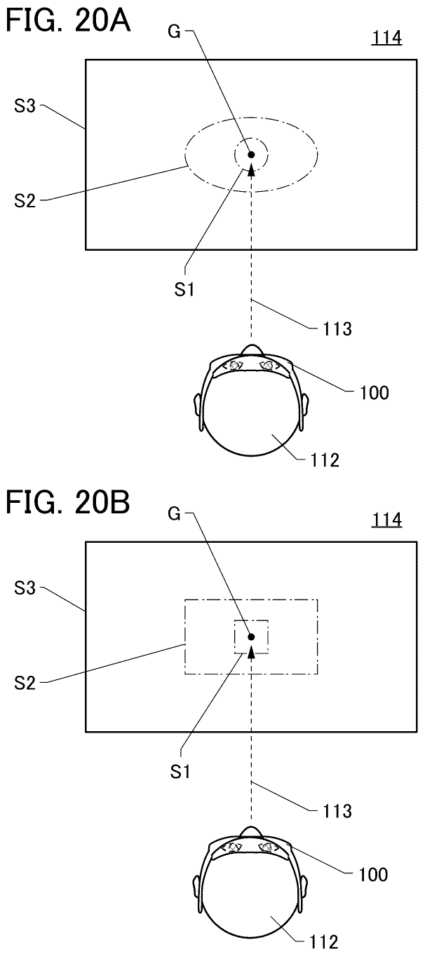

The arithmetic portion 103 determines a plurality of regions of the display portion in the display apparatus in accordance with a gaze point G based on the second information (Step E14). As shown in FIG. 20A, the first region S1 including the gaze point G is determined, and the second region S2 adjacent to the first region S1 is determined, for example. Furthermore, the outside of the second region is the third region S3.

Step E14 is described by giving a specific example.

In general, the human visual field is roughly classified into the following five fields, although varying between individuals. The discrimination visual field refers to a region within approximately 5° from the center of vision (a region including a gaze point), where visual performance such as eyesight and color identification is the most excellent. The effective visual field refers to a region that is horizontally within approximately 30° and vertically within approximately 20° from the center of vision (a gaze point) and adjacent to the outside of the discrimination visual field, where instant identification of particular information is possible only with an eye movement. The stable visual field refers to a region that is horizontally within approximately 90° and vertically within approximately 70° from the center of vision and adjacent to the outside of the effective visual field, where identification of particular information is possible without any difficulty with a head movement. The inducting visual field refers to a region that is horizontally within approximately 100° and vertically within approximately 85° from the center of vision and adjacent to the outside of the stable visual field, where the existence of a particular target can be sensed but the identification ability is low. The supplementary visual field refers to a region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

From the above, it can be found that the image quality in the discrimination visual field and the effective visual field is important in the image 114. The image quality in the discrimination visual field is particularly important.

FIG. 20A is a schematic view showing the state where the user 112 sees the image 114 displayed on the display portion of the display apparatus 10 included in the electronic device 100 from the front (image display surface). The image 114 shown in FIG. 20A also corresponds to the display portion. The gaze point G in the direction of a gaze 113 of the user 112 is shown on the image 114. In this specification and the like, a region including the discrimination visual field and a region including the effective visual field on the image 114 are referred to as the “first region S1” and the “second region S2”, respectively. Furthermore, a region including the stable visual field, the inducting visual field, or the supplementary visual field is referred to as the “third region S3”.

Although the boundary (outline) between the first region S1 and the second region S2 is shown by a curved line in FIG. 20A, one embodiment of the present invention is not limited thereto. As shown in FIG. 20B, the boundary (outline) between the first region S1 and the second region S2 may be rectangular or polygonal. Alternatively, the boundary may have a shape in which a straight line and a curved line are combined. The display portion of the display apparatus 10 may be divided into two regions; one of the regions including the discrimination visual field and the effective visual field may be referred to as the first region S1, and the other region may be referred to as the second region S2. In that case, the third region S3 is not formed.

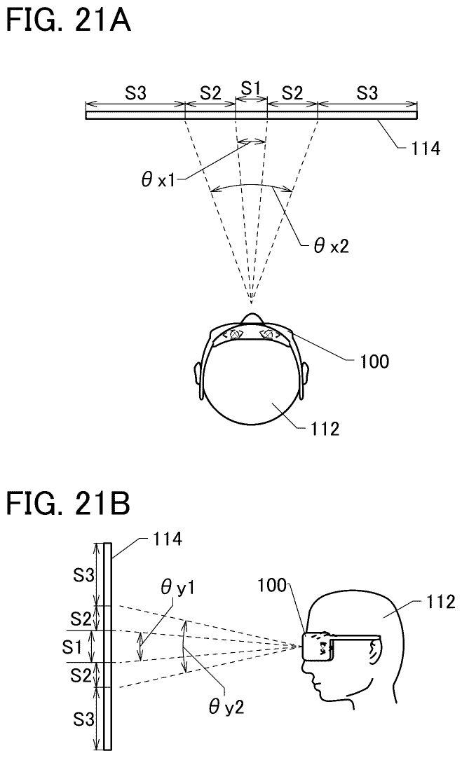

FIG. 21A is a top view of the image 114 displayed on the display portion of the display apparatus 10 of the electronic device 100, and FIG. 21B is a side view of the image 114 displayed on the display portion of the display apparatus 10 of the electronic device 100. In this specification and the like, the angle of the first region S1 in the horizontal direction is denoted as “angle θx1”, and the angle of the second region S2 in the horizontal direction is denoted as “angle θx2” (see FIG. 21A). In this specification and the like, the angle of the first region S1 in the vertical direction is denoted as “angle θy1”, and the angle of the second region S2 in the vertical direction is denoted as “angle θy2” (see FIG. 21B).

For example, by setting the angle θx1 to 10° and the angle θy1 to 10°, the area of the first region S1 can be widened. In that case, part of the effective visual field is included in the first region S1. Furthermore, by setting the angle θx2 to 45° and the angle θy2 to 35°, the area of the second region S2 can be widened. In that case, part of the stable visual field is included in the second region S2.

Note that the position of the gaze point G varies to some extent by a swing of the gaze 113. Thus, the angle θx1 and the angle θy1 are each preferably greater than or equal to 5° and smaller than 20°. When the area of the first region S1 is set larger than the discrimination visual field, the operation of the display apparatus 10 is stabilized and the image visibility is improved.

When the gaze 113 of the user 112 moves, the gaze point G also moves. Accordingly, the first region S1 and the second region S2 also move. For example, in the case where the fluctuation amount of the gaze 113 exceeds a certain value, it is judged that the gaze 113 has moved. That is, in the case where the fluctuation amount of the gaze point G exceeds a certain value, it is judged that the gaze point G has moved. Furthermore, in the case where the fluctuation amount of the gaze 113 becomes smaller than or equal to the certain value, it is judged that the gaze 113 has stopped moving, and the first region S1 to the third region S3 are determined. That is, in the case where the fluctuation amount of the gaze point G becomes smaller than or equal to the certain value, it is judged that the gaze point G has stopped moving, and the first region S1 to the third region S3 are determined.

The functional circuit 40 performs control of the driver circuit 30 differing between the plurality of regions (the first region S1 to the third region S3) (Step E15). For example, the driving frequency is adjusted so as to be suited for the plurality of regions.

The above is the description of the operation examples of the electronic device.

At least part of the structure examples, the drawings corresponding thereto, and the like described in this embodiment can be combined with the other structure examples, the other drawings, and the like as appropriate.

### Embodiment 4

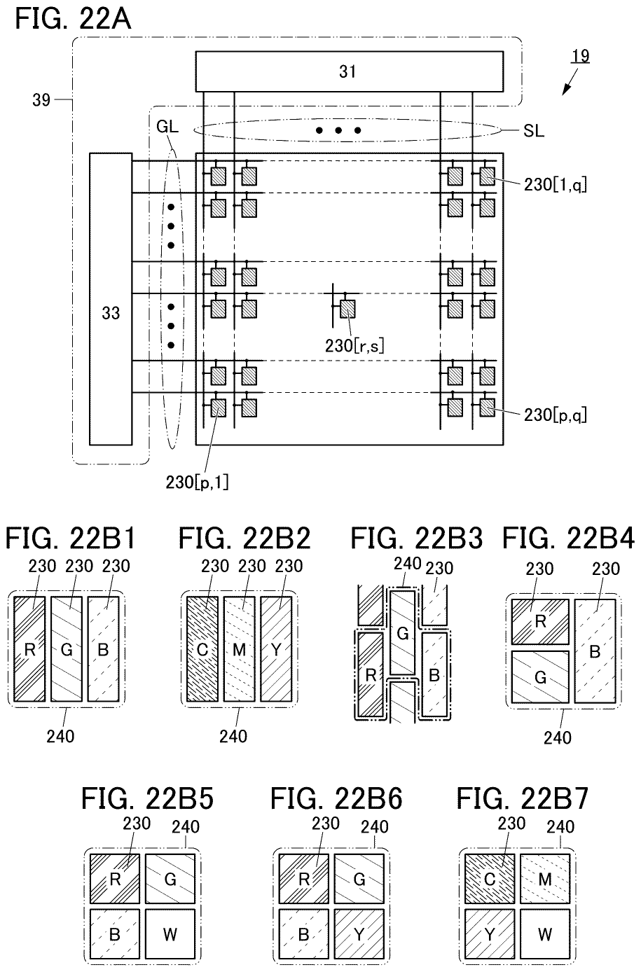

In this embodiment, a structure example of the sub-display portion 19 including the plurality of pixels 230 arranged in a matrix of p rows and q columns (p and q are each an integer greater than or equal to 2) will be described. FIG. 22A is a block diagram showing the sub-display portion 19.

In FIG. 22A, the pixel 230 in the p-th row and the first column is denoted as a pixel 230[p,1], the pixel 230 in the first row and the q-th column is denoted as a pixel 230[1,q], and the pixel 230 in the p-th row and the q-th column is denoted as a pixel 230[p,q].

A circuit included in the gate driver circuit 33 functions as, for example, a scan line driver circuit. A circuit included in the source driver circuit 31 functions as, for example, a signal line driver circuit.

For example, OS transistors may be used as the transistors included in the pixels 230 and Si transistors may be used as the transistors included in a driver circuit. The off-state current of an OS transistor is low, so that power consumption can be reduced. Since a Si transistor has a higher operation speed than an OS transistor, a Si transistor is suitably used in a driver circuit. The display apparatus may include OS transistors as both the transistors included in the pixels 230 and the transistors included in a driver circuit. The display apparatus may include Si transistors as both the transistors included in the pixels 230 and the transistors included in a driver circuit. Alternatively, the display apparatus may include Si transistors as the transistors included in the pixels 230 and OS transistors as the transistors included in a driver circuit.

Both a Si transistor and an OS transistor may be used as the transistors included in the pixels 230. Both a Si transistor and an OS transistor may be used as the transistors included in a driver circuit.

FIG. 22A shows p wirings GL which are arranged substantially parallel to each other and whose potentials are controlled by the gate driver circuit 33, and q wirings SL which are arranged substantially parallel to each other and whose potentials are controlled by the source driver circuit 31. For example, the pixels 230 arranged in the r-th row (r represents a given number and is an integer greater than or equal to 1 and less than or equal top in this embodiment and the like) are electrically connected to the gate driver circuit 33 through the wiring GL of the r-th row. The pixels 230 arranged in the s-th column (s represents a given number and is an integer greater than or equal to 1 and less than or equal to q in this embodiment and the like) are electrically connected to the source driver circuit 31 through the wiring SL of the s-th column. In FIG. 22A, the pixel 230 in the r-th row and the s-th column is denoted as a pixel 230[r,s].

Note that the number of the wirings GL electrically connected to the pixels 230 included in one row is not limited to one. Furthermore, the number of the wirings SL electrically connected to the pixels 230 included in one column is not limited to one. The wiring GL and the wiring SL are examples, and wirings connected to the pixels 230 are not limited to the wiring GL and the wiring SL.

Full-color display can be achieved by making the pixel 230 that controls red light, the pixel 230 that controls green light, and the pixel 230 that controls blue light, which are arranged in a stripe pattern, collectively function as one pixel 240 and by controlling the amount of light emission (emission luminance) from each of the pixels 230. In other words, each of the three pixels 230 functions as a subpixel. That is, three subpixels control the emission amounts or the like of red light, green light, and blue light (see FIG. 22B1). The light colors controlled by the three subpixels are not limited to a combination of red (R), green (G), and blue (B) and may be cyan (C), magenta (M), and yellow (Y) (see FIG. 22B2).

By using the pixels 240 arranged in a matrix of 1920×1080, the display portion 13 can achieve full-color display with a so-called 2K definition. For example, by using the pixels 240 arranged in a matrix of 3840×2160, the display portion 13 can achieve full-color display with a so-called 4K definition. For example, by using the pixels 240 arranged in a matrix of 7680×4320, the display portion 13 can achieve full-color display with a so-called 8K definition. By increasing the number of pixels 240, the display portion 13 that can perform full-color display with 16K or 32K definition can also be obtained.

Alternatively, the three pixels 230 constituting one pixel 240 may be arranged in a delta arrangement (see FIG. 22B3). Specifically, three pixels 230 constituting one pixel 240 may be arranged such that the lines connecting the center points of the three pixels 230 form a triangle. Alternatively, three pixels 230 constituting one pixel 240 may be arranged in an S-stripe arrangement (see FIG. 22B4). Note that the arrangement of the pixels 230 is not limited to a stripe arrangement, a delta arrangement, or an S-stripe arrangement. The pixels 230 may be arranged in a zigzag arrangement, a Bayer arrangement, or a PenTile arrangement.

The three subpixels (the pixels 230) do not necessarily have the same area. In the case where the emission efficiency, the reliability, and the like are different between emission colors, the areas of the subpixels may be different between the emission colors (see FIG. 22B4).

Four subpixels may collectively function as one pixel. For example, a subpixel that controls white light may be added to the three subpixels that control red light, green light, and blue light (see FIG. 22B5). The addition of the subpixel that controls white light can increase the luminance of a display region. Alternatively, a subpixel that controls yellow light may be added to the three subpixels that control red light, green light, and blue light (see FIG. 22B6). Alternatively, a subpixel that controls white light may be added to the three subpixels that control cyan light, magenta light, and yellow light (see FIG. 22B7).

When the number of subpixels functioning as one pixel is increased and subpixels that control light of red, green, blue, cyan, magenta, yellow, and the like are used in an appropriate combination, the reproducibility of halftones can be increased. Thus, display quality can be improved.

The display apparatus of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard used for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard used for HDTV (High Definition Television, also referred to as Hi-Vision); the DCI-P3 (Digital Cinema Initiatives P3) standard used for digital cinema projection; the ITU-R BT.2020 (REC.2020 (Recommendation 2020)) standard used for UHDTV (Ultra High Definition Television, also referred to as Super Hi-Vision); and the like.

### Structure Example of Light-Emitting Element

The light-emitting element 61 that can be used in the display apparatus of one embodiment of the present invention will be described.

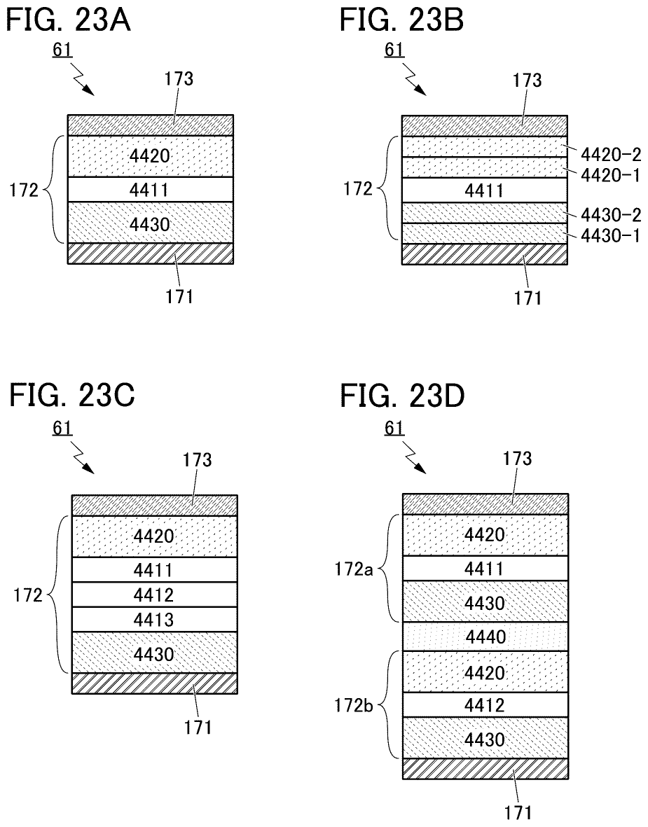

As shown in FIG. 23A, the light-emitting element 61 includes an EL layer 172 between a pair of electrodes (a conductor 171 and a conductor 173). The EL layer 172 can be formed of a plurality of layers such as a layer 4420, a light-emitting layer 4411, and a layer 4430. The layer 4420 can include, for example, a layer including a substance with a high electron-injection property (an electron-injection layer) and a layer including a substance with a high electron-transport property (an electron-transport layer). The light-emitting layer 4411 includes a light-emitting compound, for example. The layer 4430 can include, for example, a layer including a substance with a high hole-injection property (a hole-injection layer) and a layer including a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 23A is referred to as a single structure in this specification and the like.

FIG. 23B is a modification example of the EL layer 172 included in the light-emitting element 61 shown in FIG. 23A. Specifically, the light-emitting element 61 shown in FIG. 23B includes a layer 4430-1 over the conductor 171, a layer 4430-2 over the layer 4430-1, the light-emitting layer 4411 over the layer 4430-2, a layer 4420-1 over the light-emitting layer 4411, a layer 4420-2 over the layer 4420-1, and the conductor 173 over the layer 4420-2. In the case where the conductor 171 is an anode and the conductor 173 is a cathode, for example, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the conductor 171 is a cathode and the conductor 173 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layered structure, carriers can be efficiently injected to the light-emitting layer 4411, and the efficiency of the recombination of carriers in the light-emitting layer 4411 can be enhanced.

Note that the structure where a plurality of light-emitting layers (the light-emitting layer 4411, a light-emitting layer 4412, and a light-emitting layer 4413) are provided between the layer 4420 and the layer 4430 as shown in FIG. 23C is also an example of the single structure.

The structure in which a plurality of light-emitting units (an EL layer 172a and an EL layer 172b) are connected in series with an intermediate layer (charge-generation layer) 4440 therebetween as shown in FIG. 23D is referred to as a tandem structure or a stack structure in this specification and the like. Note that the tandem structure enables a light-emitting element capable of high luminance light emission.

In the case where the light-emitting element 61 has the tandem structure shown in FIG. 23D, the EL layer 172a and the EL layer 172b may emit light of the same color. For example, the EL layer 172a and the EL layer 172b may both emit green light.

Note that full-color display can be achieved by using the light-emitting element 61 emitting red light (R), the light-emitting element 61 emitting green light (G), and the light-emitting element 61 emitting blue light (B) as subpixels and constituting one pixel with these three subpixels. In the case where one pixel includes three kinds of subpixels of R, G, and B, the light-emitting elements 61 may each have a tandem structure. Specifically, the EL layer 172a and the EL layer 172b in the subpixel of R each include a material capable of emitting red light, the EL layer 172a and the EL layer 172b in the subpixel of G each include a material capable of emitting green light, and the EL layer 172a and the EL layer 172b in the subpixel of B each include a material capable of emitting blue light. In other words, the light-emitting layer 4411 and the light-emitting layer 4412 may include the same material. When the EL layer 172a and the EL layer 172b emit light of the same color, the current density per unit emission luminance can be reduced. Thus, the reliability of the light-emitting element 61 can be increased.

The emission color of the light-emitting element can be red, green, blue, cyan, magenta, yellow, white, or the like depending on the material included in the EL layer 172. Furthermore, the color purity can be further increased when the light-emitting element has a microcavity structure.

The light-emitting layer may include two or more light-emitting substances that emit light of R (red), G (green), B (blue), Y (yellow), O (orange), or the like. The light-emitting element that emits white light preferably includes two or more kinds of light-emitting substances in the light-emitting layer. To obtain white light emission, two or more light-emitting substances are selected such that they emit light having a relationship of complementary colors. For example, when the emission color of a first light-emitting layer and the emission color of a second light-emitting layer have a relationship of complementary colors, a light-emitting element that emits white light as a whole can be obtained. The same applies to a light-emitting element including three or more light-emitting layers.

The light-emitting layer preferably includes two or more light-emitting substances that emit light of R (red), G (green), B (blue), Y (yellow), O (orange), or the like. Alternatively, the light-emitting layer preferably includes two or more light-emitting substances each of which emits light including two or more of spectral components of R, G, and B. Alternatively, as the light-emitting substance, a substance that emits near-infrared light can be used.

Examples of light-emitting substances include a substance that emits fluorescent light (a fluorescent material), a substance that emits phosphorescent light (a phosphorescent material), and a substance that exhibits thermally activated delayed fluorescence (a thermally activated delayed fluorescence (TADF) material). As the light-emitting substance included in the EL element, not only an organic compound but also an inorganic compound (a quantum dot material or the like) can be used.

### <Method for Forming Light-Emitting Element>

An example of a method for forming the light-emitting element 61 will be described below.

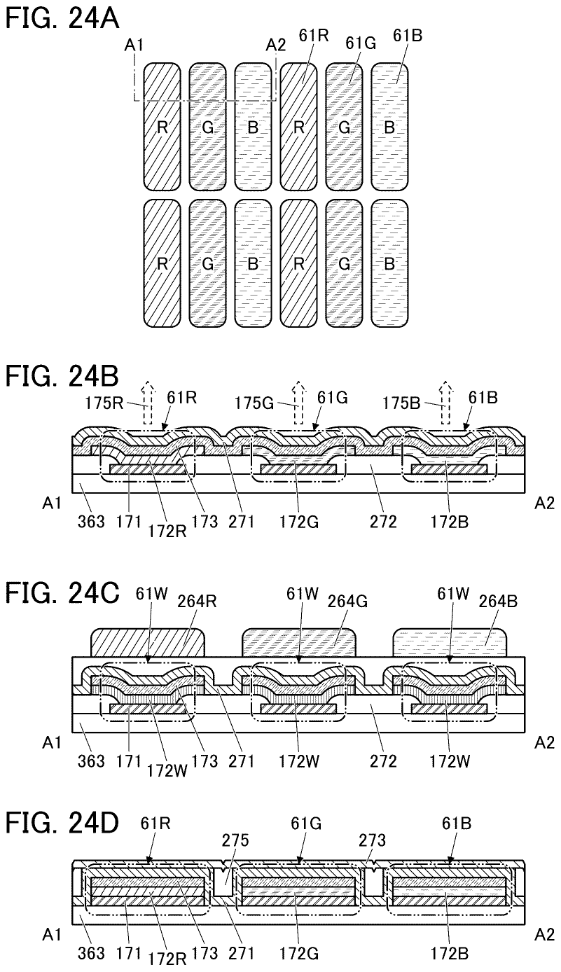

FIG. 24A shows a schematic top view of part of a display portion including a plurality of the light-emitting elements 61. The display portion includes a plurality of light-emitting elements 61R exhibiting red, a plurality of light-emitting elements 61G exhibiting green, and a plurality of light-emitting elements 61B exhibiting blue. In FIG. 24A, light-emitting regions of the light-emitting elements are denoted by R, G, and B to easily differentiate the light-emitting elements. Although FIG. 24A shows the structure having three emission colors of red (R), green (G), and blue (B), one embodiment of the present invention is not limited thereto. For example, the structure may have four or more colors.

The light-emitting elements 61R, the light-emitting elements 61G, and the light-emitting elements 61B are arranged in a matrix. Although FIG. 24A shows what is called a stripe arrangement in which the light-emitting elements of the same color are arranged in one direction, the arrangement method of the light-emitting elements is not limited thereto.

As each of the light-emitting element 61R, the light-emitting element 61G, and the light-emitting element 61B, an organic EL device such as an OLED (Organic Light Emitting Diode) or a QOLED (Quantum-dot Organic Light Emitting Diode) is preferably used. A light-emitting substance included in the EL element can be a substance that emits fluorescent light (a fluorescent material) or a substance that exhibits thermally activated delayed fluorescence (a thermally activated delayed fluorescence (TADF) material), for example. As the light-emitting substance included in the EL element, not only an organic compound but also an inorganic compound (a quantum dot material or the like) can be used.

FIG. 24B is a schematic cross-sectional view taken along dashed-dotted line A1-A2 in FIG. 24A. FIG. 24B shows a cross section of the light-emitting element 61R, the light-emitting element 61G, and the light-emitting element 61B. The light-emitting element 61R, the light-emitting element 61G, and the light-emitting element 61B are each provided over an insulator 363 and include a conductor 171 functioning as a pixel electrode and a conductor 173 functioning as a common electrode. For the insulator 363, one or both of an inorganic insulating film and an organic insulating film can be used. An inorganic insulating film is preferably used for the insulator 363. Examples of the inorganic insulating film include an oxide insulating film and a nitride insulating film, such as a silicon oxide film, a silicon oxynitride film, a silicon nitride oxide film, a silicon nitride film, an aluminum oxide film, an aluminum oxynitride film, and a hafnium oxide film.

The light-emitting element 61R includes an EL layer 172R between the conductor 171 functioning as a pixel electrode and the conductor 173 functioning as a common electrode. The EL layer 172R includes at least a light-emitting organic compound that emits light with a peak in a red wavelength range. An EL layer 172G included in the light-emitting element 61G includes at least a light-emitting organic compound that emits light with a peak in a green wavelength range. An EL layer 172B included in the light-emitting element 61B includes at least a light-emitting organic compound that emits light with a peak in a blue wavelength range.

The EL layer 172R, the EL layer 172G, and the EL layer 172B may each include one or more of an electron-injection layer, an electron-transport layer, a hole-injection layer, and a hole-transport layer in addition to the layer including a light-emitting compound (the light-emitting layer).

The conductor 171 functioning as a pixel electrode is provided in each of the light-emitting elements. The conductor 173 functioning as a common electrode is provided as a continuous layer shared by the light-emitting elements. A conductive film that has a property of transmitting visible light is used for either the conductor 171 functioning as a pixel electrode or the conductor 173 functioning as a common electrode, and a conductive film that has a reflective property is used for the other. When the conductor 171 functioning as a pixel electrode has a light-transmitting property and the conductor 173 functioning as a common electrode has a reflective property, a bottom-emission display apparatus can be obtained, whereas when the conductor 171 functioning as a pixel electrode has a reflective property and the conductor 173 functioning as a common electrode has a light-transmitting property, a top-emission display apparatus can be obtained. Note that when both the conductor 171 functioning as a pixel electrode and the conductor 173 functioning as a common electrode have a light-transmitting property, a dual-emission display apparatus can be obtained.

For example, in the case where the light-emitting element 61R has a top-emission structure, light 175R is emitted from the light-emitting element 61R to the conductor 173 side. In the case where the light-emitting element 61R has a top-emission structure, light 175G is emitted from the light-emitting element 61G to the conductor 173 side. In the case where the light-emitting element 61B has a top-emission structure, light 175B is emitted from the light-emitting element 61B to the conductor 173 side.

An insulator 272 is provided to cover end portions of the conductor 171 functioning as a pixel electrode. End portions of the insulator 272 are preferably tapered. For the insulator 272, a material similar to the material that can be used for the insulator 363 can be used.

The insulator 272 is provided to prevent an unintentional electric short-circuit between adjacent light-emitting elements 61 and unintended light emission therefrom. The insulator 272 also has a function of preventing the contact of a metal mask with the conductor 171 in the case where the metal mask is used to form the EL layer 172.

The EL layer 172R, the EL layer 172G, and the EL layer 172B each include a region in contact with the top surface of the conductor 171 functioning as a pixel electrode and a region in contact with a surface of the insulator 272. End portions of the EL layer 172R, the EL layer 172G, and the EL layer 172B are positioned over the insulator 272.

As shown in FIG. 24B, there is a gap between the two EL layers of the light-emitting elements with different colors. In this manner, the EL layer 172R, the EL layer 172G, and the EL layer 172B are preferably provided so as not to be in contact with each other. This can favorably prevent unintentional light emission (also referred to as crosstalk) from being caused by current flowing through two adjacent EL layers. As a result, the contrast can be increased to achieve a display apparatus with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method enables a display apparatus to have a high resolution, which is difficult to obtain in the case of using a metal mask.

Note that in this specification and the like, a device manufactured using a metal mask or an FMM (a fine metal mask, a high-resolution metal mask) may be referred to as a device having an MM (a metal mask) structure. In addition, in this specification and the like, a device manufactured without using a metal mask or an FMM is sometimes referred to as a device having an MML (metal maskless) structure. A display apparatus having an MML structure is manufactured without using a metal mask and thus has higher flexibility in designing the pixel arrangement, the pixel shape, and the like than a display apparatus having an MM structure.

A protective layer 271 is provided over the conductor 173 functioning as a common electrode so as to cover the light-emitting element 61R, the light-emitting element 61G, and the light-emitting element 61B. The protective layer 271 has a function of preventing diffusion of impurities such as water into the light-emitting elements from above.

The protective layer 271 can have, for example, a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as indium gallium oxide or indium gallium zinc oxide (IGZO) may be used for the protective layer 271. Note that the protective layer 271 can be formed by an ALD (Atomic Layer Deposition) method, a CVD (Chemical Vapor Deposition) method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that includes more nitrogen than oxygen. An oxynitride refers to a compound that includes more oxygen than nitrogen. Note that the content of each element can be measured by Rutherford backscattering spectrometry (RBS), for example.

In the case where indium gallium zinc oxide is used for the protective layer 271, indium gallium zinc oxide can be processed by a wet etching method or a dry etching method. For example, in the case where IGZO is used for the protective layer 271, a chemical solution of oxalic acid, phosphoric acid, a mixed chemical solution (e.g., a mixed chemical solution of phosphoric acid, acetic acid, nitric acid, and water (also referred to as a mixed acid aluminum etchant)), or the like can be used. Note that the volume ratio of phosphoric acid to acetic acid to nitric acid to water in the mixed acid aluminum etchant can be 53.3:6.7:3.3:36.7 or the neighborhood thereof.

Note that the structure shown in FIG. 24B may be referred to as an SBS structure described later.

FIG. 24C shows an example different from the above. Specifically, in FIG. 24C, light-emitting elements 61W that emit white light are provided. The light-emitting elements 61W each include an EL layer 172W that emits white light between the conductor 171 functioning as a pixel electrode and the conductor 173 functioning as a common electrode.

The EL layer 172W can have, for example, a structure in which two or more light-emitting layers that are selected so that their emission colors have a relationship of complementary colors are stacked. It is also possible to use a stacked EL layer in which a charge-generation layer is provided between light-emitting layers.

FIG. 24C shows three light-emitting elements 61W arranged side by side. A coloring layer 264R is provided above the light-emitting element 61W on the left. The coloring layer 264R functions as a band-pass filter that transmits red light. Similarly, a coloring layer 264G that transmits green light is provided above the light-emitting element 61W in the middle, and a coloring layer 264B that transmits blue light is provided above the light-emitting element 61W on the right. Thus, the display apparatus can display an image with colors.

Here, the EL layer 172W and the conductor 173 functioning as a common electrode are each separated between two adjacent light-emitting elements 61W. This can prevent unintentional light emission from being caused by a current flowing through the EL layers 172W of the two adjacent light-emitting elements 61W. Particularly when a stacked EL layer in which a charge-generation layer is provided between two light-emitting layers is used as the EL layer 172W, the effect of crosstalk becomes more significant as the resolution increases, i.e., as the distance between adjacent pixels decreases, leading to lower contrast. Thus, the above structure enables a display apparatus to have both high resolution and high contrast.

The EL layer 172W and the conductor 173 functioning as a common electrode are preferably separated by a photolithography method. This can reduce an interval between light-emitting elements, enabling a display apparatus to have a higher aperture ratio than that formed using, for example, a shadow mask such as a metal mask.

Note that in the case of a bottom-emission light-emitting element, a coloring layer is provided between the conductor 171 functioning as a pixel electrode and the insulator 363.

FIG. 24D shows an example different from the above. Specifically, in FIG. 24D, the insulator 272 is not provided between the light-emitting element 61R, the light-emitting element 61G, and the light-emitting element 61B. With such a structure, the display apparatus can have a high aperture ratio. When the insulator 272 is not provided, unevenness formed by the light-emitting elements 61 can be reduced, thereby improving the viewing angle of the display apparatus. Specifically, the viewing angle can be greater than or equal to 150 degrees and less than 180 degrees, preferably greater than or equal to 160 degrees and less than 180 degrees.

The protective layer 271 covers side surfaces of the EL layer 172R, the EL layer 172G, and the EL layer 172B. With this structure, impurities (typically, water or the like) can be inhibited from entering the EL layer 172R, the EL layer 172G, and the EL layer 172B through their side surfaces. In addition, leakage current between adjacent light-emitting elements 61 is reduced, so that color saturation and contrast ratio are improved and power consumption is reduced.

In the structure shown in FIG. 24D, the shapes of the conductor 171, the EL layer 172R, and the conductor 173 are substantially the same as each other in a plan view. This structure can be formed in such a manner that the conductor 171, the EL layer 172R, and the conductor 173 are formed and collectively processed using a resist mask or the like. In this process, the EL layer 172R and the conductor 173 are processed using the conductor 173 as a mask, and thus this process can be called self-aligned patterning. Although the EL layer 172R is described here, the EL layer 172G and the EL layer 172B can each have a similar structure.

In FIG. 24D, a protective layer 273 is further provided over the protective layer 271. For example, the protective layer 271 can be formed with an apparatus that can form a film with excellent coverage (typically, an ALD apparatus or the like), and the protective layer 273 can be formed with an apparatus that can form a film with coverage inferior to that of the protective layer 271 (typically, a sputtering apparatus or the like), whereby a region 275 can be provided between the protective layer 271 and the protective layer 273. In other words, the region 275 is positioned between the EL layer 172R and the EL layer 172G and between the EL layer 172G and the EL layer 172B.

Note that the region 275 includes, for example, any one or more selected from air, nitrogen, oxygen, carbon dioxide, and Group 18 elements (typically, helium, neon, argon, xenon, krypton, and the like). Furthermore, for example, a gas used during the formation of the protective layer 273 is sometimes included in the region 275. For example, in the case where the protective layer 273 is formed by a sputtering method, any one or more of the above-described Group 18 elements is sometimes included in the region 275. In the case where a gas is included in the region 275, a gas can be identified with a gas chromatography method or the like. Alternatively, in the case where the protective layer 273 is formed by a sputtering method, a gas used in the sputtering is sometimes included in the protective layer 273. In that case, an element such as argon is sometimes detected when the protective layer 273 is analyzed by an energy dispersive X-ray analysis (EDX analysis) or the like.

In the case where the refractive index of the region 275 is lower than the refractive index of the protective layer 271, light emitted from the EL layer 172R, the EL layer 172G, or the EL layer 172B is reflected at the interface between the protective layer 271 and the region 275. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display apparatus.

In the case of the structure shown in FIG. 24D, a region between the light-emitting element 61R and the light-emitting element 61G or a region between the light-emitting element 61G and the light-emitting element 61B (hereinafter simply referred to as a distance between the light-emitting elements) can be small. Specifically, the distance between the light-emitting elements can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region in which an interval between the side surface of the EL layer 172R and the side surface of the EL layer 172G or an interval between the side surface of the EL layer 172G and the side surface of the EL layer 172B is less than or equal to 1 μm, preferably less than or equal to 0.5 μm (500 nm), further preferably less than or equal to 100 nm.

In the case where the region 275 includes a gas, the light-emitting elements can be separated from each other and color mixture of light from the light-emitting elements, crosstalk, or the like can be inhibited.

The region 275 may be a space or may be filled with a filler. Examples of the filler include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the filler. The photoresist used as the filler may be a positive photoresist or a negative photoresist.

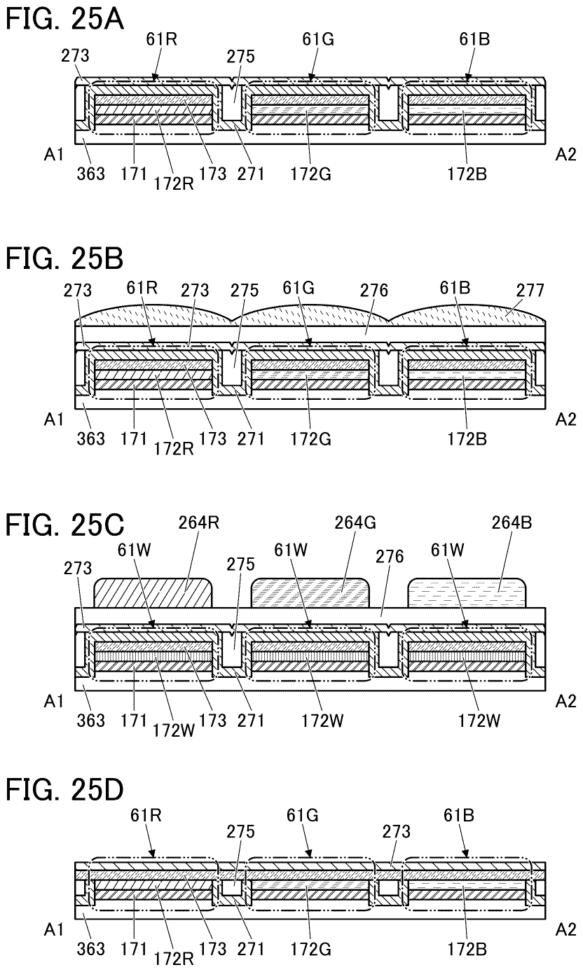

FIG. 25A shows an example different from the above. Specifically, the structure shown in FIG. 25A is different from the structure shown in FIG. 24D in the structure of the insulator 363. The top surface of the insulator 363 is partly removed when the light-emitting element 61R, the light-emitting element 61G, and the light-emitting element 61B are processed, so that the insulator 363 has a depressed portion. In addition, the protective layer 271 is formed in the depressed portion. In other words, in the cross-sectional view, a region is provided in which the bottom surface of the protective layer 271 is positioned below the bottom surface of the conductor 171. With the region, impurities (typically, water or the like) can be suitably inhibited from entering the light-emitting element 61R, the light-emitting element 61G, and the light-emitting element 61B from below. Note that the depressed portion can be formed when impurities (also referred to as residue) that could be attached to the side surfaces of the light-emitting element 61R, the light-emitting element 61G, and the light-emitting element 61B in processing of the light-emitting elements are removed by wet etching or the like. After the residue is removed, the side surfaces of the light-emitting elements are covered with the protective layer 271, whereby a highly reliable display apparatus can be provided.

FIG. 25B shows an example different from the above. Specifically, the structure shown in FIG. 25B includes an insulator 276 and a microlens array 277 in addition to the structure shown in FIG. 25A. The insulator 276 functions as an adhesive layer. Note that when the refractive index of the insulator 276 is lower than that of the microlens array 277, the microlens array 277 can condense light emitted from the light-emitting element 61R, the light-emitting element 61G, and the light-emitting element 61B. This can increase the light extraction efficiency of the display apparatus. In particular, this is suitable because a user can see bright images when the user sees the display surface from the front of the display surface of the display apparatus. As the insulator 276, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component resin may be used. An adhesive sheet or the like may be used.

FIG. 25C shows an example different from the above. Specifically, the structure shown in FIG. 25C includes three light-emitting elements 61W instead of the light-emitting element 61R, the light-emitting element 61G, and the light-emitting element 61B in the structure shown in FIG. 25A. In addition, the insulator 276 is provided above the three light-emitting elements 61W, and the coloring layer 264R, the coloring layer 264G, and the coloring layer 264B are provided above the insulator 276. Specifically, the coloring layer 264R that transmits red light is provided at a position overlapping with the light-emitting element 61W on the left, the coloring layer 264G that transmits green light is provided at a position overlapping with the light-emitting element 61W in the middle, and the coloring layer 264B that transmits blue light is provided at a position overlapping with the light-emitting element 61W on the right. Thus, the semiconductor device can display an image with colors. The structure shown in FIG. 25C is also a modification example of the structure shown in FIG. 24C.

FIG. 25D shows an example different from the above. Specifically, in the structure shown in FIG. 25D, the protective layer 271 is provided adjacent to the side surfaces of the conductor 171 and the EL layer 172. The conductor 173 is provided as a continuous layer shared by the light-emitting elements. In the structure shown in FIG. 25D, the region 275 is preferably filled with a filler.

The color purity of emitted light can be increased when the light-emitting element 61 has a micro-optical resonator (microcavity) structure. In order that the light-emitting element 61 has a microcavity structure, a product of a distance d between the conductor 171 and the conductor 173 and a refractive index n of the EL layer 172 (optical path length) is set to m times half of a wavelength λ (m is an integer greater than or equal to 1). The distance d can be obtained by Formula 1.

d=m×λ/(2×n) Formula 1.

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G, in some cases.

To be exact, the distance d is a distance from a reflection region in the conductor 171 functioning as a reflective electrode to a reflection region in the conductor 173 functioning as an electrode having properties of transmitting and reflecting emitted light (a transflective electrode). For example, in the case where the conductor 171 is a stack of silver and ITO (Indium Tin Oxide) that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by changing the thickness of the ITO.

However, it is sometimes difficult to determine the exact position of the reflection region in each of the conductor 171 and the conductor 173. In that case, it is assumed that the effect of the microcavity can be fully obtained with a certain position in each of the conductor 171 and the conductor 173 being supposed as the reflection region.

The light-emitting element 61 includes a hole-injection layer, a hole-transport layer, a light-emitting layer, an electron-transport layer, an electron-injection layer, and the like. A specific structural example of the light-emitting element 61 is described in another embodiment. In order to increase the light extraction efficiency in the microcavity structure, the optical path length from the conductor 171 functioning as a reflective electrode to the light-emitting layer is preferably set to an odd multiple of λ/4. In order to achieve this optical path length, the thicknesses of the layers in the light-emitting element 61 are preferably adjusted as appropriate.

In the case where light is emitted from the conductor 173 side, the reflectance of the conductor 173 is preferably higher than the transmittance thereof. The light transmittance of the conductor 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductor 173 is set low (the reflectance is set high), the effect of the microcavity can be enhanced.

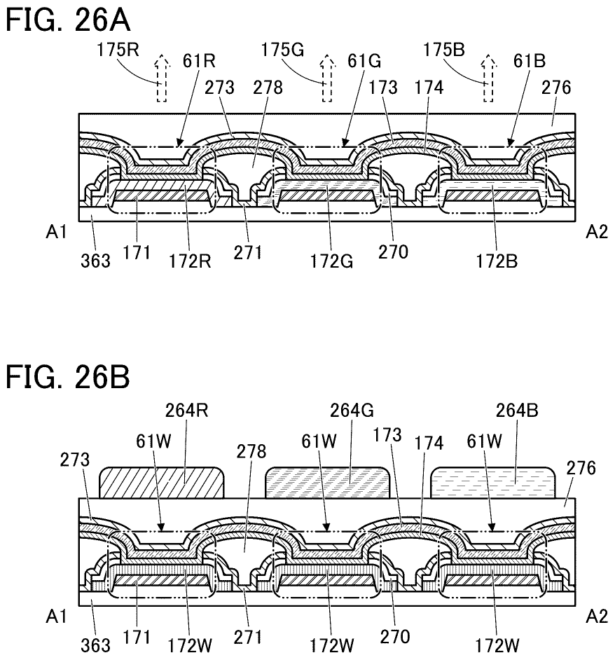

FIG. 26A shows an example different from the above. Specifically, in the structure shown in FIG. 26A, the EL layer 172 extends beyond the end portions of the conductor 171 in each of the light-emitting element 61R, the light-emitting element 61G, and the light-emitting element 61B. For example, in the light-emitting element 61R, the EL layer 172R extends beyond the end portions of the conductor 171. In the light-emitting element 61G, the EL layer 172G extends beyond the end portions of the conductor 171. In the light-emitting element 61B, the EL layer 172B extends beyond the end portions of the conductor 171.

The light-emitting element 61R, the light-emitting element 61G, and the light-emitting element 61B each include a region where the EL layer 172 overlaps with the protective layer 271 with an insulator 270 therebetween. In a region between adjacent light-emitting elements 61, an insulator 278 is provided over the protective layer 271.

Examples of the insulator 278 include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the insulator 278. The photoresist used as the insulator 278 may be a positive photoresist or a negative photoresist.

A common layer 174 is provided over the light-emitting element 61R, the light-emitting element 61G, the light-emitting element 61B, and the insulator 278, and the conductor 173 is provided over the common layer 174. The common layer 174 includes a region in contact with the EL layer 172R, a region in contact with the EL layer 172G, and a region in contact with the EL layer 172B. The common layer 174 is shared by the light-emitting element 61R, the light-emitting element 61G, and the light-emitting element 61B.

As the common layer 174, one or more of a hole-injection layer, a hole-transport layer, a hole-blocking layer, an electron-blocking layer, an electron-transport layer, and an electron-injection layer can be used. For example, the common layer 174 may be a carrier-injection layer (a hole-injection layer or an electron-injection layer). The common layer 174 can also be regarded as part of the EL layer 172. Note that the common layer 174 is provided as necessary. In the case where the common layer 174 is provided, a layer having the same function as the common layer 174 among the layers included in the EL layer 172 is not necessarily provided.

The protective layer 273 is provided over the conductor 173, and the insulator 276 is provided over the protective layer 273.

FIG. 26B shows an example different from the above. Specifically, the structure shown in FIG. 26B includes three light-emitting elements 61W instead of the light-emitting element 61R, the light-emitting element 61G, and the light-emitting element 61B in the structure shown in FIG. 26A. In addition, the insulator 276 is provided above the three light-emitting elements 61W, and the coloring layer 264R, the coloring layer 264G, and the coloring layer 264B are provided above the insulator 276. Specifically, the coloring layer 264R that transmits red light is provided at a position overlapping with the light-emitting element 61W on the left, the coloring layer 264G that transmits green light is provided at a position overlapping with the light-emitting element 61W in the middle, and the coloring layer 264B that transmits blue light is provided at a position overlapping with the light-emitting element 61W on the right. Thus, the semiconductor device can display an image with colors. The structure shown in FIG. 26B is also a modification example of the structure shown in FIG. 25C.

At least part of the structure examples, the drawings corresponding thereto, and the like described in this embodiment can be combined with the other structure examples, the other drawings, and the like as appropriate.

### Embodiment 5

In this embodiment, display apparatuses of one embodiment of the present invention will be described. The display apparatus exemplified below can be used as the display apparatus included in the electronic device described in the above embodiment.

### Structure Example 1 of Display Apparatus

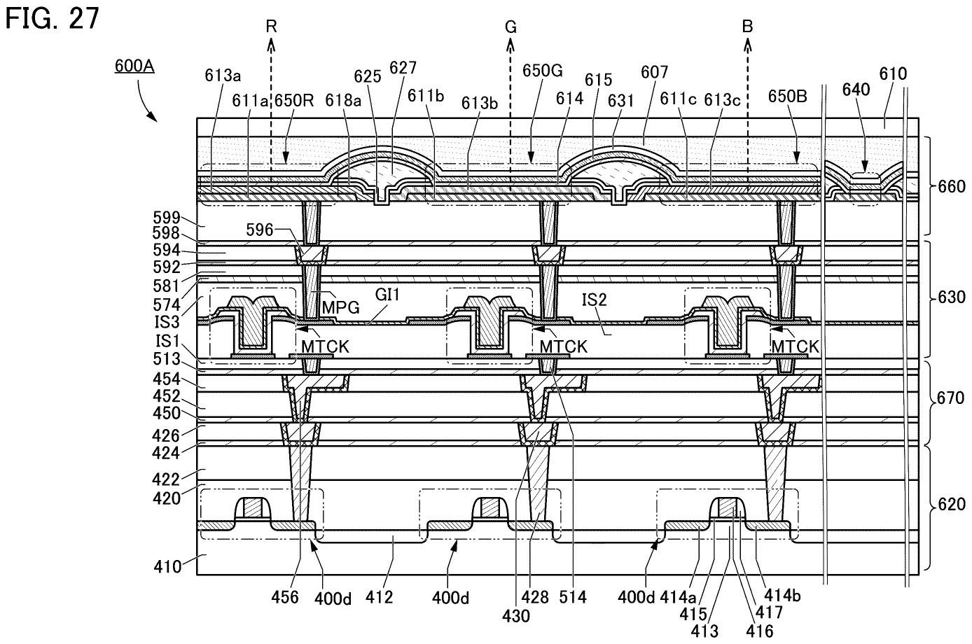

FIG. 27 is a cross-sectional view of a display apparatus 600A. The display apparatus 600A is an example of a display apparatus having an MML (metal maskless) structure. In other words, the display apparatus 600A includes a light-emitting device that is formed without using a fine metal mask.

An island-shaped light-emitting layer of the light-emitting device included in the display apparatus having an MML structure is formed in the following manner: a light-emitting layer is formed on the entire surface, and then, the light-emitting layer is processed by a photolithography method. Accordingly, a high-resolution display apparatus or a display apparatus with a high aperture ratio, which has been difficult to achieve, can be manufactured. Moreover, light-emitting layers can be formed separately for the respective colors, enabling the display apparatus to perform extremely clear display with high contrast and high display quality. For example, in the case where the display apparatus includes three kinds of light-emitting devices, which are a light-emitting device emitting blue light, a light-emitting device emitting green light, and a light-emitting device emitting red light, three kinds of island-shaped light-emitting layers can be formed by repeating the set of formation of a light-emitting layer and processing by photolithography three times.

Note that a device having an MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in resolution by employing a unique pixel arrangement such as a PenTile arrangement in a display apparatus employing an MML structure; thus, the display apparatus can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

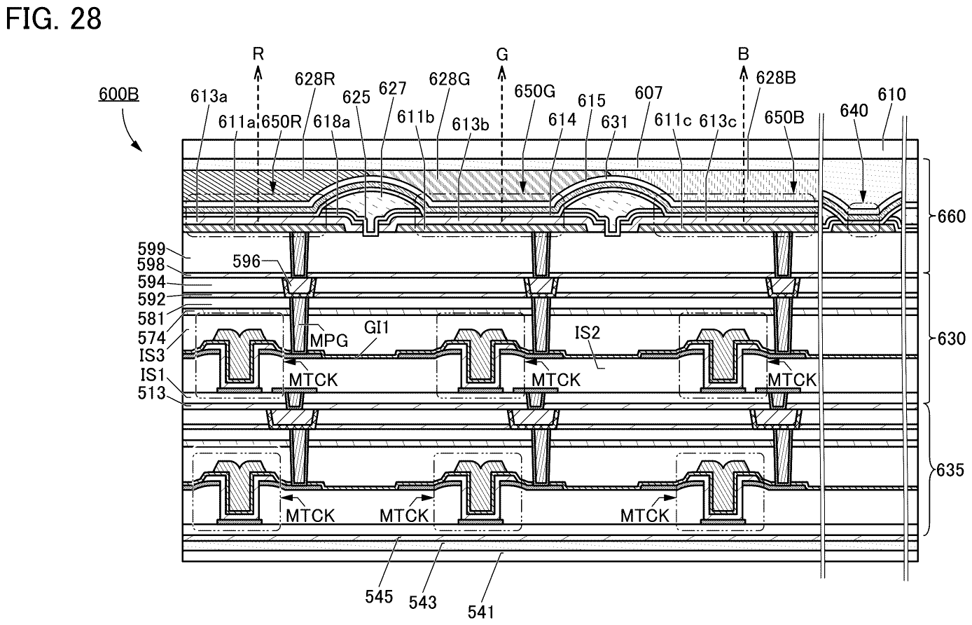

Moreover, providing a sacrificial layer over the light-emitting layer can reduce damage to the light-emitting layer in the manufacturing process of the display apparatus, resulting in an improvement in reliability of the light-emitting device. Note that the sacrificial layer may remain in the completed display apparatus or may be removed in the manufacturing process. For example, a sacrificial layer 618a shown in FIG. 27 and FIG. 28 is part of the sacrificial layer provided over the light-emitting layer.

A light-emitting device can be manufactured through a relatively simple process, by employing a film formation step using an area mask and a processing step using a resist mask.

FIG. 27 is a schematic cross-sectional view of the display apparatus 600A that is a display apparatus (a semiconductor device) of one embodiment of the present invention. The display apparatus 600A has a structure including a pixel circuit, a driver circuit, and the like provided over a substrate 410. Note that in the display apparatus 600A in FIG. 27, a wiring layer 670 is shown in addition to an element layer 620, an element layer 630, and an element layer 660. The wiring layer 670 is a layer provided with a wiring.

A pixel circuit of the display apparatus is preferably provided in the element layer 630. A driver circuit (one or both of a gate driver and a source driver) of the display apparatus is preferably provided in the element layer 620. One or more of a variety of circuits such as an arithmetic circuit and a memory circuit may be provided in the element layer 620.

The element layer 620 includes the substrate 410, for example, and a transistor 400d is formed over the substrate 410. The wiring layer 670 is provided above the transistor 400d, and a wiring for electrically connecting the transistor 400d to a conductive layer, a transistor, or the like provided in the element layer 630 (a conductor 514 in FIG. 27) is provided in the wiring layer 670. The element layer 630 and the element layer 660 are provided above the wiring layer 670, and the element layer 630 includes the transistors MTCK and the like, for example. The element layer 660 includes light-emitting devices 650 (a light-emitting device 650R, a light-emitting device 650G, and a light-emitting device 650B in FIG. 27), and the like.

The transistor 400d is an example of a transistor included in the element layer 620. The transistor MTCK is an example of a transistor included in the element layer 630. The light-emitting devices (the light-emitting device 650R, the light-emitting device 650G, and the light-emitting device 650B) are examples of the light-emitting devices included in the element layer 660.

As the substrate 410, a semiconductor substrate (e.g., a single crystal substrate including silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film including a fibrous material can be used as the substrate 410. In description of this embodiment, the substrate 410 is a semiconductor substrate including silicon as a material. Thus, a transistor included in the element layer 620 can be a Si transistor.

The transistor 400d includes an element isolation layer 412, a conductor 416, an insulator 415, an insulator 417, a semiconductor region 413 that is part of the substrate 410, and a low-resistance region 414a and a low-resistance region 414b that function as a source region and a drain region. Thus, the transistor 400d is a Si transistor. Although FIG. 27 shows a structure in which one of a source and a drain of the transistor 400d is electrically connected to the conductor 514 provided in the element layer 630 through a conductor 428, a conductor 430, and a conductor 456, the electrical connection structure in the display apparatus of one embodiment of the present invention is not limited thereto.

The transistor 400d can be a Fin type when, for example, the top surface of the semiconductor region 413 and the side surface thereof in the channel width direction are covered with the conductor 416 with the insulator 415 functioning as a gate insulator therebetween. The effective channel width can be increased in the Fin-type transistor 400d, so that the on-state characteristics of the transistor 400d can be improved. In addition, since contribution of an electric field of a gate electrode can be increased, the off-state characteristics of the transistor 400d can be improved. Alternatively, the transistor 400d may have a planar structure instead of a Fin-type structure.

Note that the transistor 400d can be either a p-channel transistor or an n-channel transistor. Alternatively, a plurality of the transistors 400d may be provided and both the p-channel transistor and the n-channel transistor may be used.

A region of the semiconductor region 413 where a channel is formed, a region in the vicinity thereof, and the low-resistance region 414a and the low-resistance region 414b that function as the source region and the drain region preferably include silicon, specifically, preferably include single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 400d may be a HEMT (High Electron Mobility Transistor) using gallium arsenide and aluminum gallium arsenide, for example.

For the conductor 416 functioning as a gate electrode, a semiconductor material such as silicon including an element that imparts n-type conductivity, such as arsenic or phosphorus, or an element that imparts p-type conductivity, such as boron or aluminum, can be used. Alternatively, for the conductor 416, a conductive material such as a metal material, an alloy material, or a metal oxide material can be used, for example.

Note that since a work function depends on the material of the conductor, the threshold voltage of the transistor can be adjusted by selecting the material of the conductor. Specifically, it is preferable to use one or both of titanium nitride and tantalum nitride as the material of the conductor. Moreover, for both conductivity and embeddability, it is preferable to use stacked layers of metal materials of one or both of tungsten and aluminum as the conductor, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d shown in FIG. 27, an insulator 420 and an insulator 422 are sequentially stacked from the substrate 410 side.

For each of the insulator 420 and the insulator 422, one or more selected from silicon oxide, silicon oxynitride, silicon nitride oxide, silicon nitride, aluminum oxide, aluminum oxynitride, aluminum nitride oxide, and aluminum nitride are used, for example.

The insulator 422 may have a function of a planarization film for eliminating a level difference caused by the transistor 400d or the like covered with the insulator 420 and the insulator 422. For example, a top surface of the insulator 422 may be planarized by planarization treatment using a chemical mechanical polishing (CMP) method or the like to improve planarity.

The conductor 428 connected to the transistor MTCK and the like provided above the insulator 422 is embedded in the insulator 420 and the insulator 422. The conductor 428 has a function of a plug or a wiring.

In the display apparatus 600A, the wiring layer 670 is provided over the transistor 400d. The wiring layer 670 includes, for example, an insulator 424, an insulator 426, the conductor 430, an insulator 450, an insulator 452, an insulator 454, and the conductor 456.

Over the insulator 422 and the conductor 428, the insulator 424 and the insulator 426 are sequentially stacked. An opening is formed in the insulator 424 and the insulator 426 in a region overlapping with the conductor 428. In addition, the conductor 430 is embedded in the opening.

The insulator 450, the insulator 452, and the insulator 454 are sequentially stacked over the insulator 426 and the conductor 430. An opening is formed in the insulator 450, the insulator 452, and the insulator 454 in a region overlapping with the conductor 430. The conductor 456 is embedded in the opening.

The conductor 430 and the conductor 456 have a function of a plug or a wiring that is connected to the transistor 400d.

Note that like an insulator 592 described later, for example, the insulator 424 and the insulator 450 are preferably formed using an insulator having a barrier property against one or more selected from hydrogen, oxygen, and water. Like an insulator 594 described later, each of the insulator 426, the insulator 452, and the insulator 454 is preferably formed using an insulator having a relatively low dielectric constant to reduce parasitic capacitance generated between wirings. Each of the insulator 426, the insulator 452, and the insulator 454 has functions of an interlayer insulating film and a planarization film. Furthermore, each of the insulator 426, the insulator 452, and the insulator 454 preferably includes an insulator having a barrier property against one or more selected from hydrogen, oxygen, and water.

For the conductor having a barrier property against hydrogen, tantalum nitride is preferably used, for example. In addition, using a stack of tantalum nitride and tungsten, which has high conductivity, can inhibit diffusion of hydrogen from the transistor 400d while the conductivity of a wiring is kept. In that case, the tantalum nitride layer having a barrier property against hydrogen is preferably in contact with the insulator 450 having a barrier property against hydrogen.

An insulator 513 is provided above the insulator 454 and the conductor 456. An insulator IS1 is provided over the insulator 513. A conductor functioning as a plug or a wiring is embedded in the insulator IS1 and the insulator 513. Thus, the transistor 400d can be electrically connected to the conductor 514 provided in the element layer 630. Alternatively, a source or a drain of the transistor MTCK and the source or the drain of the transistor 400d may be electrically connected to each other.

The transistor MTCK is provided over the insulator IS1. An insulator IS3, an insulator 574, and an insulator 581 are stacked in this order over the transistor MTCK. A conductor MPG functioning as a plug or a wiring is embedded in the insulator IS3, the insulator 574, and the insulator 581. Note that the transistor MTCK and an insulator, a conductor, and a semiconductor which are around the transistor MTCK are described later in this embodiment.

The insulator 574 preferably has a function of inhibiting diffusion of impurities such as water and hydrogen (e.g., one or both of a hydrogen atom and a hydrogen molecule). In other words, the insulator 574 preferably functions as a barrier insulating film that inhibits the entry of the impurities into the transistor MTCK. Moreover, the insulator 574 preferably has a function of inhibiting diffusion of oxygen (e.g., one or both of an oxygen atom and an oxygen molecule). For example, the insulator 574 preferably has a lower oxygen permeability than an insulator IS2 and the insulator IS3.

Thus, the insulator 574 preferably functions as a barrier insulating film that inhibits diffusion of impurities such as water and hydrogen. Accordingly, it is preferable to use, for the insulator 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator including one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides including aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 574. Accordingly, it is possible to inhibit diffusion of impurities such as water and hydrogen to the transistor MTCK side from above the insulator 574. In addition, it is possible to inhibit diffusion of oxygen included in the insulator IS3 or the like to above the insulator 574.

The insulator 581 is preferably a film functioning as an interlayer film and having a lower permittivity than the insulator 574. When a material with a lower permittivity is used for an interlayer film, parasitic capacitance generated between wirings can be reduced. The dielectric constant of the insulator 581 is preferably lower than 4, further preferably lower than 3, for example. The dielectric constant of the insulator 581 is, for example, preferably 0.7 times or less, further preferably 0.6 times or less the dielectric constant of the insulator 574. When a material with a low permittivity is used for the insulator 581 functioning as an interlayer film, parasitic capacitance generated between wirings can be reduced.

The concentration of impurities such as water and hydrogen in the insulator 581 is preferably reduced. In this case, for the insulator 581, silicon oxide, silicon oxynitride, silicon nitride oxide, or silicon nitride can be used, for example. Alternatively, for the insulator 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region including oxygen to be released by heating can be easily formed. Alternatively, for the insulator 581, a resin can be used. A material that can be used for the insulator 581 may be an appropriate combination of the above-described materials.

An insulator 592 and an insulator 594 are stacked in this order over the insulator 574 and the insulator 581.

For the insulator 592, it is preferable to use an insulating film having a barrier property (referred to as a barrier insulating film) which can prevent diffusion of impurities such as water and hydrogen from the substrate 410 or the transistor MTCK to a region above the insulator 592 (e.g., the region where the light-emitting device 650R, the light-emitting device 650G, the light-emitting device 650B, and the like are provided). Accordingly, for the insulator 592, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (an insulating material through which the above oxygen is less likely to pass). It is preferable that the insulator 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectroscopy (TDS), for example. The amount of hydrogen released from the insulator 424 that is converted into hydrogen atoms per area of the insulator 424 is less than or equal to 10×10¹⁵ atoms/cm², preferably less than or equal to 5×10¹⁵ atoms/cm², in the TDS analysis in a film-surface temperature range of 50° C. to 500° C., for example.

Like the insulator 581, the insulator 594 is preferably an interlayer film with a low permittivity. Thus, for the insulator 594, a material that can be used for the insulator 581 can be used.

Note that the insulator 594 preferably has a lower permittivity than the insulator 592. The dielectric constant of the insulator 594 is preferably lower than 4, further preferably lower than 3, for example. The dielectric constant of the insulator 594 is, for example, preferably 0.7 times or less, further preferably 0.6 times or less the dielectric constant of the insulator 592. When a material with a low permittivity is used for the insulator 594 functioning as an interlayer film, parasitic capacitance generated between wirings can be reduced.

A conductor MPG functioning as a plug or a wiring is embedded in the insulator GI1 and the insulator IS3, and a conductor 596 functioning as a plug or a wiring is embedded in the insulator 592 and the insulator 594. In particular, the conductor MPG and the conductor 596 are electrically connected to the light-emitting device or the like provided above the insulator 594. A plurality of conductors functioning as plugs or wirings are collectively denoted by the same reference numeral in some cases. In this specification and the like, a wiring and a plug connected to the wiring may be a single component. That is, part of a conductor functions as a wiring in some cases and part of the conductor functions as a plug in other cases.

As a material of each of plugs and wirings (e.g., the conductor MPG, the conductor 428, the conductor 430, the conductor 456, the conductor 514, and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulator 598 and an insulator 599 are sequentially formed over the insulator 594 and the conductor 596.

Like the insulator 592, for example, the insulator 598 is preferably formed using an insulator having a barrier property against one or more selected from hydrogen, oxygen, and water. Like the insulator 594, the insulator 599 is preferably formed using an insulator having a relatively low dielectric constant to reduce parasitic capacitance generated between wirings. The insulator 599 has functions of an interlayer insulating film and a planarization film.

The light-emitting device 650 and a connection portion 640 are formed over the insulator 599. Note that structure examples of the light-emitting device will be described later in Embodiment 5.

The connection portion 640 is referred to as a cathode contact portion in some cases, and is electrically connected to cathode electrodes of the light-emitting device 650R, the light-emitting device 650G, and the light-emitting device 650B. In the connection portion 640 shown in FIG. 27, a conductor formed using the same material in the same step as a conductor 611a to a conductor 611c is electrically connected to a common electrode 615 described later. Although FIG. 27 shows an example where the conductor is electrically connected to the common electrode 615 through a common layer 614 described later, the conductor and the common electrode 615 may be in direct contact with each other.

Note that the connection portion 640 may be provided to surround four sides of the display portion in the plan view, or may be provided in the display portion (e.g., between adjacent light-emitting devices 650) (not shown).

The light-emitting device 650R includes the conductor 611a as a pixel electrode. Similarly, the light-emitting device 650G includes the conductor 611b as a pixel electrode, and the light-emitting device 650B includes the conductor 611c as a pixel electrode.

The conductor 611a, the conductor 611b, and the conductor 611c are connected to the conductor 596 embedded in the insulator 594 through a conductor (plug) embedded in the insulator 599.

The light-emitting device 650R includes a layer 613a, the common layer 614 over the layer 613a, and the common electrode 615 over the common layer 614. The light-emitting device 650G includes a layer 613b, the common layer 614 over the layer 613b, and the common electrode 615 over the common layer 614. The light-emitting device 650B includes a layer 613c, the common layer 614 over the layer 613c, and the common electrode 615 over the common layer 614.

The display apparatus 600A employs an SBS structure. The SBS structure can optimize materials and structures of light-emitting devices and thus can extend freedom of choice of materials and structures, whereby the luminance and the reliability can be easily improved.

The display apparatus 600A has a top-emission structure. The aperture ratio of pixels in a top-emission structure can be higher than that of pixels in a bottom-emission structure because a transistor and the like can be provided so as to overlap with a light-emitting region of a light-emitting device in the top-emission structure.

Note that the layer 613a is formed to cover the top and side surfaces of the conductor 611a. Similarly, the layer 613b is formed to cover the top and side surfaces of the conductor 611b. Similarly, the layer 613c is formed to cover the top and side surfaces of the conductor 611c. Accordingly, regions provided with the conductor 611a, the conductor 611b, and the conductor 611c can be entirely used as the light-emitting regions of the light-emitting device 650R, the light-emitting device 650G, and the light-emitting device 650B, respectively, increasing the aperture ratio of the pixels.

In the light-emitting device 650R, the layer 613a and the common layer 614 can be collectively referred to as an EL layer. Similarly, in the light-emitting device 650G, the layer 613b and the common layer 614 can be collectively referred to as an EL layer. Similarly, in the light-emitting device 650B, the layer 613c and the common layer 614 can be collectively referred to as an EL layer

There is no particular limitation on the structure of the light-emitting device in this embodiment, and the light-emitting device can have a single structure or a tandem structure.

The layer 613a, the layer 613b, and the layer 613c are each processed into an island shape by a photolithography method. At each of end portions of the layer 613a, the layer 613b, and the layer 613c, an angle between the top surface and side surface is approximately 90°. By contrast, for example, an organic film formed using an FMM (Fine Metal Mask) tends to have a thickness that gradually decreases with decreasing distance to an end portion, and has a sloped top surface in an area ranging from 1 μm to 10 μm, both inclusive, toward the end portion for example; thus, such an organic film has a shape whose top surface and side surface cannot be easily distinguished from each other.

The top surface and the side surface of each of the layer 613a, the layer 613b, and the layer 613c are clearly distinguished from one another. Accordingly, regarding the layer 613a and the layer 613b which are adjacent to each other, one of the side surfaces of the layer 613a and one of the side surfaces of the layer 613b are placed to face each other. This applies to a combination of any two of the layer 613a, the layer 613b, and the layer 613c.

The layer 613a, the layer 613b, and the layer 613c each include at least a light-emitting layer. It is preferable that the layer 613a include a red-light-emitting layer, the layer 613b include a green-light-emitting layer, and the layer 613c include a blue-light-emitting layer, for example. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since the surfaces of the layer 613a, the layer 613b, and the layer 613c are exposed in the manufacturing process of the display apparatus, providing the carrier-transport layer over the light-emitting layer inhibits the light-emitting layer from being exposed on the outermost surface, so that damage to the light-emitting layer can be reduced. Accordingly, the reliability of the light-emitting devices can be improved.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared between the light-emitting device 650R, the light-emitting device 650G, and the light-emitting device 650B. Note that the common layer 614 is not necessarily provided, and the whole EL layer included in the light-emitting device may be provided in an island shape like the layer 613a, the layer 613b, and the layer 613c.

The common electrode 615 is shared by the light-emitting device 650R, the light-emitting device 650G, and the light-emitting device 650B. As shown in FIG. 27, the common electrode 615 shared by the plurality of light-emitting devices is electrically connected to a conductor included in the connection portion 640.

An insulator 625 preferably has a function of a barrier insulating layer against one or both of water and oxygen. Alternatively, the insulator 625 preferably has a function of inhibiting diffusion of one or both of water and oxygen. Alternatively, the insulator 625 preferably has a function of capturing or fixing (also referred to as gettering) one or both of water and oxygen. When the insulator 625 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display apparatus can be provided.

The insulator 625 preferably has a low impurity concentration. Accordingly, degradation of the EL layer, which is caused by entry of impurities into the EL layer from the insulator 625, can be inhibited. In addition, when the impurity concentration is reduced in the insulator 625, a barrier property against one or both of water and oxygen can be increased. For example, it is desirable that one or both of the hydrogen concentration and the carbon concentration in the insulator 625 be sufficiently low.

As an insulator 627, an insulating layer including an organic material can be favorably used. As the organic material, a photosensitive organic resin is preferably used; for example, a photosensitive resin composition including an acrylic resin may be used. Note that in this specification and the like, an acrylic resin refers to not only a polymethacrylic acid ester or a methacrylic resin, but also all the acrylic-based polymers in a broad sense in some cases.

The organic material that can be used for the insulator 627 is not limited to the materials given above. For the insulator 627, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 627 in some cases. For the insulator 627, for example, a photoresist can be used as the photosensitive resin in some cases. Note that as the photosensitive resin, a positive material or a negative material can be used.

For the insulator 627, a material absorbing visible light may be used. When the insulator 627 absorbs light from the light-emitting device, leakage of light (stray light) from the light-emitting device to the adjacent light-emitting device through the insulator 627 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials including pigment of black or the like, materials including dye, light-absorbing resin materials (e.g., polyimide), and resin materials that can be used for color filters (color filter materials). A resin material obtained by stacking or mixing color filter materials of two colors or three or more colors is particularly preferably used to enhance the effect of blocking visible light. In particular, mixing color filter materials of three or more colors enables the formation of a black or nearly black resin layer.

For example, the insulator 627 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film to be the insulator 627 is preferably formed by spin coating.

The insulator 627 is formed at a temperature lower than the heat resistance temperature of the EL layer. The typical substrate temperature in formation of the insulator 627 is lower than or equal to 200° C., preferably lower than or equal to 180° C., further preferably lower than or equal to 160° C., still further preferably lower than or equal to 150° C., yet still further preferably lower than or equal to 140° C.

In the above, the insulator 627 preferably has a tapered side surface. Such a forward tapered shape (less than 90°, preferably less than or equal to 60°, further preferably less than or equal to 45°) of the end portion of the side surface of the insulator 627 can prevent disconnection, local thinning, or the like from occurring in the common layer 614 and the common electrode 615 which are provided over the end portion of the side surface of the insulator 627, leading to film formation with good coverage. Accordingly, the in-plane uniformity of the common layer 614 and the common electrode 615 can be improved, leading to higher display quality of the display apparatus.

The top surface of the insulator 627 preferably has a convex shape in a cross-sectional view of the display apparatus. The top surface of the insulator 627 preferably has a convex shape that bulges gradually toward the center. The insulator 627 preferably has a shape such that the projecting portion at the center portion of the top surface is connected smoothly to the tapered portion of the end portion of the side surface. When the insulator 627 has such a shape, the common layer 614 and the common electrode 615 can be formed with good coverage over the whole the insulator 627.

The insulator 627 is formed in a region between two EL layers (e.g., a region between the first layer 613a and the second layer 613b). At this time, part of the insulator 627 is placed at a position sandwiched between an end portion of the side surface of one of the EL layers (e.g., the layer 613a) and an end portion of the side surface of the other of the EL layers (e.g., the layer 613b).

One end portion of the insulator 627 preferably overlaps with the conductor 611a functioning as a pixel electrode, and the other end portion of the insulator 627 preferably overlaps with the conductor 611b functioning as a pixel electrode. Such a structure enables the end portion of the insulator 627 to be formed over flat or substantially flat region in the layer 613a (layer 613b). This makes it relatively easy to process the tapered shape of the insulator 627 as described above.

By providing the insulator 627 and the like in the above manner, a disconnected portion and a locally thinned portion can be prevented from being formed in the common layer 614 and the common electrode 615 from a flat or substantially flat region in the layer 613a to a flat or substantially flat region in the layer 613b. Thus, between the light-emitting devices, a connection defect caused by the disconnected portion and an increase in electric resistance caused by the locally thinned portion can be inhibited from occurring in the common layer 614 and the common electrode 615.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a high-resolution display apparatus with a high aperture ratio can be provided.

A protective layer 631 is provided over the light-emitting device 650. The protective layer 631 is a film functioning as a passivation film for protecting the light-emitting devices 650. Provision of the protective layer 631 covering the light-emitting device can inhibit an impurity such as water and oxygen from entering the light-emitting device, and increase the reliability of the light-emitting device 650. For the protective layer 631, aluminum oxide, silicon nitride, or silicon nitride oxide can be used, for example.

The protective layer 631 and a substrate 610 are bonded to each other with an adhesive layer 607. A solid sealing structure, a hollow sealing structure, or the like can be employed to seal the light-emitting devices. In FIG. 27, a solid sealing structure is employed in which a space between the substrate 410 and the substrate 610 is filled with the adhesive layer 607. Alternatively, a hollow sealing structure may be employed, in which the space is filled with an inert gas (e.g., nitrogen or argon). Here, the adhesive layer 607 may be provided not to overlap with the light-emitting devices. The space may be filled with a resin other than the frame-shaped adhesive layer 607.

For the adhesive layer 607, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet may be used.

The display apparatus 600A has a top-emission structure. Light from the light-emitting device is emitted toward the substrate 610 side. Thus, for the substrate 610, a material having a high visible-light-transmitting property is preferably used. For example, as the substrate 610, a substrate having a high visible-light-transmitting property may be selected from substrates usable as the substrate 410. The pixel electrode includes a material that reflects visible light, and a counter electrode (the common electrode 615) includes a material that transmits visible light.

Note that the display apparatus of one embodiment of the present invention may be not a top-emission display apparatus but a bottom-emission display apparatus where light from the light-emitting device is emitted to the substrate 410 side. In that case, a substrate having a high visible-light-transmitting property is selected as the substrate 410.

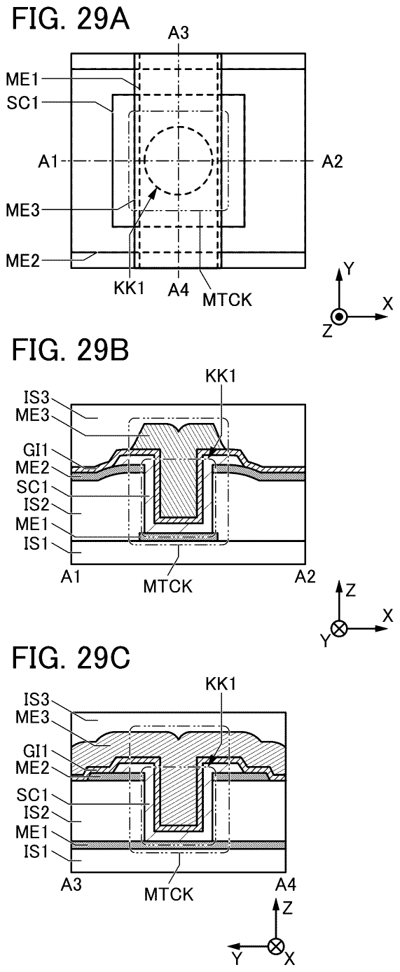

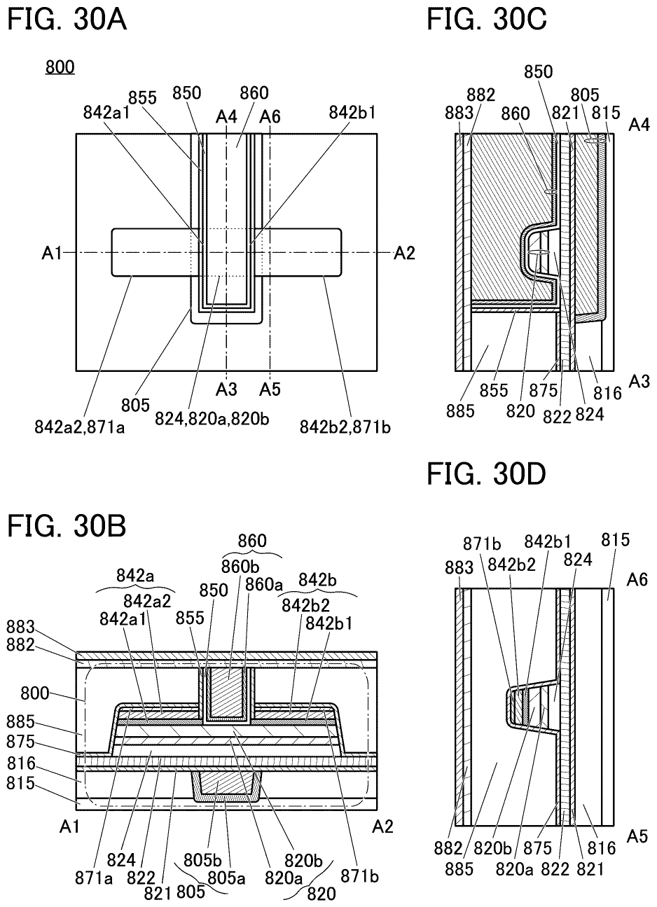

Although the element layer 630 of the display apparatus 600A in FIG. 27 includes the transistor MTCK, one embodiment of the present invention is not limited thereto. Note that there is no particular limitation on the structure of the transistor included in the display apparatus of one embodiment of the present invention. One or more kinds of transistors can be used in the display apparatus of one embodiment of the present invention. For example, one or both of the transistor MTCK shown in FIG. 29 and a transistor 800 shown in FIG. 30 can be used. One or both of an OS transistor and a Si transistor can be used in the display apparatus of one embodiment of the present invention.

### Structure Example 2 of Display Apparatus

FIG. 28 is a cross-sectional view of a display apparatus 600B.

The display apparatus 600B can be a display apparatus having flexibility (also referred to as flexible display device) when a flexible substrate is used as each of a substrate 541 and the substrate 610. The substrate 541 is bonded to an insulating layer 545 with an adhesive layer 543. The substrate 610 is bonded to the protective layer 631 with the adhesive layer 607. An example of a manufacturing method of a flexible device is described later in this embodiment.

The element layer 660 of the display apparatus 600B is different from the element layer 660 of the display apparatus 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are separated from one another. When the EL layer is provided in an island shape for each light-emitting device, a leakage current between adjacent light-emitting devices (sometimes referred to as a horizontal-direction leakage current, a horizontal leakage current, or a lateral leakage current) can be inhibited. Accordingly, unintentional light emission due to crosstalk can be prevented, and color mixture between adjacent light-emitting devices can be inhibited, so that a display apparatus with extremely high contrast can be obtained.

The light-emitting devices 650R, 650G, and 650B shown in FIG. 28 emit white light, for example. White light emitted from the light-emitting devices 650R, 650G, and 650B passes through the coloring layer 628R, the coloring layer 628G, and the coloring layer 628B, whereby light of a desired color can be obtained.

In the case where the light-emitting device configured to emit white light has a microcavity structure, light with a specific wavelength such as red, green, or blue is sometimes intensified and emitted.

Light emitted by the light-emitting device 650R is extracted as red light to the outside of the display apparatus 600B through the coloring layer 628R. Similarly, light emitted by the light-emitting device 650G is extracted as green light to the outside of the display apparatus 600B through the coloring layer 628G. Light emitted by the light-emitting device 650B is extracted as blue light to the outside of the display apparatus 600B through the coloring layer 628B.

A light-emitting device that emits white light preferably has a tandem structure. A structure example of the light-emitting device having a tandem structure is described in detail in Embodiment 5.

Alternatively, the light-emitting devices 650R, 650G, and 650B shown in FIG. 28 emit blue light, for example. In this case, the layer 613a, the layer 613b, and the layer 613c include one or more light-emitting layers that emit blue light. In a subpixel that emits blue light, blue light emitted from the light-emitting device 650B can be extracted. In each of the subpixel emitting red light and the subpixel emitting green light, a color conversion layer is provided between the light-emitting device 650R and the coloring layer 628R and between the light-emitting device 650G and the coloring layer 628G, so that blue light emitted from the light-emitting device 650R or the light-emitting device 650G is converted into light with a longer wavelength and red light or green light can be extracted. When light transmitted through the color conversion layer is extracted through the coloring layer, light other than light of the intended color can be absorbed by the coloring layer, and color purity of light exhibited by the subpixel can be improved.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

The element layer 630 of the display apparatus 600B has a structure similar to that of the element layer 630 of the display apparatus 600A; thus, the detailed description thereof is omitted.

The display apparatus 600B is different from the display apparatus 600A in not including the element layer 620 but including an element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display apparatus are preferably provided in the element layer 635.

Although FIG. 28 shows an example where two element layers (the element layer 630 and the element layer 635) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display apparatus, the uppermost layer be used for the pixel circuit of the display apparatus, and one or more layers between them be used for the pixel circuit or the driver circuit.

A Si transistor is typically formed on a single crystal Si wafer, and thus is difficult to have flexibility. Meanwhile, as shown in FIG. 28, in the case where the display apparatus is formed using only OS transistors without using a Si transistor, the display apparatus can have flexibility through a relatively simple manufacturing process.

### Structure Example 1 of Transistor

FIG. 29A to FIG. 29C show an example of a semiconductor device (showing, for example, a pixel circuit or a driver circuit) including the transistor MTCK. Specifically, FIG. 29A is a schematic plan view of the transistor MTCK. FIG. 29B is a schematic cross-sectional view corresponding to a portion along the dashed-dotted line A1-A2 shown in FIG. 29A, and is also a schematic cross-sectional view of the transistor MTCK. FIG. 29C is a schematic cross-sectional view corresponding to a portion along the dashed-dotted line A3-A4 shown in FIG. 29A, and is also a schematic cross-sectional view of the transistor MTCK.

Note that in FIG. 29A to FIG. 29C, the direction of the dashed-dotted line A1-A2 is an X direction, and the direction of the dashed-dotted line A3-A4 is a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 29A and the like, in some cases, the right side, the left side, the upper side, and the lower side are referred to as the X direction, a −X direction, the Y direction, and a −Y direction, respectively. In the description of the schematic cross-sectional view in FIG. 29B and the like, in some cases, the right side, the left side, the upper side, and the lower side are referred to as the X direction, the −X direction, the Z direction, and a −Z direction, respectively. In the description of the schematic cross-sectional view such as FIG. 29C, in some cases, the right side, the left side, the upper side, and the lower side are referred to as the −Y direction, a +Y direction, the Z direction, and the −Z direction, respectively.

The transistor MTCK in FIG. 29A to FIG. 29C includes the insulator IS1 to the insulator IS3, the insulator GI1, a conductor ME1 to a conductor ME3, and a semiconductor SC1.

The insulator IS1 functions as, for example, a base film above which a source, a drain, and a channel formation region of the transistor MTCK are to be provided. For the insulator IS1, silicon oxide, silicon oxynitride, silicon nitride oxide, or silicon nitride may be used, for example. Alternatively, for the insulator IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region including oxygen to be released by heating can be easily formed. Alternatively, for the insulator IS1, a resin can be used, for example. A material used for the insulator IS1 may be an appropriate combination of the above-described insulating materials.

The conductor ME1 is a conductor (sometimes rephrased as a terminal, a wiring, or the like) functioning as one of the source and the drain in the transistor MTCK. The conductor ME2 is a conductor (sometimes rephrased as a terminal, a wiring, or the like) functioning as the other of the source and the drain in the transistor MTCK.

Note that in FIG. 29A to FIG. 29C, the conductor ME1 is provided as a wiring to extend in the Y direction, for example. The conductor ME2 is provided as a wiring to extend in the X direction, for example.

For the conductive film ME1, the conductor ME2, and the conductor ME3, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including two or more selected from the above metal elements; or an alloy including a combination of two or more selected from the above metal elements, for example. As the conductive film ME1, the conductor ME2, and the conductor ME3, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that maintain their conductivity even after absorbing oxygen. As the conductor, a semiconductor having high electrical conductivity, typified by polycrystalline silicon including an impurity element (e.g., phosphorus or arsenic), or silicide (e.g., nickel silicide) may be used, for example.

An oxide conductor may be used for the conductor ME1, the conductor ME2, and the conductor ME3. Examples of an oxide conductor include indium oxide, zinc oxide, In—Sn oxide (ITO), In—Zn oxide (also denoted as IZO (registered trademark)), In—W oxide, In—W—Zn oxide, In—Ti oxide, In—Ti—Sn oxide, In—Sn—Si oxide (also referred to as ITO including silicon or ITSO), zinc oxide to which gallium is added, and In—Ga—Zn oxide. A conductive oxide including indium has high conductivity, and thus is particularly preferable.

A stack of a plurality of conductive films formed of the above-described materials may be used. For example, a stacked-layer structure combining a material including the above metal element and a conductive material including oxygen may be employed. Specific examples of the stacked-layer structure of the conductive film include a stacked-layer structure of indium oxide and a metal film including ruthenium. In addition, a stacked-layer structure combining a material including the above metal element and a conductive material including nitrogen may be employed. Furthermore, a stacked-layer structure combining a material including the above metal element, a conductive material including oxygen, and a conductive material including nitrogen may be employed.

The insulator IS2 functions as, for example, an interlayer film that separates the source and the drain in the transistor MTCK. For the insulating film IS2, a material that can be used for the insulator IS1 can be used, for example. In the case where the semiconductor SC1 is a metal oxide functioning as an oxide semiconductor, for example, silicon oxide, silicon oxynitride, and porous silicon oxide are preferably used. With these materials, a region including oxygen released by heating can be easily formed, and the released oxygen can be supplied to the metal oxide. This reduces the carrier concentration of the metal oxide at the interface between the semiconductor SC1 and the insulator IS2 in contact with each other and the vicinity of the interface, so that the interface and the vicinity of the interface in the semiconductor SC1 become i-type or substantially i-type. Accordingly, the interface of the semiconductor SC1 and the vicinity of the interface can function as the channel formation region of the transistor MTCK.

The semiconductor film SC1 can be a metal oxide functioning as an oxide semiconductor, for example. In this case, the transistor MTCK is an OS transistor. The metal oxide preferably includes at least indium or zinc, for example. In particular, indium and zinc are preferably included. In addition to them, an element M is preferably included. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably includes one or both of gallium and tin.

More specific examples of the metal oxide include indium oxide, gallium oxide, zinc oxide, indium zinc oxide (IZO (registered trademark)), indium tin oxide, indium titanium oxide, indium gallium oxide, indium gallium aluminum oxide, indium gallium tin oxide, gallium zinc oxide (also referred to as GZO), aluminum zinc oxide (also referred to as AZO), indium aluminum zinc oxide (also referred to as IAZO), indium tin zinc oxide (also referred to as ITZO (registered trademark)), indium titanium zinc oxide, indium gallium zinc oxide (also referred to as IGZO), indium gallium tin zinc oxide (also referred to as IGZTO), or indium gallium aluminum zinc oxide. Alternatively, indium tin oxide including silicon, gallium tin oxide, aluminum tin oxide, or the like can be given as an example. Note that a material that does not include Zn, such as indium oxide, is preferable in that it improves the compatibility with an LSI manufacturing process. By contrast, a material that includes Zn is preferred in that crystallinity can be easily increased.

When the semiconductor SC1 is a metal oxide functioning as an oxide semiconductor, it is preferably formed by an ALD (Atomic Layer Deposition) method. As shown in FIG. 29B and FIG. 29C, when the semiconductor SC1 is formed in a region having a step, an ALD method enables favorable coverage.

In the case where a metal oxide functioning as an oxide semiconductor is used as the semiconductor SC1, microwave treatment is preferably performed in an atmosphere including oxygen during or after the film formation of the metal oxide to reduce the impurity concentration in the metal oxide. Specific examples of the impurity include hydrogen and carbon. The microwave treatment can increase the crystallinity of the metal oxide in some cases. Here, the microwave treatment refers to, for example, treatment using an apparatus including a power source that generates high-density plasma with use of a microwave.

It is preferable to use a metal oxide layer having crystallinity as the semiconductor SC1. For example, a metal oxide layer having a CAAC (c-axis aligned crystal) structure, a polycrystalline structure, a nano-crystal (nc) structure, or the like can be used. With use of the metal oxide layer having crystallinity as the semiconductor SC1, the density of defect states in the semiconductor SC1 can be reduced, which enables the semiconductor device to have high reliability.

For the semiconductor SC1, for example, an In—Ga—Zn oxide is preferably used. In particular, the In—Ga—Zn oxide is further preferably a metal oxide with a composition of In:Ga:Zn =1:1:1 [atomic ratio] or in the neighborhood thereof, a composition of 4:2:3 [atomic ratio] or in the neighborhood thereof, or a composition of 3:1:2 [atomic ratio] or in the neighborhood thereof. For another example, an In—Zn oxide is preferably used for a semiconductor film SC1A. In particular, the In—Zn oxide is further preferably a metal oxide with a composition of In:Zn=4:1 [atomic ratio] or in the neighborhood thereof.

The semiconductor SC1 preferably has a stacked-layer structure of a plurality of oxide layers that differ in the atomic ratio of metal atoms. As the metal oxide, for example, a first metal oxide and a second metal oxide formed over the first metal oxide are considered. For example, in the case where the metal oxides each include at least indium (In) and the element M, the proportion of the number of atoms of the element M included in the first metal oxide to the number of atoms of all elements that constitute the first metal oxide is preferably higher than the proportion of the number of atoms of the element M included in the second metal oxide to the number of atoms of all elements that constitute the second metal oxide. In addition, the atomic ratio of the element M to In in the first metal oxide is preferably greater than the atomic ratio of the element M to In in the second metal oxide.

Specifically, as the first metal oxide, a metal oxide with a composition of In:Ga:Zn=1:3:4 [atomic ratio] or in the neighborhood thereof, 1:3:2 [atomic ratio] or in the neighborhood thereof, or 1:1:0.5 [atomic ratio] or in the neighborhood thereof can be used. As the second metal oxide, a metal oxide with a composition of In:Ga:Zn=1:1:1 [atomic ratio] or in the neighborhood thereof, 4:2:3 [atomic ratio] or in the neighborhood thereof, or 3:1:2 [atomic ratio] or in the neighborhood thereof can be used. Note that the neighborhood of the atomic ratio includes ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

In a region of the insulator IS2 where the transistor MTCK is provided, an opening KK1 whose side surface is substantially perpendicular (a taper angle greater than or equal to 700 and less than or equal to 110°) to an X-Y plane is formed. The semiconductor SC1 including the channel formation region of the transistor MTCK is provided to be in contact with the conductor ME1 and the conductor ME2 through the opening KK1.

In the transistor MTCK, the insulator GI1 is provided over the semiconductor SC1. Specifically, the insulator GI1 is positioned above and overlaps with the channel formation region included in the semiconductor SC1 in the plan view. The insulator GI1 functions as a gate insulating film of the transistor MTCK.

Thus, for the insulator GI1, a single layer or a stacked layer using an insulator including what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST) is preferably used. Alternatively, for the insulator GI1, as an insulator with a high dielectric constant, an oxide including aluminum and hafnium, an oxynitride including aluminum and hafnium, an oxide including silicon and hafnium, an oxynitride including silicon and hafnium, or a nitride including silicon and hafnium may be used. A material that can be used for the insulator IS1 may be used for the insulator GI1. For the insulator GI1, silicon oxide, silicon oxynitride, silicon nitride oxide, or silicon nitride may be used, for example.

In the transistor MTCK, the conductor ME3 is provided over the insulator GI1 to fill the opening KK1. The conductor ME3 is a conductor (sometimes rephrased as a terminal, a wiring, or the like) functioning as a gate in the transistor MTCK.

Note that in FIG. 29A to FIG. 29C, the conductor ME3 is provided as a wiring to extend in the Y direction, for example.

The insulator IS3 is a film functioning as an interlayer film, for example. Thus, the insulator IS3 preferably includes an insulating material with a low dielectric constant. When an insulating material with a low dielectric constant is used for an interlayer film, parasitic capacitance generated between wirings can be reduced.

For the insulator IS3, a material that can be used for the insulator IS1 can be used, for example.

As described above, in the transistor MTCK shown in FIG. 29A to FIG. 29C, the conductor ME1 functioning as one of the source and the drain is positioned below the insulator IS2 functioning as an interlayer film, and the conductor ME2 functioning as the other of the source and the drain is positioned above the insulator IS2. Thus, the transistor MTCK has a structure in which the channel formation region is provided along the opening in the insulator IS2.

In the transistor MTCK, the source and the drain are positioned at different levels, so that a current flows in the semiconductor layer in the height direction. In other words, the channel length direction can be regarded as having a component of the height direction (the vertical direction); accordingly, the transistor MTCK can also be referred to as a VFET (Vertical Field Effect Transistor), a vertical transistor, a vertical-channel transistor, a vertical-channel-type transistor, and the like.

As shown in FIG. 29A to FIG. 29C, when the channel formation region of the transistor is provided along the side surface of the opening in the insulator functioning as an interlayer film, the area occupied by the transistor can be smaller than that in the case where the channel formation region of the transistor is provided along the X-Y plane. Thus, when a circuit is formed using one or both of the transistor MTCK, the area of the circuit can be small. This results in a reduction in size of a semiconductor device including the circuit or a display apparatus including the circuit.

### Structure Example 2 of Transistor

FIG. 30A is a schematic top view of the transistor 800. FIG. 30B is a cross-sectional view taken along the dashed-dotted line A1-A2 in FIG. 30A. FIG. 30B is also a cross-sectional view of the transistor 800 in the channel length direction. FIG. 30C is a cross-sectional view taken along the dashed-dotted line A3-A4 in FIG. 30A. FIG. 30C is also a cross-sectional view of the transistor 800 in the channel width direction. FIG. 30D is a cross-sectional view taken along a dashed-dotted line A5-A6 in FIG. 30A. FIG. 30D is also a cross-sectional view of the transistor 800 in the channel width direction. Note that for clarity of the drawing, some components are not shown in the top view of FIG. 30A.

The transistor 800 includes a conductor 805 (a conductor 805a and a conductor 805b) provided to be embedded in an insulator 816; an insulator 821 over the insulator 816 and the conductor 805; an insulator 822 over the insulator 821; an insulator 824 over the insulator 822; an oxide 820 (an oxide 820a and an oxide 820b) over the insulator 824; a conductor 842a (a conductor 842al and a conductor 842a2) and a conductor 842b (a conductor 842b1 and a conductor 842b2) over the oxide 820; an insulator 871a over the conductor 842a; an insulator 871b over the conductor 842b; an insulator 850 over the oxide 820; and a conductor 860 (a conductor 860a and a conductor 860b) over the insulator 850.

An insulator 875 is provided over the insulators 871a and 871b, and an insulator 885 is provided over the insulator 875. An insulator 855, the insulator 850, and the conductor 860 are placed in an opening provided in the insulator 885 and the insulator 875. An insulator 882 is provided over the insulator 885 and the conductor 860. An insulator 883 is provided over the insulator 882. An insulator 815 is provided below the insulator 816 and the conductor 805. The insulator 855 is provided between the insulator 850 and the conductor 842a2, the conductor 842b2, the insulator 871a, the insulator 871b, the insulator 875, and the insulator 885.

Note that the insulator 815, the insulator 816, the conductor 805, the insulator 821, the insulator 822, the insulator 824, the oxide 820, the conductor 842a, the conductor 842b, the insulator 871a, the insulator 871b, the insulator 875, the insulator 885, the insulator 855, the insulator 850, the conductor 860, the insulator 882, and the insulator 883 may each have a single-layer structure or a stacked-layer structure.

The oxide 820 includes a region functioning as a channel formation region. The conductor 860 includes a region functioning as a first gate electrode (an upper gate electrode). The insulator 850 includes a region functioning as a first gate insulator. The conductor 805 includes a region functioning as a second gate electrode (a lower gate electrode). The insulator 824, the insulator 822, and the insulator 821 each include a region functioning as a second gate insulator.

The conductor 842a includes a region functioning as one of a source electrode and a drain electrode. The conductor 842b includes a region functioning as the other of the source electrode and the drain electrode.

The oxide 820 preferably includes the oxide 820a over the insulator 824 and the oxide 820b over the oxide 820a. Including the oxide 820a under the oxide 820b makes it possible to inhibit diffusion of impurities into the oxide 820b from components formed below the oxide 820a. Note that the oxide 820 may have a single-layer structure of the oxide 820b or a stacked-layer structure of three or more layers.

The oxide 820b includes the channel formation region and a source region and a drain region provided to sandwich the channel formation region. At least part of the channel formation region overlaps with the conductor 860. The source region overlaps with the conductor 842a, and the drain region overlaps with the conductor 842b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the channel formation region, the source region, and the drain region may each be formed not only in the oxide 820b but also in the oxide 820a.

In the oxide 820, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

An oxide semiconductor is preferably used for the oxide 820 (the oxide 820a and the oxide 820b).

The oxide 820 preferably has a stacked-layer structure of a plurality of oxide layers with different chemical compositions. For example, the atomic ratio of the element M to a metal element that is a main component in the oxide 820a is preferably greater than that in the oxide 820b. The atomic ratio of the element M to In in the oxide 820a is preferably greater than that in the oxide 820b. With this structure, impurities and oxygen can be inhibited from diffusing into the oxide 820b from the components formed below the oxide 820a.

The atomic ratio of In to the element Min the oxide 820b is preferably greater than the atomic ratio of In to the element Min the oxide 820a. With this structure, the transistor 800 can have a high on-state current and excellent frequency characteristics.

When the oxide 820a and the oxide 820b include a common element as the main component besides oxygen, the density of defect states at the interface between the oxide 820a and the oxide 820b can be decreased. Thus, the influence of interface scattering on carrier conduction is reduced, and the transistor 800 can have a high on-state current and high frequency characteristics.

Specifically, for the oxide 820a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 820b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. It is preferable to use gallium as the element M. In the case where a single layer of the oxide 820b is provided as the oxide 820, a metal oxide usable for the oxide 820a may be used for the oxide 820b. Note that the compositions of the metal oxides usable for the oxide 820a and the oxide 820b are not limited to the above. For example, a metal oxide usable for the oxide 820a may be used for the oxide 820b, or a metal oxide usable for the oxide 820b may be used for the oxide 820a.

When the metal oxide is formed by a sputtering method, the above atomic ratio is not limited to the atomic ratio of the formed metal oxide and may be the atomic ratio of a sputtering target used for forming the metal oxide.

The oxide 820b preferably has crystallinity. It is particularly preferable to use a CAAC-OS for the oxide 820b. This can inhibit oxygen extraction from the oxide 820b by the source electrode or the drain electrode. Furthermore, oxygen extraction from the oxide 820b can be reduced even when heat treatment is performed; thus, the transistor 800 is stable with respect to high temperatures in the manufacturing process (what is called thermal budget).

Examples of materials that can be used for the conductors, the insulators, and the oxide semiconductor included in the transistor 800 include the above-described materials that can be used for the conductor ME1 to the conductor ME3. A typical example is described below.

The conductor 842a has a stacked structure of the conductor 842al and the conductor 842a2, and the conductor 842b has a stacked structure of the conductor 842b1 and the conductor 842b2. The conductor 842al and the conductor 842b1 in contact with the oxide 820b are preferably conductors that are not easily oxidized, such as metal nitride. Thus, the conductor 842a and the conductor 842b can be prevented from being oxidized excessively by oxygen included in the oxide 820b. The conductor 842a2 and the conductor 842b2 are preferably conductors having higher conductivity than the conductor 842al and the conductor 842b1, such as a metal layer. Accordingly, the conductor 842a and the conductor 842b can each function as a wiring or an electrode with high conductivity.

For example, tantalum nitride or titanium nitride can be used for the conductor 842al and the conductor 842b1, and tungsten can be used for the conductor 842a2 and the conductor 842b2.

The opening formed in the insulator 885 and the insulator 875 overlap with a region between the conductor 842a2 and the conductor 842b2. In a plan view, the side surface of the opening in the insulator 885 is aligned or substantially aligned with the side surface of the conductor 842a2 and the side surface of the conductor 842b2. The conductor 842a1 and the conductor 842b1 are formed to partly extend toward the inside of the opening. Here, part of a top surface of the conductor 842a1 is in contact with the conductor 842a2, and part of a top surface of the conductor 842b1 is in contact with the conductor 842b2. Thus, the insulator 855 is in contact with another part of the top surface of the conductor 842al, another part of the top surface of the conductor 842b1, and the side surface of the conductor 842a2, and the side surface of the conductor 842b2 in the opening. The insulator 850 is in contact with the top surface of the oxide 820, the side surface of the conductor 842al, the side surface of the conductor 842b1, and the side surface of the insulator 855.

The insulator 855 is preferably an insulator that is not easily oxidized, such as nitride. By anisotropic etching, the insulator 855 is formed to be in contact with the sidewall of the opening formed in the insulator 885 and the like (here, the sidewall of the opening corresponds to, for example, the side surface of the insulator 885 or the like). The insulator 855 is formed in contact with the side surface of the conductor 842a2 and the side surface of the conductor 842b2 and has a function of protecting the conductor 842a2 and the conductor 842b2. In order to supply oxygen to the oxide 820b, heat treatment in an atmosphere including oxygen is preferably performed after the separation into the conductor 842a1 and the conductor 842b1 and before the formation of the insulator 850. At this time, since the insulator 855 is formed in contact with the side surface of the conductor 842a2 and the side surface of the conductor 842b2, excessive oxidation of the conductor 842a2 and the conductor 842b2 can be prevented. The insulator 855 can be formed using silicon nitride, for example.

The insulator 850 preferably has a function of capturing or fixing hydrogen. Thus, the hydrogen concentration in the channel formation region of the oxide 820b can be reduced. Accordingly, VoH in the channel formation region can be reduced, so that the channel formation region can be an i-type or substantially i-type region.

The insulator 850 functions as a gate insulator. The insulator 850 is provided in the opening formed in the insulator 885, together with the insulator 855 and the conductor 860. The thickness of the insulator 850 is preferably small for miniaturization of the transistor 800. The thickness of each layer included in the insulator 850 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Each of the layers included in the insulator 850 at least partly includes a region with the above-described thickness.

The insulator 850 is preferably formed by an ALD method. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

The thickness of the insulator 855 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 855 has a thickness in the above range, excessive oxidation of the conductor 842a2 and the conductor 842b2 can be inhibited. In this case, at least part of the insulator 855 has a region with the above-described thickness. When the thickness of the insulator 855 is set excessively large, the time for forming the insulator 855 by an ALD method is long, which decreases the productivity; for this reason, the thickness of the insulator 855 is preferably in the above range.

Each of the insulator 815, the insulator 821, the insulator 822, the insulator 882, and the insulator 883 preferably includes an insulator having a function of inhibiting diffusion of oxygen and impurities such as water and hydrogen. Examples of the insulator include aluminum oxide, magnesium oxide, hafnium oxide, zirconium oxide, oxide including aluminum and hafnium (hafnium aluminate), oxide including hafnium and zirconium (hafnium zirconium oxide), gallium oxide, silicon nitride, and silicon nitride oxide. For example, silicon nitride, which has a higher hydrogen barrier property, is preferably used for the insulator 883 and the insulator 821. For example, the insulator 882 preferably includes aluminum oxide or the like, which has a function of capturing and fixing hydrogen well. For example, hafnium oxide, which has high capability of capturing or fixing hydrogen and is a high dielectric constant (high-k) material, is preferably used for the insulator 822.

The conductor 805 is placed to overlap with the oxide 820 and the conductor 860. Here, the conductor 805 is preferably provided to be embedded in an opening portion formed in the insulator 816. Moreover, the conductor 805 is preferably provided to extend in the channel width direction as shown in FIG. 30A and FIG. 30C. With such a structure, the conductor 805 functions as a wiring when a plurality of transistors are provided.

As shown in FIG. 30B and FIG. 30C, the conductor 805 preferably includes the conductor 805a and the conductor 805b. The conductor 805a is provided in contact with the bottom surface and the sidewall of the opening portion. The conductor 805b is provided to fill a depressed portion that is defined by the conductor 805a and formed along the opening portion. Here, the top surface of the conductor 805 is level or substantially level with the top surface of the insulator 816.

When the conductor 805a is formed using a conductive material having a function of inhibiting diffusion of hydrogen, impurities such as hydrogen included in the conductor 805b can be prevented from diffusing into the oxide 820 through the insulator 816 and the like. When a conductive material having a function of inhibiting diffusion of oxygen is used for the conductor 805a, the conductivity of the conductor 805b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 805a can have a single-layer structure or a stacked-layer structure of the above conductive material. For example, the conductor 805a preferably includes titanium nitride.

The conductor 805b is preferably formed using a conductive material including tungsten, copper, or aluminum as its main component. For example, the conductor 805b preferably includes tungsten.

The conductor 805 can function as the second gate electrode. In that case, by changing a potential applied to the conductor 805 not in conjunction with but independently of a potential applied to the conductor 860, the threshold voltage (Vth) of the transistor 800 can be controlled. In particular, by applying a negative potential to the conductor 805, Vth of the transistor 800 can be higher, and its off-state current can be reduced. Thus, a drain current at the time when a potential applied to the conductor 860 is 0 V can be lower in the case where a negative potential is applied to the conductor 805 than in the case where the negative potential is not applied to the conductor 805.

The insulator 824 that is in contact with the oxide 820 preferably includes silicon oxide or silicon oxynitride, for example. Accordingly, oxygen can be supplied from the insulator 824 to the oxide 820, so that oxygen vacancies can be reduced.

The insulator 824 is preferably processed into an island shape in the same manner as the oxide 820. In that case, the plurality of transistors 800 provided include the insulators 824 having substantially the same sizes. Accordingly, substantially the same amount of oxygen is supplied from the insulator 824 to the oxide 820 in the transistors 800. This can reduce variations in electrical characteristics of the transistors 800 in the substrate plane. Note that the structure is not limited to this, and it is possible not to pattern the insulator 824 as in the case of the insulator 822.

A conductive material that is less likely to be oxidized or a conductive material having a function of inhibiting diffusion of oxygen is preferably used for each of the conductor 842a, the conductor 842b, and the conductor 860. Examples of the conductive material include a conductive material including nitrogen and a conductive material including oxygen. Thus, a decrease in the conductivity of the conductor 842a, the conductor 842b, and the conductor 860 can be inhibited.

The insulator 871a and the insulator 871b are inorganic insulators functioning as etching stoppers in the processing into the conductor 842a2 and the conductor 842b2 and protecting the conductor 842a2 and the conductor 842b2. Since the insulator 871a and the insulator 871b are respectively in contact with the conductor 842a and the conductor 842b, the insulator 871a and the insulator 871b are preferably inorganic insulators that are less likely to oxidize the conductors 842a and 842b. The insulator 871a and the insulator 871b preferably have a stacked-layer structure of a nitride insulator and an oxide insulator, for example.

The conductor 860 preferably includes the conductor 860a and the conductor 860b placed over the conductor 860a. For example, the conductor 860a is preferably placed to cover the bottom surface and the side surface of the conductor 860b. In this case, a conductive material that is less likely to be oxidized or a conductive material having a function of inhibiting diffusion of oxygen is preferably used for the conductor 860a. When the conductor 860a has a function of inhibiting diffusion of oxygen, the conductivity of the conductor 860b can be inhibited from being lowered because of oxidation due to oxygen included in the insulator 885 or the like. As the conductive material having a function of inhibiting diffusion of oxygen, for example, titanium, titanium nitride, tantalum, tantalum nitride, ruthenium, or ruthenium oxide is preferably used.

As the conductor 860b, a conductor having high conductivity is preferably used. For example, a conductive material including tungsten, copper, or aluminum as its main component can be used as the conductor 860b. The conductor 860b may have a stacked-layer structure; for example, a stacked-layer structure of the conductive material and titanium or titanium nitride may be employed.

The insulator 816 and the insulator 885 each preferably have a lower permittivity than the insulator 822. When a material with a low permittivity is used for an interlayer film, parasitic capacitance generated between wirings can be reduced.

At least part of the structure examples, the drawings corresponding thereto, and the like described in this embodiment can be combined with the other structure examples, the other drawings, and the like as appropriate.

### Example

In this example, an electronic device using the display system of one embodiment of the present invention was fabricated.

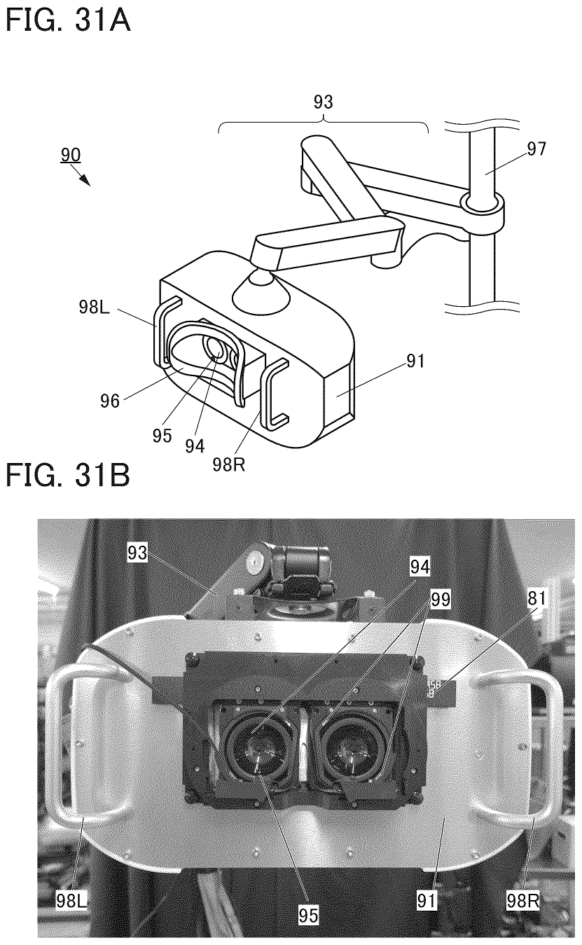

FIG. 31A shows a schematic view of a fabricated electronic device 90. The electronic device 90 includes a housing 91, an articulated arm 93, a handle 98R, a handle 98L, a cushion 96, and the like. The housing 91 is connected to a support rod 97 with the articulated arm 93. The cushion 96 is a portion that is in contact with the user's face (forehead, cheek, or the like) to block peripheral light (external light). Blocking the external light by the cushion 96 enables not only the user to concentrate on a video but also the video to ensure contrast, thereby enhancing sense of immersion.

The housing 91 is provided with a pair of lenses 94 and a pair of cameras 95 for eye tracking. Although not shown here, a pair of display modules, an acceleration sensor for motion sensing, and the like are provided inside the housing 91. The housing 91 is connected to a computer and a circuit module including an FPGA through a cable. The computer executes programs as the coordinate detection portion and the image generation portion exemplified in Embodiment 1. The circuit module executes a program having a function of the data generation portion.

The electronic device 90 is assumed to be used in a way that a user pulls the device toward the head with the handle 98R and the handle 98L to look into it. The electronic device 90 is held by the articulated arm 93. Thus, the electronic device allows a hands-free use, which is hygienic, and a use without a feel of weight, whereby anyone from children to elderly people regardless of physique can have fun with the device. For example, the electronic device is suitable for a use by an unspecified number of people, e.g., demonstrations at exhibitions or the like and entertainment purposes at tourist destinations or the like. In addition, for medical purposes, the electronic device is not only less physically burdensome for doctors because they do not have to support the weight of the goggles on their heads, but also safe in terms of hygiene as doctors can use the device with their hands free during surgery.

FIG. 31B is a photograph of the fabricated electronic device seen from the front side.

The camera 95 is attached below the lens 94. In addition, a pair of infrared LEDs 99 are placed such that the lens 94 is sandwiched therebetween. The housing 91 is provided with an interpupillary distance adjustment mechanism 81, so that the distance between the pair of lenses 94 can be adjusted.

The specifications of the display module placed inside the housing 91 are as follows. Two display modules were incorporated in the housing 91.

TABLE 1

| Screen diagonal | 1.5 | inch |
|---|---|---|
| Resolution | 3840 × RGB × 2880 | |
| Pixel size | 7.92 μm × 7.92 μm | |
| Pixel density | 3207 | ppi |
| Structure | OLED/OS/Si | |
| Coloring method | SBS with photolithography | |
| Emission type | Top emission | |
| Si CMOS process | 55 nm HV | |
| | Logic: 1.2 V, analog: 6.0 V | |
| CAAC-OS process | 360 | nm |
| Refresh rate | 90 Hz (Normal mode) | |
| Source and Gate drivers | Integrated: 32 drivers | |
| Memory (SRAM) | Integrated: 45 MB | |
| Number of Si logic gates | 5 | million |

The fabricated electronic device was found to perform foveated rendering that changes the definition between 32 divided blocks of a display portion in accordance with the coordinates of the gaze point measured by eye tracking.

At least part of the structure examples, the drawings corresponding thereto, and the like described in this example can be combined with the other structure examples, the other drawings, and the like as appropriate.

### REFERENCE NUMERALS

81: interpupillary distance adjustment mechanism, 90: electronic device, 91: housing, 93: articulated arm, 94: lens, 95: camera, 96: cushion, 97: support rod, 98L: handle, 98R: handle, 99: infrared LED, 500: display system, 501: gaze detection portion, 502: attitude detection portion, 503: coordinate detection portion, 504: image generation portion, 505: data generation portion 505, 506: display module, 507A: optical system, 507B: optical system, 507C: optical system, 507: optical system, 511: image-capturing portion, 512: light source, 513: insulator, 514: conductor, 515: display portion, 516: circuit portion, 520B: pixel, 520G: pixel, 520R: pixel, 521: block, 531: lens group, 532: lens group, 533: lens, 534: reflective plate, 535: reflective plate, 536: lens, 537: light guide plate, 538: reflective plate, 539: reflective plate, 541: substrate, 543: adhesive layer, 545: insulating layer, 551: eye

1. A display system comprising:
a display module, a gaze detection portion, an attitude detection portion, a coordinate detection portion, an image generation portion, and a data generation portion,
wherein the display module comprises a circuit portion and a display portion divided into a plurality of blocks,
wherein the gaze detection portion is configured to capture an image of a user's eye and its vicinity and to output image information to the coordinate detection portion,
wherein the coordinate detection portion is configured to generate coordinate information of a gaze point from the image information and to output the coordinate information to the image generation portion,
wherein the attitude detection portion is configured to detect an orientation of a user's head and to output the orientation to the image generation portion as attitude information,
wherein the image generation portion is configured to generate first image data on the basis of the attitude information, to generate definition information for each of the blocks on the basis of the coordinate information, and to output the first image data and the definition information to the data generation portion,
wherein the data generation portion is configured to generate second image data obtained by performing thinning processing on the blocks of the first image data on the basis of the definition information and to output the second image data to the display module,
wherein the circuit portion is configured to generate third image data obtained by interpolation processing for interpolating missing data of the block, subjected to the thinning processing, of the second image data and to output the third image data to the display portion, and
wherein the display portion is configured to display an image on the basis of the third image data.

2. The display system according to claim 1, further comprising an optical system,
wherein the optical system is positioned between the display module and the user, and
wherein the optical system comprises a pancake lens.

3. The display system according to claim 1, further comprising an optical system,
wherein the optical system is positioned between the display module and the user, and
wherein the optical system comprises one or more lenses and two or more reflective plates.

4. The display system according to claim 1,
wherein the gaze detection portion comprises a light source emitting infrared light and a camera having sensitivity to infrared light.

5. The display system according to claim 4,
wherein the camera is provided at a position allowing image capturing of the user's eye from obliquely below.

6. The display system according to claim 1,
wherein the display portion comprises a pixel circuit, and
wherein the pixel circuit comprises a transistor comprising an oxide semiconductor in a semiconductor layer where a channel is formed.

7. The display system according to claim 6,
wherein the display module further comprises a plurality of driver circuits,
wherein the driver circuits each comprise a gate driver circuit and a source driver circuit, and
wherein the display portion and the driver circuits are provided over the same substrate and overlap with each other.

8. The display system according to claim 7,
wherein the source driver circuit comprises a transistor comprising silicon in a semiconductor layer where a channel is formed.
